(19) United States
(12) Patent Application Publication
(10) Pub. No.: US 2020/0019058 A1
(43) Pub. Date: Jan. 16, 2020

(54) ACTINIC RAY-SENSITIVE OR RADIATION-SENSITIVE RESIN COMPOSITION, RESIST FILM, PATTERN FORMING METHOD, AND METHOD FOR MANUFACTURING ELECTRONIC DEVICE

(71) Applicant: FUJIFILM Corporation, Tokyo (JP)

(72) Inventors: Naoya HATAKEYAMA, Haibara-gun (JP); Yasunori YONEKUTA, Haibara-gun (JP); Tsutomu YOSHIMURA, Haibara-gun (JP); Kohei HIGASHI, Haibara-gun (JP); Yoichi NISHIDA, Haibara-gun (JP)

(73) Assignee: FUJIFILM Corporation, Tokyo (JP)

(21) Appl. No.: 16/579,014

(22) Filed: Sep. 23, 2019

Related U.S. Application Data
(63) Continuation of application No. PCT/JP2018/018239, filed on May 11, 2018.

(30) Foreign Application Priority Data
May 19, 2017 (JP) 2017-099988
Feb. 27, 2018 (JP) 2018-033794

(51) Int. Cl. G03F 7/039; G03F 7/038; G03F 7/004; C08F 212/14; C08F 220/68; C08F 212/32

(52) U.S. Cl. CPC G03F 7/039; G03F 7/038; G03F 7/0045; G03F 7/162; C08F 220/68; C08F 212/32; C08F 212/14

(57) ABSTRACT

An actinic ray-sensitive or radiation-sensitive resin composition includes: a resin, in which the actinic ray-sensitive or radiation-sensitive resin composition has a concentration of a solid content of 10% by mass or more, and in which the resin includes: a repeating unit A which is a repeating unit derived from a monomer allowing a homopolymer formed therefrom to have a glass transition temperature of 50° C. or lower, and a repeating unit B which is a repeating unit having an acid-decomposable group, a content of the repeating unit B is 20% by mole or less with respect to all the repeating units in the resin, and at least one of the repeating unit contained in the resin is a repeating unit having an aromatic ring.

### CROSS-REFERENCE TO RELATED APPLICATIONS

This application is a Continuation of PCT International Application No. PCT/JP2018/018239 filed on May 11, 2018, which claims priority under 35 U.S.C § 119(a) to Japanese Patent Application No. 2017-099988 filed on May 19, 2017, and Japanese Patent Application No. 2018-033794 filed on Feb. 27, 2018. Each of the above application(s) is hereby expressly incorporated by reference, in its entirety, into the present application.

### BACKGROUND OF THE INVENTION

### 1. Field of the Invention

The present invention relates to an actinic ray-sensitive or radiation-sensitive resin composition, a resist film, a pattern forming method, and a method for manufacturing an electronic device.

### 2. DESCRIPTION OF THE RELATED ART

An image forming method called chemical amplification has been used as an image forming method for a resist in order to compensate for a reduction in sensitivity caused by light absorption since a resist for a KrF excimer laser (248 nm). For example, examples of a chemically amplified positive-tone image forming method include an image forming method in which a photoacid generator in an exposed area decomposes upon exposure with an excimer laser, electron beams, extreme ultraviolet light, or the like to produce an acid, an alkali-insoluble group is converted to an alkali-soluble group using an acid thus generated as a reaction catalyst by post-exposure baking (PEB), and the exposed area is removed with an alkali developer.

On the other hand, miniaturization using a wavelength of an exposure light source has recently faced limits, and in particular, in process applications in an ion implantation process and a NAND memory (NOT AND memory), it has become a mainstream to make memory layers in a three-dimensional form for the purpose of achieving a large capacity. Since it is necessary to increase the number of processing stages in a vertical direction in making memory layers in a three-dimensional form, it has been required to increase the thickness of a resist film from a nano dimension to a micron dimension.

For example, JP2008-191218A discloses a chemically amplified positive-tone photoresist composition for a thick film, which is used to form a thick-film photoresist layer having a film thickness of 5 to 150 μm.

### SUMMARY OF THE INVENTION

The present inventors have carried out an etching of an object to be etched, using a pattern of a thick film which is formed by lithography with the chemically amplified positive-tone photoresist composition for a thick film described in JP2008-191218A, as a mask, and have studied on a change in the shape and/or a change in the dimension of the mask, and accordingly, they have revealed that the crack resistance of the mask is not necessarily sufficient and there is room for further improvement. Specifically, the present inventors have found that cracks are easily generated in evacuation during an etching of the object to be etched. In addition, even a pattern used as the mask is exposed to a plasma environment during the etching of the object to be etched, but the mask is shrunk in the plasma environment and cracks are generated due to a stress generated during the shrinking.

In addition, the present inventors have revealed that since it is difficult to control the mask into a three-dimensional shape due to a too high etching rate (in other words, deteriorated etching resistance), and there is room for further improvement.

Therefore, an object of the present invention is to provide an actinic ray-sensitive or radiation-sensitive resin composition capable of forming a pattern that can be applied as a mask having excellent crack resistance and etching resistance during an etching, a resist film, a pattern forming method, and a method for manufacturing an electronic device.

The present inventors have conducted extensive studies in order to accomplish the objects, and as a result, they have found that the objects can be accomplished with an actinic ray-sensitive or radiation-sensitive resin composition containing a resin having a specific structure, thereby completing the present invention.

That is, the present inventors have found that the objects can be accomplished by the following configurations.

[1] An actinic ray-sensitive or radiation-sensitive resin composition, comprising:

a resin,

in which the actinic ray-sensitive or radiation-sensitive resin composition has a concentration of a solid content of 10% by mass or more, and

in which the resin includes:

a repeating unit A which is a repeating unit derived from a monomer allowing a homopolymer formed therefrom to have a glass transition temperature of 50° C. or lower, and

a repeating unit B which is a repeating unit having an acid-decomposable group,

a content of the repeating unit B is 20% by mole or less with respect to all the repeating units in the resin, and

at least one of the repeating unit contained in the resin is a repeating unit having an aromatic ring.

[2] The actinic ray-sensitive or radiation-sensitive resin composition as described in [1],

in which a content of the repeating unit A is 5% by mole or more with respect to all the repeating units in the resin.

[3] The actinic ray-sensitive or radiation-sensitive resin composition as described in [1] or [2],

in which a content of the repeating unit A is 10% by mole or more with respect to all the repeating units in the resin.

[4] The actinic ray-sensitive or radiation-sensitive resin composition as described in any one of [1] to [3],

in which the repeating unit A is a repeating unit derived from a monomer allowing a homopolymer formed therefrom to have a glass transition temperature of 30° C. or lower.

[5] The actinic ray-sensitive or radiation-sensitive resin composition as described in any one of [1] to [4],

in which the repeating unit A has a non-acid-decomposable chain alkyl group having 2 or more carbon atoms, which may have a heteroatom.

[6] The actinic ray-sensitive or radiation-sensitive resin composition as described in [5],

in which the repeating unit A is a repeating unit represented by General Formula (1) which will be described later.

[7] The actinic ray-sensitive or radiation-sensitive resin composition as described in any one of [1] to [4],

in which the repeating unit A is a repeating unit represented by General Formula (2) which will be described later.

[1] The actinic ray-sensitive or radiation-sensitive resin composition as described in any one of [I] to [7],

in which the resin further includes a repeating unit C having a carboxy group.

[9] The actinic ray-sensitive or radiation-sensitive resin composition as described in any one of [1] to [8],

in which the resin further includes a repeating unit D having a phenolic hydroxyl group.

[10] The actinic ray-sensitive or radiation-sensitive resin composition as described in any one of [1] to [9], further comprising a compound represented by General Formula (ZI-3) which will be described later or a compound represented by General Formula (ZI-4) which will be described later.

[11] A resist film formed of the actinic ray-sensitive or radiation-sensitive resin composition as described in any one of [1] to [10].

[12] A pattern forming method comprising:

a resist film forming step of forming a resist film using the actinic ray-sensitive or radiation-sensitive resin composition as described in any one of [l] to [10]:

an exposing step of exposing the resist film; and

a developing step of developing the exposed resist film using a developer.

[13] A method for manufacturing an electronic device, comprising the pattern forming method as described in [12].

According to the present invention, it is possible to provide an actinic ray-sensitive or radiation-sensitive resin composition capable of forming a pattern that can be applied as a mask having excellent crack resistance and etching resistance during an etching, a resist film, a pattern forming method, and a method for manufacturing an electronic device.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

“Actinic rays” or “radiation” in the present specification means, for example, a bright line spectrum of a mercury lamp, far ultraviolet rays typified by an excimer laser, extreme ultraviolet rays (EUV rays), X-rays, electron beams (EB), or the like. “Light” in the present specification means actinic rays or radiation.

“Exposure” in the present specification encompasses, unless otherwise specified, not only exposure by a bright line spectrum of a mercury lamp, far ultraviolet rays typified by an excimer laser, extreme ultraviolet rays (EUV rays), X-rays, or the like, but also writing by particle rays such as electron beams and ion beams.

In the present specification, a numerical range expressed using “to” is used in a meaning of a range that includes the preceding and succeeding numerical values of “to” as the lower limit value and the upper limit value, respectively.

In the present specification, (meth)acrylate represents acrylate and methacrylate. In addition, (meth)acrylic acid represents acrylic acid and methacrylic acid.

In the present specification, the weight-average molecular weight (Mw), the number-average molecular weight (Mn), and the dispersity (also referred to as a molecular weight distribution (Mw/Mn) of a resin are defined as values in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

In citations for a group (atomic group) in the present specification, in a case where the group is denoted without specifying whether it is substituted or unsubstituted, the group includes both a group not having a substituent and a group having a substituent. For example, an “alkyl group” includes not only an alkyl group not having a substituent (unsubstituted alkyl group), but also an alkyl group having a substituent (substituted alkyl group). In addition, an “organic group” in the present specification refers to a group including at least one carbon atom.

Moreover, in a case of an expression, “which may have a substituent” in the present specification, the types of substituents, the positions of the substituents, and the number of the substituents are not particularly limited. The number of the substituents may be, for example, one, two, three, or more. Examples of the substituent include a monovalent non-metal atomic group except for a hydrogen atom, and the substituent can be selected from, for example, the following substituent group T.

(Substituent T)

Examples of the substituent T include halogen atoms such as a fluorine atom, a chlorine atom, a bromine atom and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group: acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butvlsulfanyl group; arylsulfanyl groups such as a phenylsulfanyl group and a p-tolylsulfanyl group; an alkyl group: a cycloalkyl group; an aryl group; a heteroaryl group; a hydroxyl group; a carboxy group; a formyl group; a sulfo group: a cyano group; an alkylaminocarbonyl group: an arylaminocarbonyl group; a sulfonamido group; a silyl group; an amino group; a monoalkylamino group: a dialkylamino group; an arylamino group; and a combination thereof.

[Actinic Ray-Sensitive or Radiation-Sensitive Resin Composition]

The actinic ray-sensitive or radiation-sensitive resin composition of an embodiment of the present invention (hereinafter also referred to as “the composition of an embodiment of the present invention”) has a concentration of a solid content of 10% by mass or more, and contains a resin satisfying the following conditions [1] to [4] (hereinafter also referred to as a “resin (A)”).

[1] The actinic ray-sensitive or radiation-sensitive resin composition contains a repeating unit A which is a repeating unit derived from a monomer allowing a homopolymer formed therefrom to have a glass transition temperature of 50° C. or lower.

[2] The actinic ray-sensitive or radiation-sensitive resin composition contains a repeating unit B which is a repeating unit having an acid-decomposable group.

[3] A content of the repeating unit B is 20% by mole or less with respect to all the repeating units in the resin.

[4] At least one of the repeating units contained in the resin is a repeating unit having an aromatic ring.

By the configurations, in a case where a pattern obtained with the actinic ray-sensitive or radiation-sensitive resin composition of the embodiment of the present invention is used as a mask in an etching of an object to be etched, the crack resistance is excellent and the etching resistance is also excellent.

Hereinafter, the action and the effect of the present invention will be described. The action and the effect of the present invention are not clear, but are presumed to be expressed by the following mechanism that acts synergistically.

(Concentration of Solid Content)

The actinic ray-sensitive or radiation-sensitive resin composition of the embodiment of the present invention has a concentration of a solid content of 10% by mass or more. As a result, for example, it is possible to form a thick-film pattern having a film thickness of 1 μm or more (preferably 10 μm or more). Further, the concentration of the solid content is intended to mean a mass percentage of a mass of other components (components that can constitute a resist film) except for a solvent with respect to a total mass of the composition.

(Resin (A))

The present inventors have found that as the thickness of a pattern formed with the actinic ray-sensitive or radiation-sensitive resin composition is increased, a problem of cracks of a pattern caused by a residual solvent remaining inside the pattern significantly occurs. Specifically, it is presumed that in steps such as evacuation to be carried out during an etching of an object to be etched, a stress is generated in the pattern due to volatilization of a residual solvent remaining inside the pattern, and as a result, cracks are generated.

With regard to the findings, the present inventors have solved the problems by incorporating a repeating unit A which is a repeating unit derived from a monomer allowing a homopolymer formed therefrom to have a glass transition temperature of 50° C. or lower [1], into the resin (A). That is, by incorporating the repeating unit A into the resin (A), it becomes easy for the solvent to be volatilized due to enhanced plasticity of a resist film (in other words, a coating film with an actinic ray-sensitive or radiation-sensitive resin composition) upon formation of the resist film, and it is also possible to reduce the amount of the residual solvent in the resist film. As a result, cracks of a pattern in steps such as evacuation to be carried out during the etching of an object to be etched are suppressed.

Moreover, on the other hand, the present inventors have found that cracks are generated in a pattern even in a case where the pattern as a mask is exposed to a plasma environment as described above. It was presumed that an acid-decomposable group decomposes, the mask is shrunk in the plasma environment, a stress is generated in the pattern due to the shrinking, and as a result, cracks are generated.

With regard to the findings, the present inventors have solved the problems by incorporating a repeating unit B having an acid-decomposable group into the resin (A) [2], and adjusting a content of the repeating unit B to 20% by mole or less with respect to all the repeating units in the resin [3].

In addition, with regard to the resin (A), the present inventors have found that in a case where at least one of the repeating unit contained in the resin has a repeating unit having an aromatic ring, the etching resistance of the pattern as a mask is excellent [4].

Hereinafter, the components included in the composition of the embodiment of the present invention will be described in detail. Further, the composition of the embodiment of the present invention is a so-called resist composition, and may be either a positive-tone resist composition or a negative-tone resist composition. In addition, the composition may be either a resist composition for alkali development or a resist composition for organic solvent development. Among those, the composition is preferably the positive-tone resist composition and the resist composition for alkali development.

The composition of the embodiment of the present invention is typically a chemically amplified resist composition.

<Resin (A)>

The composition of the embodiment of the present invention contains a resin (A) satisfying any of the conditions [1] to [4]. Further, the resin (A) corresponds to a resin whose polarity increases through decomposition by the action of an acid from the viewpoint that it contains a repeating unit B having an acid-decomposable group as shown in the condition [2]. That is, in the pattern forming method of an embodiment of the present invention which will be described later, typically, in a case where an alkali developer is employed as a developer, a positive-tone pattern is suitably formed, and in a case where an organic developer is employed as a developer, a negative-tone pattern is suitably formed.

Hereinafter, the repeating unit A to repeating unit D, and the other repeating units included in the resin (A) will be described in detail.

(Repeating Unit A)

The resin (A) contains a repeating unit A which is a repeating unit derived from a monomer allowing a homopolymer formed therefrom to have a glass transition temperature of 50° C. or lower (condition [1]). It is preferable that the repeating unit A does not have an acid-decomposable group.

The monomer is not particularly limited as long as it allows a homopolymer formed therefrom to have a glass transition temperature (Tg) of 50° C. or lower, and from the viewpoint that the crack resistance is more excellent, it is preferable that the has a Tg of 30° C. or lower. The lower limit is not particularly limited, and is −80° C. or higher in many cases.

Furthermore, as a glass transition temperature (Tg (° C.)) of the homopolymer, in a case where there is a catalog value or a literature value, the value is employed, and in a case where there is not such a value, the glass transition temperature (Tg (° C.)) can be measured by differential scanning calorimetry (DSC). A specific measurement method therefor will be described later.

Moreover, from the viewpoint that the residual solvent is more easily volatilized, it is preferable that the repeating unit A is a repeating unit having a non-acid-decomposable chain alkyl group having 2 or more carbon atoms, which may include a heteroatom. In the present specification, an expression. “being non-acid-decomposable”, means that an acid generated by a photoacid generator has a property of not causing a leaving/decomposing reaction.

That is, more specific examples of the “non-acid-decomposable chain alkyl group” include a chain alkyl group that does not leave from the resin (A) by the action of an acid generated by a photoacid generator and a chain alkyl group that does not decompose by the action of an acid generated by a photoacid generator.

Hereinafter, the repeating unit having a non-acid-decomposable chain alkyl group having 2 or more carbon atoms, which may include a heteroatom, will be described.

The number of carbon atoms of the non-acid-decomposable chain alkyl group is not particularly limited as long as it is 2 or more. From the viewpoint that the Tg of the homopolymer is set to 50° C. or lower, the upper limit of the number of carbon atoms of the non-acid-decomposable chain alkyl group is, for example, 20 or less.

The non-acid-decomposable chain alkyl group having 2 or more carbon atoms, which may include a heteroatom, is not particularly limited, and examples thereof include a chained (either linear or branched) alkyl group having 2 to 20 carbon atoms and a chain alkyl group having 2 to 20 carbon atoms, which contains a heteroatom.

Examples of the chain alkyl group having 2 to 20 carbon atoms, which contains a heteroatom, include a chain alkyl group, in which one or two or more of —CH₂—'s are substituted with —O—, —S—, —CO—, —NR₆—, or a divalent organic group formed by combination of two of these groups. R₆ represents a hydrogen atom or an alkyl group having 1 to 6 carbon atoms.

Specific examples of the non-acid-decomposable chain alkyl group having 2 or more carbon atoms, which may include a heteroatom, include a methyl group, an ethyl group, a propyl group, a butyl group, a pentyl group, a hexyl group, a heptyl group, an octyl group, a nonyl group, a decyl group, an isobutyl group, a sec-butyl group, a 1-ethylpentyl group, a 2-ethylhexyl group, and a monovalent alkyl group in which one or two or more of —CH₂—'s of the alkyl group are substituted with —O— or —O—CO—.

From the viewpoint that the crack resistance is more excellent, number of carbon atoms of the non-acid-decomposable chain alkyl group having 2 or more carbon atoms, which may include a heteroatom, is preferably 2 to 16, more preferably 2 to 10, and still more preferably 2 to 8.

In addition, the non-acid-decomposable chain alkyl group having 2 or more carbon atoms may have a substituent (for example, a substituent group T).

Among those, from the viewpoint that the effect of the present invention is more excellent, the repeating unit having the non-acid-decomposable chain alkyl group having 2 or more carbon atoms, which may include a heteroatom, is preferably a repeating unit represented by General Formula (1).

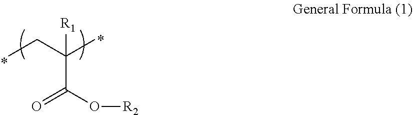

In General Formula (1), R₁ represents a hydrogen atom, a halogen atom, or an alkyl group. R₂ represents a non-acid-decomposable chain alkyl group having 2 or more carbon atoms, which may include a heteroatom.

The halogen atom represented by R₁ is not particularly limited, and examples thereof include a fluorine atom, a chlorine atom, a bromine atom, and an iodine atom.

The alkyl group (in any of linear, branched, and cyclic forms) represented by R₁ is not particularly limited, and examples thereof include an alkyl group having 1 to 10 carbon atoms, and specifically, a methyl group, an ethyl group, and a tert-butyl group. Among those, an alkyl group having 1 to 3 carbon atoms is preferable, and the methyl group is more preferable.

Among those, a hydrogen atom or a methyl group is preferable as R₁.

The definitions and the suitable aspects of the non-acid-decomposable chain alkyl group having 2 or more carbon atoms, which may include a heteroatom, represented by R₂ are as described above.

Moreover, the repeating unit A may also be a repeating unit having a non-acid-decomposable alkyl group having a carboxy group or a hydroxyl group, which may include a heteroatom, from the viewpoint that the residual solvent can be more easily volatilized.

Hereinafter, the repeating unit having a non-acid-decomposable alkyl group having a carboxy group or a hydroxyl group, which may include a heteroatom, will be described.

The non-acid-decomposable alkyl group may be either chain (in any of a linear form and a branched form) or cyclic.

The number of carbon atoms of the non-acid-decomposable alkyl group is preferably 2 or more from the viewpoint that the Tg of the homopolymer is set to 50° C. or lower, and the upper limit of the number of carbon atoms of the non-acid-decomposable alkyl group is, for example, 20 or less.

The non-acid-decomposable alkyl group, which may include a heteroatom, is not particularly limited, and examples thereof include an alkyl group having 2 to 20 carbon atoms, and an alkyl group having 2 to 20 carbon atoms, which contains a heteroatom. In addition, at least one of hydrogen atoms in the alkyl group is substituted with a carboxy group or a hydroxyl group.

Examples of the alkyl group having 2 to 20 carbon atoms, which contains a heteroatom, include alkyl groups in which one or two or more of —CH₂—'s are substituted with —O—, —S—, —CO—, —NR₆—, or a divalent organic group formed by combination of two or more of these groups. R₆ represents a hydrogen atom or an alkyl group having 1 to 6 carbon atoms.

Specific examples of the non-acid-decomposable alkyl group, which may include a heteroatom, include a cyclohexyl group, in addition to the above-mentioned non-acid-decomposable chain alkyl group.

From the viewpoint that the crack resistance is more excellent, the number of carbon atoms of the non-acid-decomposable alkyl group, which may include a heteroatom, is preferably 2 to 16, more preferably 2 to 10, and still more preferably 2 to 8.

In addition, the non-acid-decomposable alkyl group may have a substituent (for example, a substituent group T).

Among those, from the viewpoint that the effect of the present invention is more excellent, a repeating unit represented by General Formula (2) is preferable as the repeating unit having a non-acid-decomposable alkyl group having a carboxy group or a hydroxyl group, which may include a heteroatom.

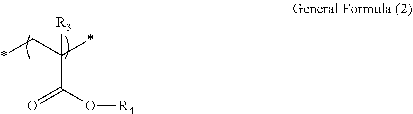

In General Formula (2), R₃ represents a hydrogen atom, a halogen atom, or an alkyl group. R₄ represents a non-acid-decomposable alkyl group having a carboxy group or a hydroxyl group, which may include a heteroatom.

In General Formula (2), R₃ has the same definition as the above-mentioned R₁, and a preferred aspect thereof is also the same.

The definition and suitable aspects of the non-acid-decomposable alkyl group having a carboxy group or a hydroxyl group, which may include a heteroatom, represented by R₄, are as described above. Among those, a cyclic alkylene group having a carboxy group or a hydroxyl group, which may include a heteroatom, is preferable as R₄.

Examples of a monomer constituting the repeating unit represented by General Formula (1) or the repeating unit represented by General Formula (2) include ethyl acrylate (−22° C.), n-propyl acrylate (−37° C.), isopropyl acrylate (−5° C.), n-butyl acrylate (−55° C.), n-butyl methacrylate (20° C.), n-hexyl acrylate (−57° C.), 2-ethylhexyl acrylate (−70° C.), isononyl acrylate (−82° C.), lauryl methacrylate (−65° C.), 2-hydroxyethyl acrylate (−15° C.), 2-hydroxypropyl methacrylate (26° C.), 1-[2-(methacryloyloxy)ethyl] succinate (9° C.), 2-ethylhexyl methacrylate (−10° C.), sec-butyl acrylate (−26° C.), methoxypolyethylene glycol monomethacrylate (n=2) (−20° C.), hexadecyl acrylate (35° C.), and 2-ethylhexyl methacrylate (−10° C.). Further, the Tg (° C.) in a case where the monomers are used to form a homopolymer is in the parenthesis.

The resin (A) may include one kind or two or more kinds of the repeating units A in combination.

In the resin (A), the content of the repeating unit A (a total content in a case where a plurality of the repeating units A are present) is preferably 5% by mole or more, more preferably 10% by mole or more, still more preferably 50% by mole or less, more preferably 40% by mole or less, and even still more preferably 30% by mole or less with respect to all the repeating units of the resin (A). Among those, the content of the repeating unit A (a total content in a case where a plurality of the repeating units A are present) in the resin (A) is preferably 5% to 50% by mole, more preferably 5% to 40% by mole, and still more preferably 5% to 30% by mole with respect to all the repeating units of the resin (A).

(Repeating Unit B)

The resin (A) contains a repeating unit B which is a repeating unit having an acid-decomposable group (Condition [2]). In the resin (A), the content of the repeating unit B is 20% by mole or less with respect to all the repeating units in the resin (A) (Condition [3]). Hereinafter, the repeating unit B will be described in detail.

The acid-decomposable group preferably has a structure in which a polar group is protected with a group (leaving group) that leaves through decomposition by the action of an acid.

Examples of the polar group include an acidic group (a group that dissociates in a 2.38%-by-mass aqueous tetramethylammonium hydroxide solution) such as a carboxy group, a phenolic hydroxyl group, a fluorinated alcohol group, a sulfonic acid group, a sulfonamido group, a sulfonylimido group, an (alkylsulfonyl)(alkylcarbonyl)methylene group, an (alkylsulfonylXalkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Moreover, the alcoholic hydroxyl group refers to a hydroxyl group bonded to a hydrocarbon group, which is a hydroxyl group other than a hydroxyl group (phenolic hydroxyl group) directly bonded to an aromatic ring, from which an aliphatic alcohol (for example, a hexafluoroisopropanol group) having the α-position substituted with an electron withdrawing group such as a fluorine atom is excluded as a hydroxyl group. The alcoholic hydroxyl group is preferably a hydroxyl group having an acid dissociation constant (pKa) from 12 to 20.

Preferred examples of the polar group include a carboxy group, a fluorinated alcohol group (preferably a hexafluoroisopropanol group), and a sulfonic acid group.

A group which is preferable as the acid-decomposable group is a group in which a hydrogen atom of the polar group is substituted with a group that leaves by the action of an acid.

Examples of the group (leaving group) that leaves by an acid include —C(R₃₆)(R₃₇)(R₃₈), —C(R₃₆)(R₃₇)(OR₃₉), and —C(R₀₁)(R₀₂)(R₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the alkyl group as each of R₃₆ to R₃₉, R₀₁, and R₀₂, an alkyl group having 1 to 8 carbon atoms is preferable, and examples thereof include a methyl group, an ethyl group, a propyl group, an n-butyl group, a sec-butyl group, a hexyl group, and an octyl group.

A cycloalkyl group as each of R₃₆ to R₃₉, R₀₁, and R₀₂ may be a monocyclic cycloalkyl group or a polycyclic cycloalkyl group. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, and a cyclooctyl group. As the polycyclic cycloalkyl group, a cycloalkyl group having 6 to 20 carbon atoms is preferable, and examples thereof include an adamantyl group, a norbornyl group, an isobornyl group, a camphonyl group, a dicyclopentyl group, an α-pinene group, a tricyclodecanyl group, a tetracyclododecyl group, and an androstanyl group. Further, at least one carbon atom in the cycloalkyl group may be substituted with heteroatoms such as an oxygen atom.

An aryl group as each of R₃₆ to R₃₉, R₀₁, and R₀₂ is preferably an aryl group having 6 to 10 carbon atoms, and examples thereof include a phenyl group, a naphthyl group, and an anthryl group.

An aralkyl group as each of R₃₆ to R₃₉, R₀₁, and R₀₂ is preferably an aralkyl group having 7 to 12 carbon atoms, and examples thereof include a benzyl group, a phenethyl group, and a naphthylmethyl group.

An alkenyl group as each of R₃₆ to R₃₉, R₀₁, and R₀₂ is preferably an alkenyl group having 2 to 8 carbon atoms, and examples thereof include a vinyl group, an allyl group, a butenyl group, and a cyclohexenyl group.

A ring formed by the bonding of R₃₆ and R₃₇ is preferably a (monocyclic or polycyclic) cycloalkyl group. As the cycloalkyl group, monocyclic cycloalkyl groups such as a cyclopentyl group and a cyclohexyl group, and polycyclic cycloalkyl groups such as a norbornyl group, a tetracyclodecanyl group, a tetracyclododecanyl group, and an adamantyl group are preferable.

The acid-decomposable group is preferably a cumyl ester group, an enol ester group, an acetal ester group, a tertiary alkyl ester group, or the like, and more preferably an acetal ester group or a tertiary alkyl ester group.

Repeating Unit Having Structure (Acid-Decomposable Group) in Which —COO— Group Is Protected with Leaving Group That Leaves through Decomposition by Action of Acid

The resin (A) preferably has a repeating unit represented by General Formula (AI) as the repeating unit B.

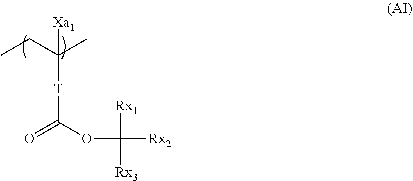

In General Formula (AI),

Xa₁ represents a hydrogen atom, a halogen atom, or a monovalent organic group.

T represents a single bond or a divalent linking group.

Rx₁ to Rx₃ each independently represent an alkyl group or a cycloalkyl group.

Any two of Rx₁ to Rx₃ may or may not be bonded to each other to form a ring structure.

Examples of the divalent linking group of T include an alkylene group, an arylene group, —COO—Rt-, and —O—Rt-. In the formulae, Rt represents an alkylene group, a cycloalkylene group, or an arylene group.

T is preferably a single bond or —COO-Rt-. Rt is preferably an alkylene group having 1 to 5 carbon atoms, and more preferably a —CH₂— group, a —(CH₂)₂— group, or a —(CH₂)₃— group. T is more preferably a single bond.

Xa₁ is preferably a hydrogen atom or an alkyl group.

The alkyl group of Xa₁ may have a substituent, and examples of the substituent include a hydroxyl group and a halogen atom (preferably a fluorine atom).

The alkyl group of Xa₁ preferably has 1 to 4 carbon atoms, and examples thereof include a methyl group, an ethyl group, a propyl group, a hydroxymethyl group, and a trifluoromethyl group. The alkyl group of Xa₁ is preferably a methyl group.

The alkyl group of each of Rx₁. Rx₂, and Rx₃ may be linear or branched, and is preferably a methyl group, an ethyl group, an n-propyl group, an isopropyl group, an n-butyl group, an isobutyl group, a t-butyl group, or the like is preferable. The number of the carbon atoms of the alkyl group is preferably 1 to 10, more preferably 1 to 5, and still more preferably 1 to 3. The alkyl group of each of Rx₁, Rx₂, and Rx₃ may have some of carbon-carbon bonds that are double-bonded.

The cycloalkyl group of each of Rx₁, Rx₂, and Rx₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

As the ring structure formed by the bonding of two of Rx₁, Rx₂, and Rx₃, a monocyclic cycloalkane ring such as a cyclopentyl ring, a cyclohexyl ring, a cycloheptyl ring, and a cyclooctane ring, or a polycyclic cycloalkyl group such as a norbornane ring, a tetracyclodecane ring, a tetracyclododecane ring, and an adamantane ring is preferable. Among those, the cyclopentyl ring, the cyclohexyl ring, or the adamantane ring is more preferable. As the ring structure formed by the bonding of two of Rx₁, Rx₂, and Rx₃, a structure shown below is also preferable.

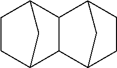 [SMILES: C1CC2CC1C1C3CCC(C3)C21]

Specific examples of a monomer corresponding to the repeating unit represented by General Formula (AI) are shown below, but the present invention is not limited to these specific examples. The following specific examples correspond to a case where Xa₁ in General Formula (AI) is a methyl group, but Xa₁ can be optionally substituted with a hydrogen atom, a halogen atom, or a monovalent organic group.

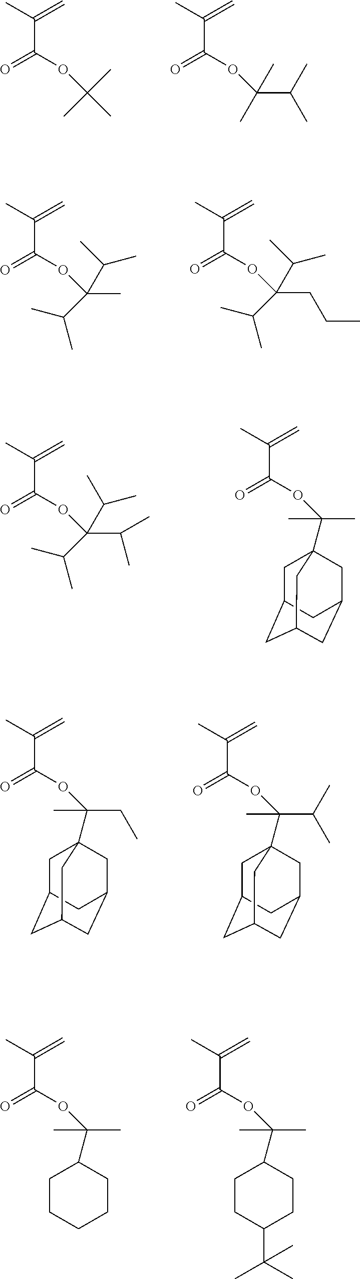

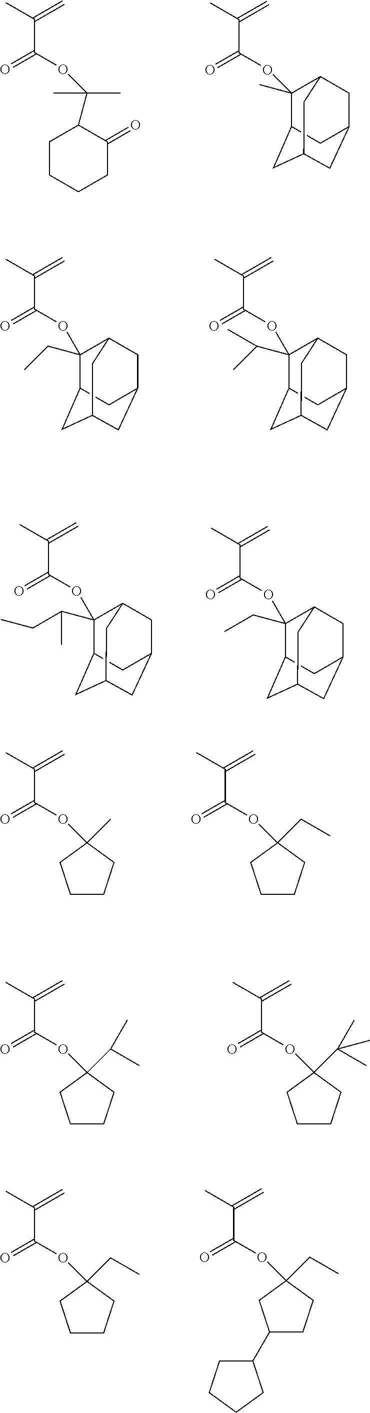

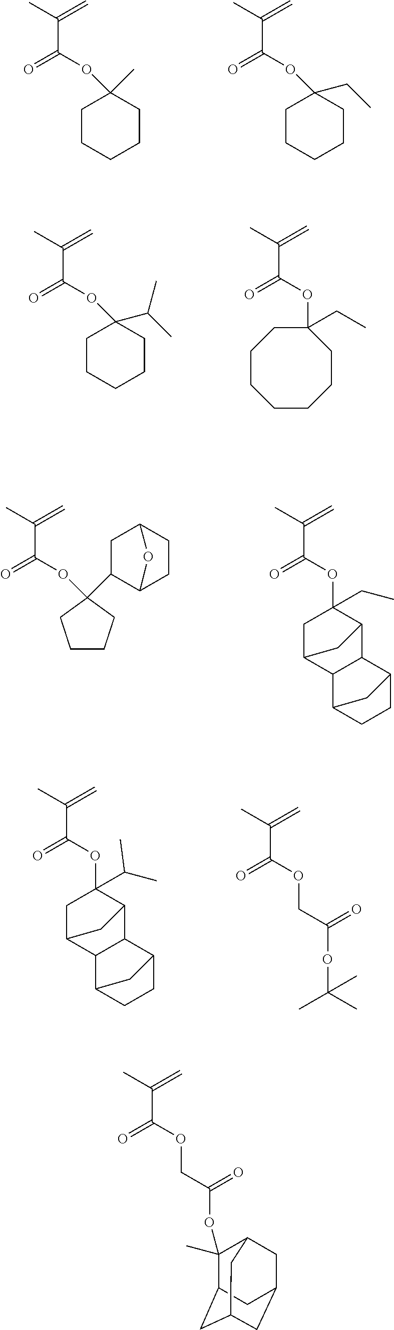

It is also preferable that the resin (A) has the repeating unit described in paragraphs <0336> to <0369> of US2016/0070167AI as the repeating unit B.

Moreover, the resin (A) may have a repeating unit including a group that generates an alcoholic hydroxyl group through decomposition by the action of an acid, described in paragraphs <0363> to <0364> of US2016/0070167A1, as the repeating unit B.

Repeating Unit Having Structure (Acid-Decomposable Group) in Which Phenolic Hydroxyl Group Is Protected with Leaving Group That Leaves through Decomposition by Action of Acid

The resin (A) preferably has a repeating unit having a structure in which a phenolic hydroxyl group is protected with a leaving group that leaves through decomposition by the action of an action as the repeating unit B. Further in the present specification, the phenolic hydroxyl group is a group formed by substituting a hydrogen atom of an aromatic hydrocarbon group with a hydroxyl group. The aromatic ring of the aromatic hydrocarbon group is a monocyclic or polycyclic aromatic ring, and examples thereof include a benzene ring and a naphthalene ring.

Examples of the leaving group that leaves through decomposition by the action of an action include groups represented by Formulae (Y1) to (Y4).

—C(Rx₁)(Rx₂)(Rx₃) Formula(Y1):

—C(═O)OC(Rx₁)(Rx₂)(Rx₃) Formula (Y2):

—C(R₃₆)(R₃₇)(R₃₈) Formula (Y3):

—C(Rn)(H)(Ar) Formula (Y4):

In Formulae (Y1) and (Y2), Rx₁ to Rx₃ each independently represent an (linear or branched) alkyl group or a (monocyclic or polycyclic) cycloalkyl group. It should be noted that in a case where all of Rx₁ to Rx₃ are (linear or branched) alkyl groups, it is preferable that at least two of Rx₁, . . . , or Rx₃ are methyl groups.

Among those, it is preferable that Rx₁ to Rx₃ each independently represent a repeating unit representing a linear or branched alkyl group, and it is more preferable that Rx₁ to Rx₃ each independently represent a repeating unit representing a linear alkyl group.

Two of Rx₁ to Rx₃ may be bond to each other to form a monocycle or a poly cycle.

As the alkyl group as each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable. A monocyclic cycloalkyl group having 5 or 6 carbon atoms is more preferable.

In the cycloalkyl group formed by the bonding of two of Rx₁ to Rx₃, for example, one methylene group constituting the ring may be substituted with a heteroatom such as an oxygen atom or a group having a heteroatom, such as a carbonyl group.

For the group represented by each of Formulae (Y1) and (Y2), for example, an aspect in which Rx₁ is a methyl group or an ethyl group, and Rx₂ and Rx₃ are bonded to each other to form the above-mentioned cycloalkyl group is preferable.

In Formula (Y3), R₃₆ to R₃₈ each independently represent a hydrogen atom or a monovalent organic group. R₃₇ and R₃₈ may be bonded to each other to form a ring.

Examples of the monovalent organic group include an alkyl group, a cycloalkyl group, an aryl group, an aralkyl group, and an alkenyl group. It is also preferable that R₃₆ is a hydrogen atom.

In Formula (Y4), Ar represents an aromatic hydrocarbon group. Rn represents an alkyl group, a cycloalkyl group, or an aryl group. Rn and Ar may be bonded to each other to form a non-aromatic ring. Ar is more preferably an aryl group.

The repeating unit having a structure (acid-decomposable group) in which a phenolic hydroxyl group is protected with a leaving group that leaves through decomposition by the action of an action preferably a structure in which a hydrogen atom in the phenolic hydroxyl group is protected with a group represented by Formulae (Y1) to (Y4).

As the repeating unit having a structure (acid-decomposable group) in which a phenolic hydroxyl group is protected with a leaving group that leaves through decomposition by the action of an action, a repeating unit represented by General Formula (AII) is preferable.

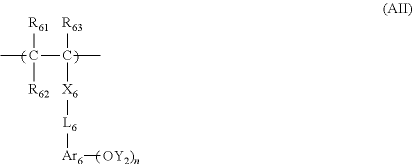

In General Formula (AII),

R₆₁, R₆₂, and R₆₃ each independently represent a hydrogen atom, an alkyl group, a cycloalkyl group, a halogen atom, a cyano group, or an alkoxycarbonyl group. It should be noted that R₆₂ may be bonded to Ar₆ to form a ring, and in this case, R₆₂ represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1)-valent aromatic hydrocarbon group, and in a case where Ar₆ is bonded to R₆₂ to form a ring, Ar₆ represents an (n+2)-valent aromatic hydrocarbon group.

In a case of n≥2, Y₂'s each independently represent a hydrogen atom or a group that leaves by the action of an acid. It should be noted that at least one of Y>'s represents a group that leaves by the action of an acid. The group that leaves by the action of an acid as Y₂ is preferably a group of each of Formulae (Y1) to (Y4), n represents an integer of 1 to 4.

Each of the groups may have a substituent, and examples of the substituent include an alkyl group (having 1 to 4 carbon atoms), a halogen atom, a hydroxyl group, an alkoxy group (having 1 to 4 carbon atoms), a carboxy group, and an alkoxycarbonyl group (having 2 to 6 carbon atoms), and the number of carbon atoms of the substituent is preferably 8 or less.

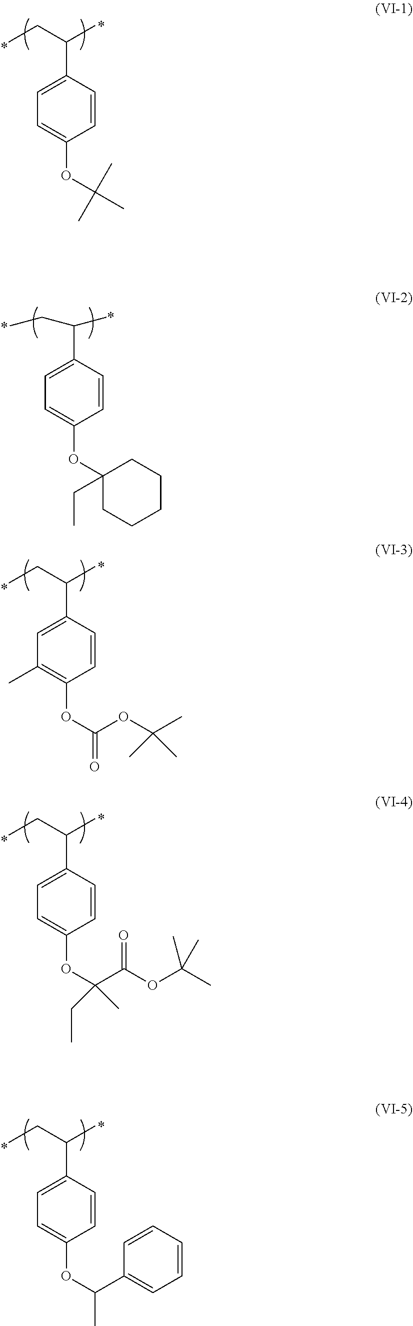

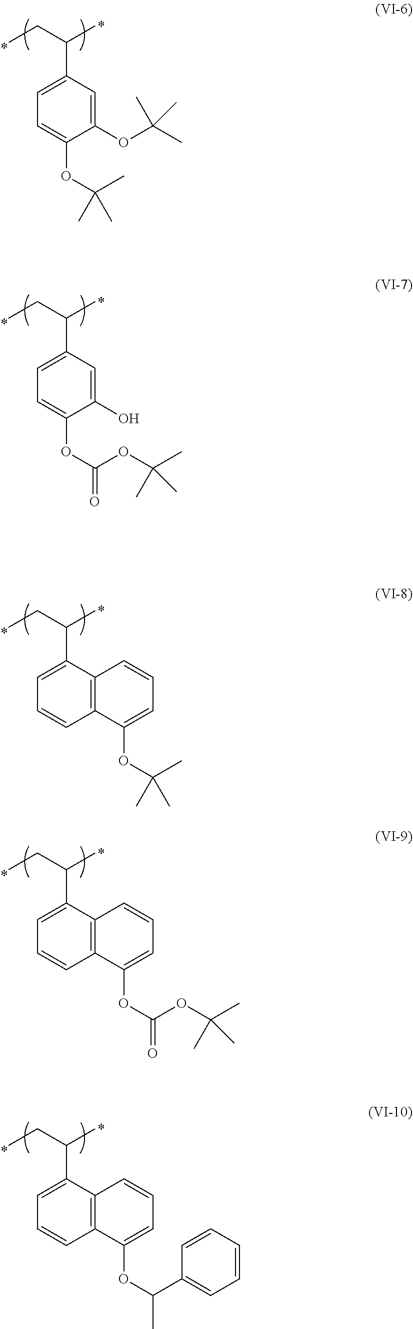

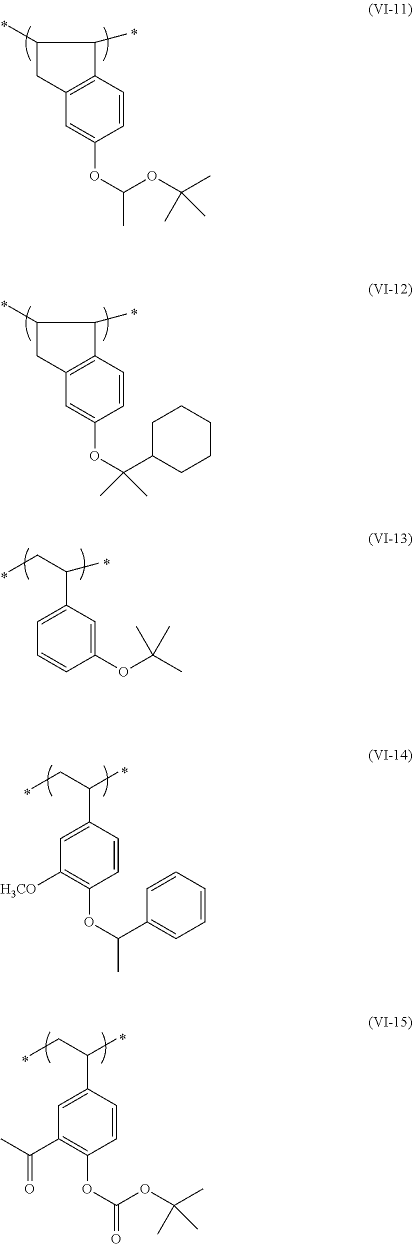

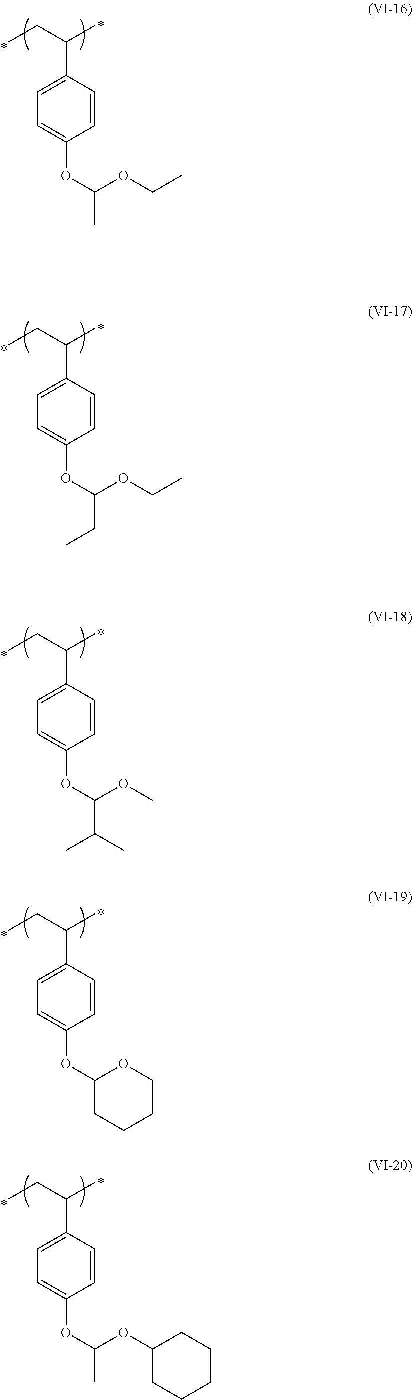

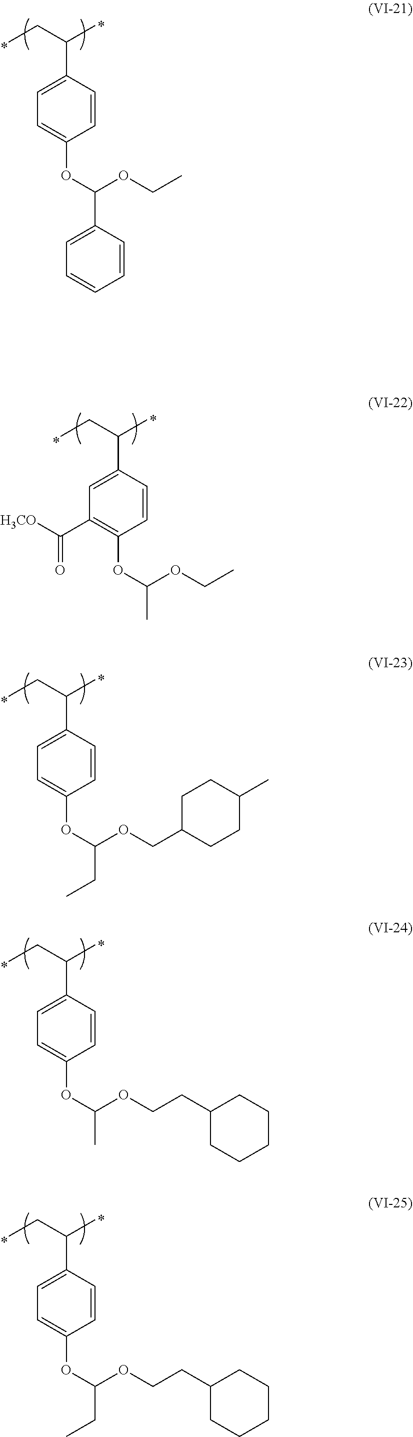

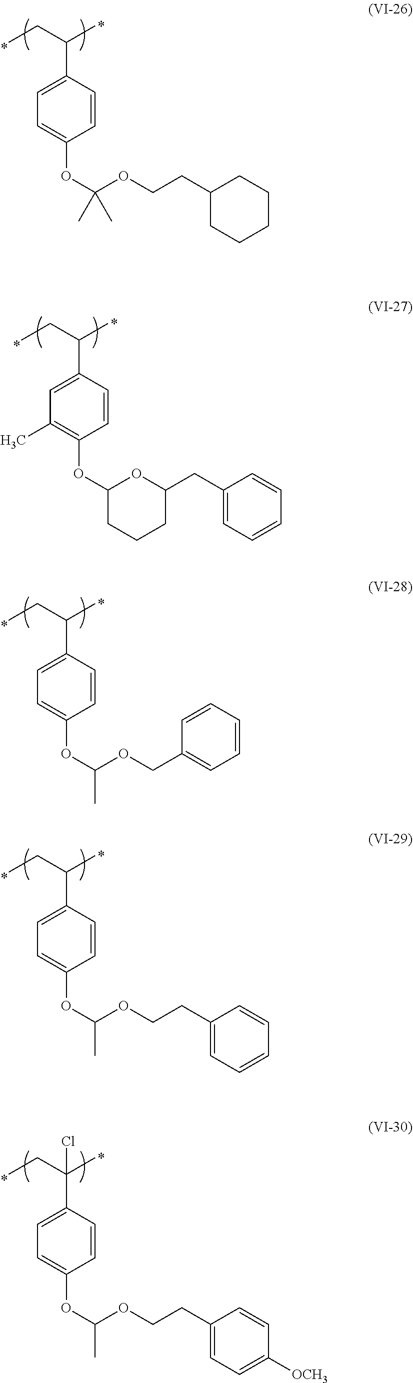

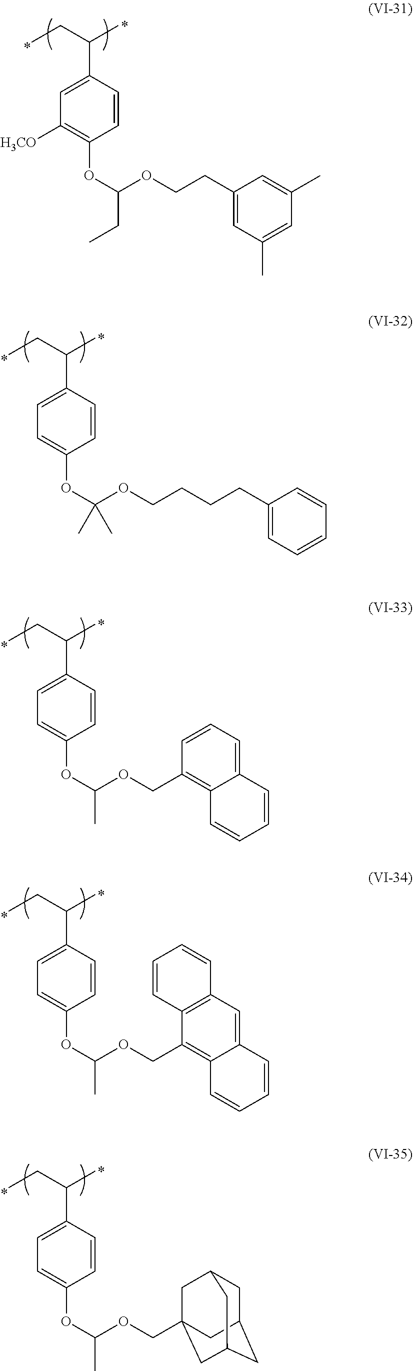

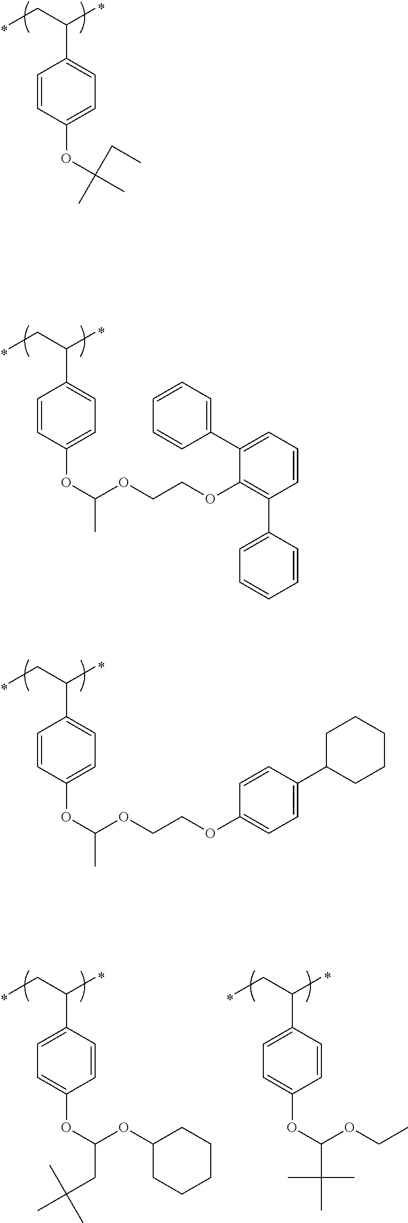

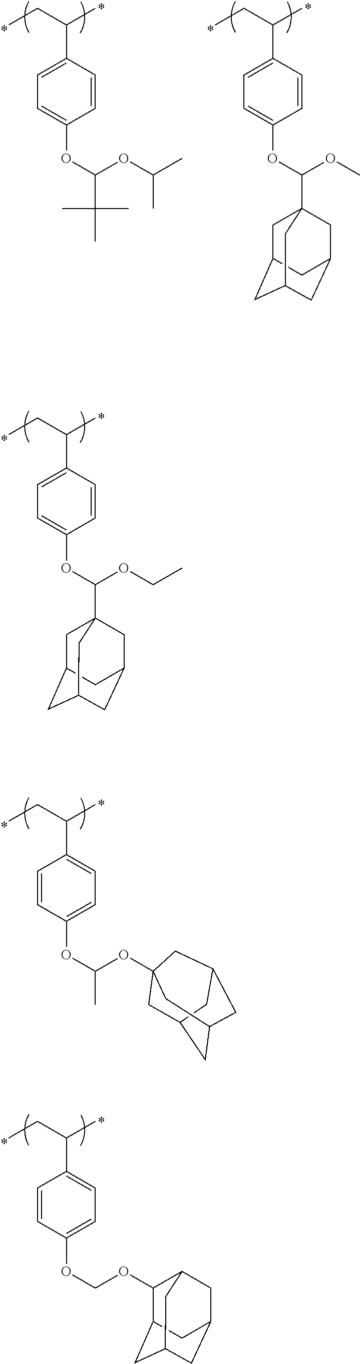

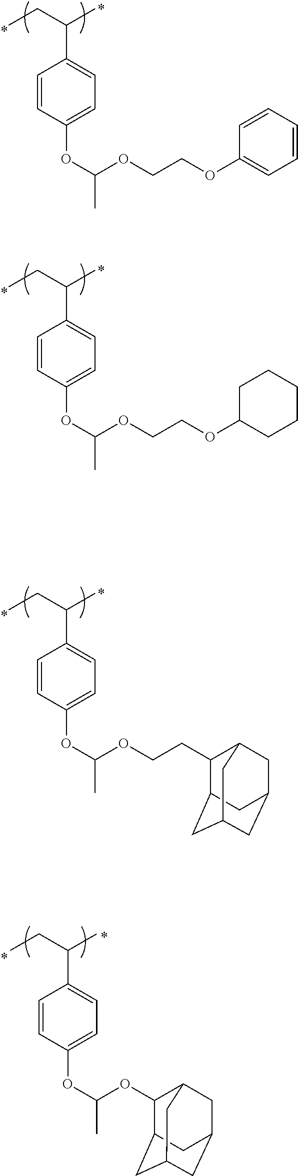

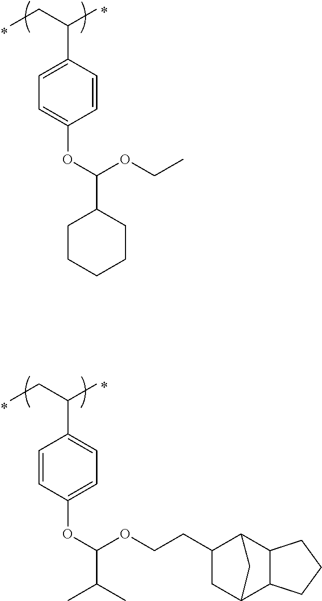

The resin (A) may include one kind or two or more kinds of the repeating units B in combination.

In the resin (A), the content of the repeating unit B (a total content in a case where a plurality of the repeating units B are present) is 20% by mole or less with respect to all the repeating units of the resin (A), and from the viewpoint that the crack resistance and the etching resistance are more excellent, the content of the repeating unit B is preferably 15% by mole or less. In addition, the lower limit of the content of the repeating unit B is, for example, 3% by mole or more, and preferably 5% by mole or more with respect to all the repeating units of the resin (A).

(Repeating Unit C)

The resin (A) preferably contains a repeating unit C which is a repeating unit having a carboxy group, in addition to the above-mentioned repeating unit A and repeating unit B. By incorporating the repeating unit C into the resin (A), the dissolution rate during an alkali development is more excellent.

Examples of the repeating unit C include repeating units derived from (meth)acrylic acids, as shown below.

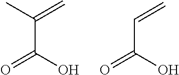

The resin (A) may have one kind or two or more kinds of the repeating units C in combination.

In the resin (A), the content of the repeating unit C is preferably 1% to 10% by mole, and more preferably 2% to 8% by mole with respect to all the repeating units in the resin (A).

(Repeating Unit D)

The resin (A) preferably contains a repeating unit D having a phenolic hydroxyl group, in addition to the above-mentioned repeating units A to C. Further, the repeating unit D does not have an acid-decomposable group. By incorporating the repeating unit D into the resin (A), the dissolution rate during an alkali development is more excellent and the etching resistance is more excellent.

Examples of the repeating unit D include a hydroxystyrene repeating unit and a hydroxy styrene (meth)acrylate repeating unit. Among the repeating units D, a repeating unit represented by General Formula (I) is preferable.

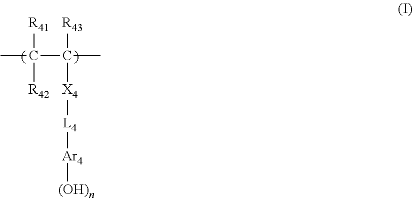

In the formula, R₄₁, R₄₂, and R₄₃ each independently represent a hydrogen atom, an alkyl group, a cycloalkyl group, a halogen atom, a cyano group, or an alkoxycarbonyl group. It should be noted that R₄₂ may be bonded to Ar₄ to form a ring, and in this case, R₄₂ represents a single bond or an alkyl ene group.

X₄ represents a single bond, —COO—, or —CONR₆₄—, and R₆₄ represents a hydrogen atom or an alkyl group.

L₄ represents a single bond or a divalent linking group.

Ar₄ represents an (n+1)-valent aromatic hydrocarbon group, and in a case where Ar₄ is bonded to R*₂ to form a ring, Ar₄ represents an (n+2)-valent aromatic hydrocarbon group.

n represents an integer of 1 to 5.

For the purpose of enhancing the polarity of the repeating unit represented by General Formula (I), it is also preferable that n is an integer of 2 or more, or X₄ is —COO— or —CONR₆₄—.

As the alkyl group of each of R₄₁, R₄₂, and R₄₃ in General Formula (1), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, is preferable, an alkyl group having 8 or less carbon atoms is more preferable, and an alkyl group having 3 or less carbon atoms is still more preferable.

The cycloalkyl group R₄₁, R₄₂, and R₄₃ in General Formula (I) may be either monocyclic or polycyclic. Among those, a monocyclic cycloalkyl group having 3 to 8 carbon atoms, such as a cyclopropyl group, a cyclopentyl group, and a cyclohexyl group, is preferable.

Examples of the halogen atom of each of R₄₁, R₄₂, and R₄₃ in General Formula (I) include a fluorine atom, a chlorine atom, a bromine atom, and an iodine atom, and the fluorine atom is preferable.

As the alkyl group included in the alkoxycarbonyl group of each of R₄₁, R₄₂, and R₄₃ in General Formula (I), the same ones as the alkyl group in each of R₄₁, R₄₂, and R₄₃ are preferable.

Preferred examples of the substituent in each of the groups include an alkyl group, a cycloalkyl group, an aryl group, an amino group, an amido group, a ureido group, a urethane group, a hydroxyl group, a carboxy group, a halogen atom, an alkoxy group, a thioether group, an acyl group, an acyloxy group, an alkoxycarbonyl group, a cyano group, and a nitro group, and the number of carbon atoms of the substituent is preferably 8 or less.

Ar₄ represents an (n+1)-valent aromatic hydrocarbon group. The divalent aromatic hydrocarbon group in a case where n is 1 may have a substituent, and for example, an arylene group having 6 to 18 carbon atoms, such as a phenylene group, a tolylene group, a naphthylene group, and an anthracenylene group, or an aromatic hydrocarbon group including a heterocycle, such as thiophene, furan, pyrrole, benzothiophene, benzofuran, benzopyrrole, triazine, imidazole, benzimidazole, triazole, thiadiazole, and thiazole, is preferable.

Specific suitable examples of the (n+1)-valent aromatic hydrocarbon group in a case where n is an integer of 2 or more include groups formed by excluding any (n−1) hydrogen atoms from the above-mentioned specific examples of the divalent aromatic hydrocarbon group.

The (n+1)-valent aromatic hydrocarbon group may further have a substituent.

Examples of the substituent which can be contained in the above-mentioned alkyl group, cycloalkyl group, alkoxycarbonyl group, alkylene group, and (n+1)-valent aromatic hydrocarbon group include the alkyl groups listed in R₄₁, R₄₂, and R₄₃ in General Formula (I); alkoxy groups such as a methoxy group, an ethoxy group, a hydroxyethoxy group, a propoxy group, a hydroxy propoxy group, and a butoxy group; and aryl groups such as a phenyl group.

As the alkyl group of R₆₄ in —CONR₆₄— (R₆₄ represents a hydrogen atom or an alkyl group) represented by X₄, an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group is preferable, and an alkyl group having 8 or less carbon atoms is more preferable.

As X₄, a single bond, —COO—, or —CONH— is preferable, and the single bond or —COO— is more preferable.

As the divalent linking group as L₄, an alkylene group is preferable. As the alkylene group, an alkylene group having 1 to 8 carbon atoms, such as a methylene group, an ethylene group, a propylene group, butylene group, a hexylene group, and an octylene group, is preferable.

As Ar₄, an aromatic hydrocarbon group having 6 to 18 carbon atoms is preferable, and a benzene ring group, a naphthalene ring group, or a biphenylene ring group is more preferable. Among those, the repeating unit represented by General Formula (I) is preferably a repeating unit derived from hydroxystyrene. That is, Ar₄ is preferably a benzene ring group.

Specific examples of the repeating unit D are shown below, but the present invention is not limited thereto. In the formulae, a represents 1 or 2.

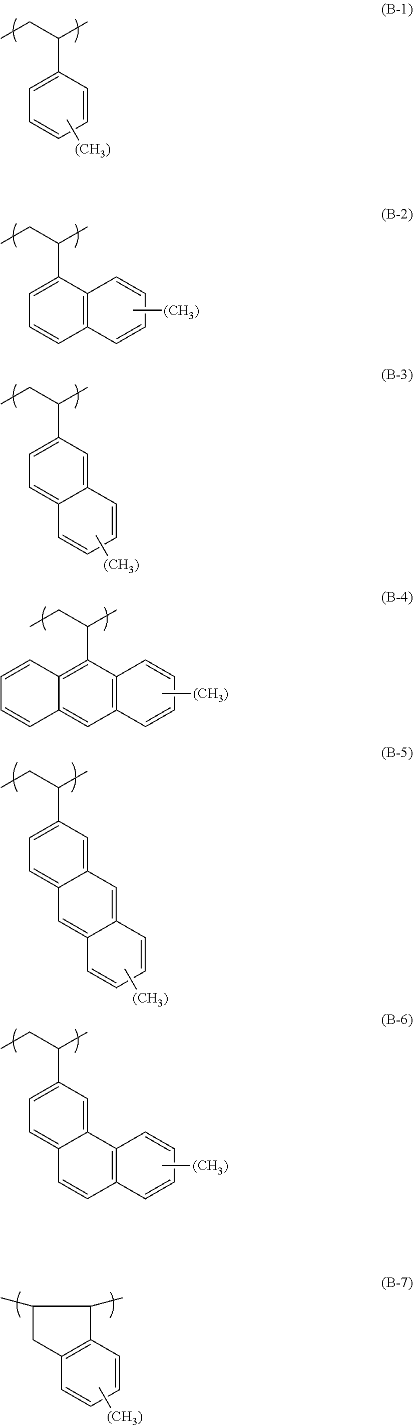

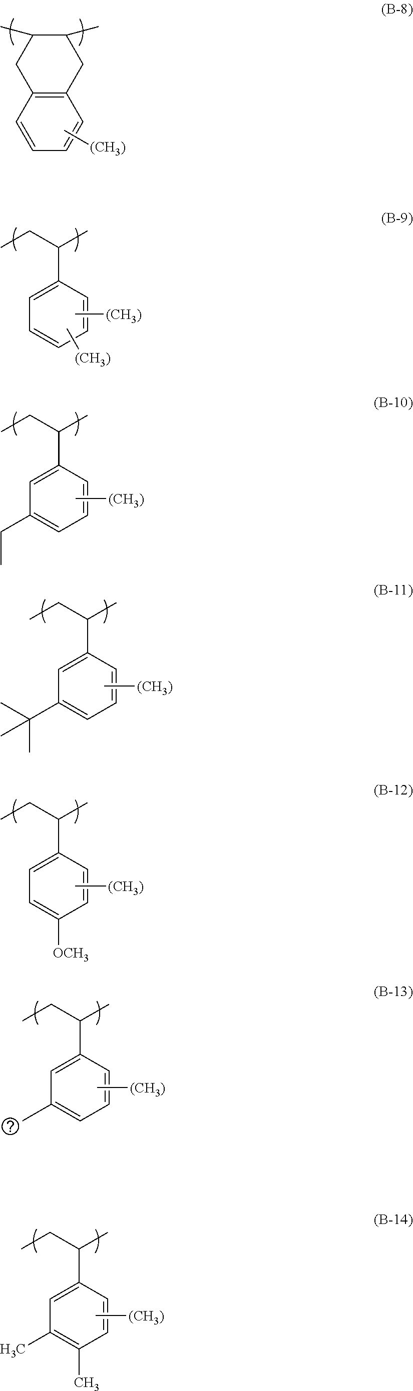

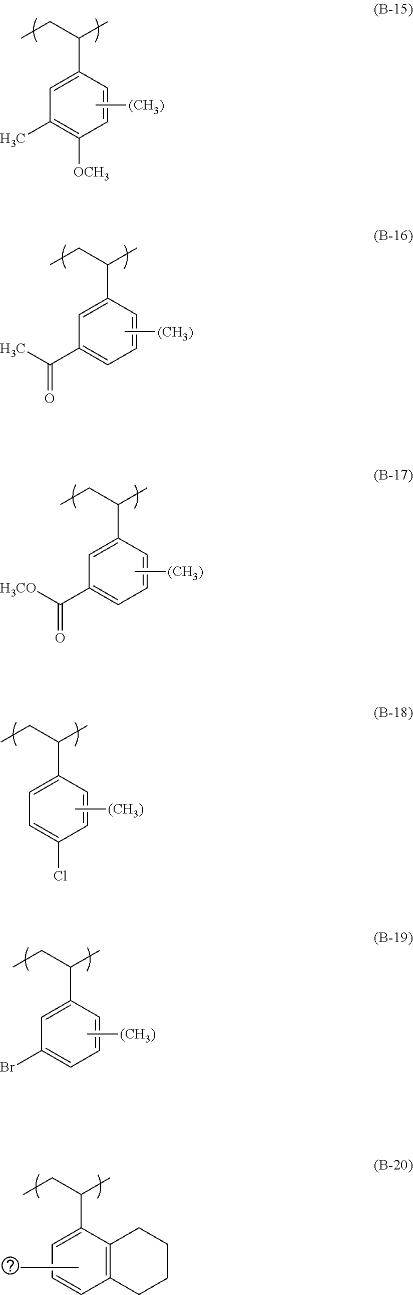

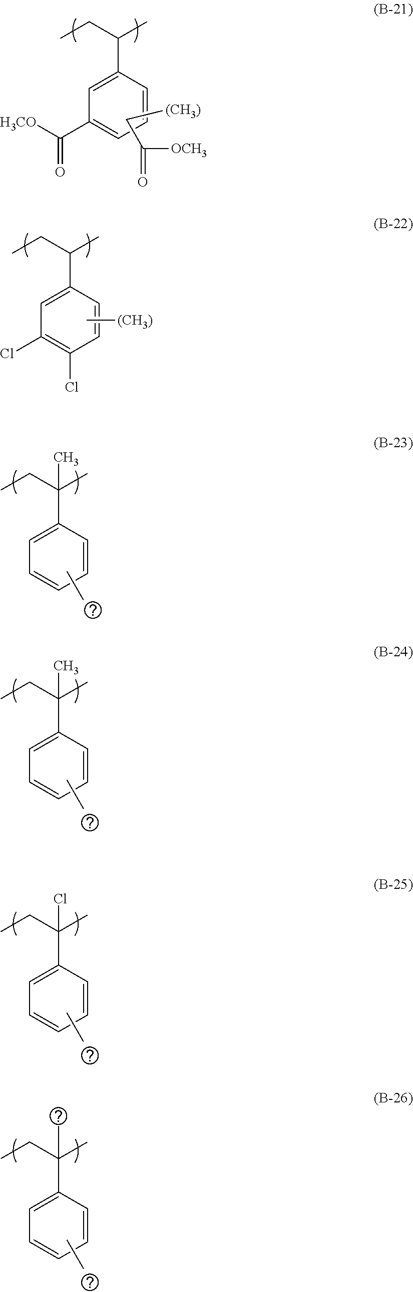

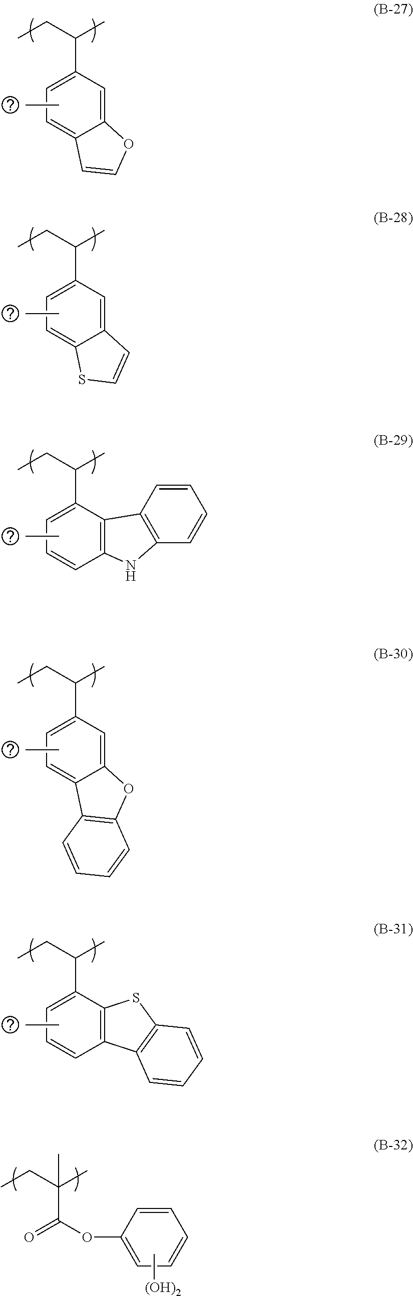

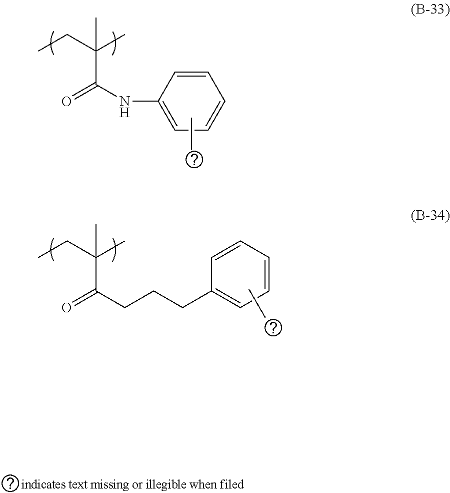

The resin (A) may have one kind or two or more kinds of the repeating units D in combination.

In the resin (A), the content of the repeating unit D is preferably 40% by mole or more, more preferably 50% by mole or more, and still more preferably 60% by mole or more, and is preferably 85% by mole or less, and more preferably 80% by mole or less, with respect to all the repeating units in the resin (A).

(Other Repeating Units)

The resin (A) preferably contains other repeating units, in addition to the above-mentioned repeating units A to D.

Such other repeating units that can be contained in the resin (A) will be described in detail.

The resin (A) preferably has a repeating unit having at least one selected from the group consisting of a lactone structure, a sultone structure, and a carbonate structure.

As the lactone structure or sultone structure, any structure may be used as long as it has a lactone structure or sultone structure, but the structure is preferably a 5- to 7-membered ring lactone structure or a 5- to 7-membered ring sultone structure. Among those, the structure is more preferably a 5- to 7-membered ring lactone structure to which another ring structure is fused in the form of forming a bicyclo structure or a spiro structure or a 5- to 7-membered ring sultone structure to which another ring structure is fused in the form of forming a bicyclo structure or a spiro structure.

The resin (A) still more preferably has a repeating unit having a lactone structure represented by any one of General Formulae (LC1-1) to (LC1-21) or a sultone structure represented by any one of General Formulae (SL1-1) to (SL1-3). Further, the lactone structure or sultone structure may be bonded directly to the main chain. Preferred examples of the structure include a lactone structure represented by General Formula (LC1-1), General Formula (LC1-4), General Formula (LC1-5), General Formula (LC1-8), General Formula (LC1-16), or General Formula (LC1-21), or a sultone structure represented by General Formula (SL1-1).

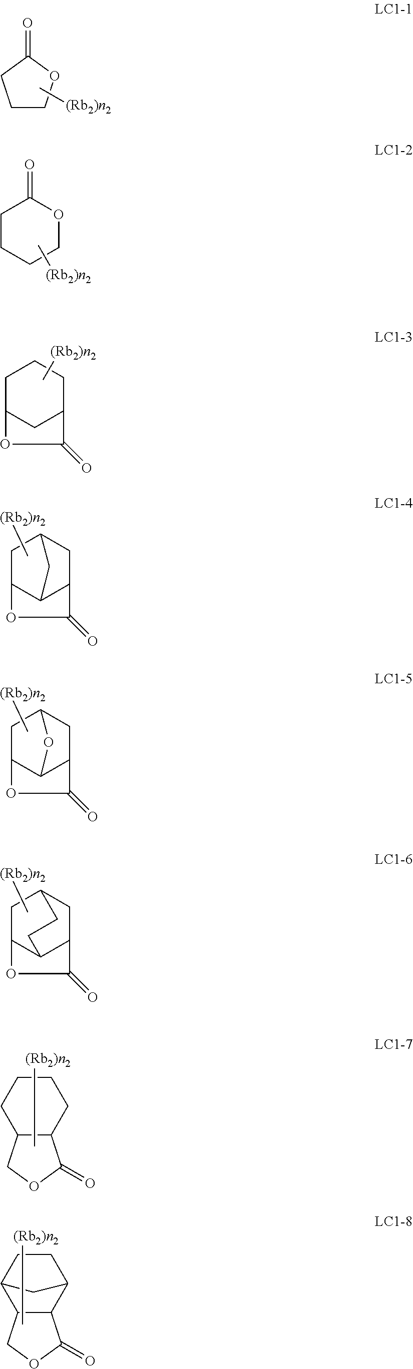

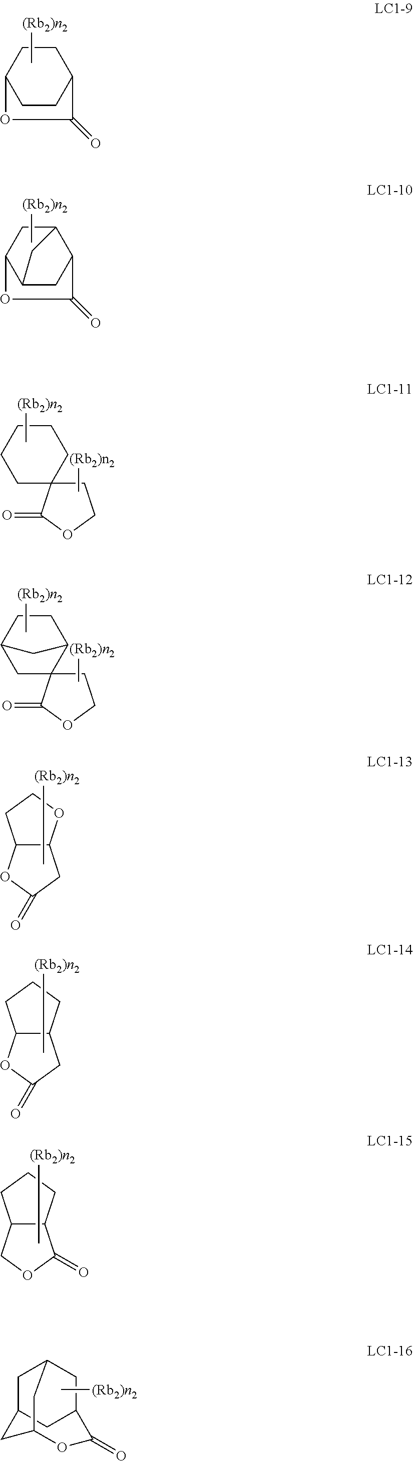

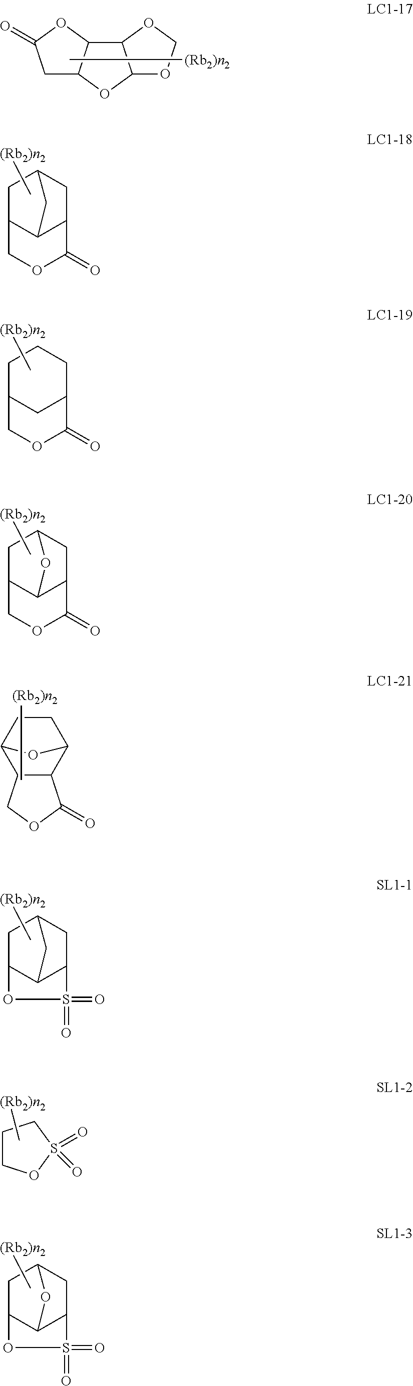

The lactone structural moiety or the sultone structural moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxy carbonyl group having 2 to 8 carbon atoms, a carboxy group, a halogen atom, a hydroxyl group, a cyano group, and an acid-decomposable group, and an alkyl group having 1 to 4 carbon atoms, a cyano group, or an acid-decomposable group is preferable. n₂ represents an integer of 0 to 4. In a case where n₂ is 2 or more, the substituents (Rb₂) which are present in plural number may be the same as or different from each other. Further, the substituents (Rb₂) which are present in plural number may be bonded to each other to form a ring.

As the repeating unit having a lactone structure or a sultone structure, a repeating unit represented by General Formula (III) is preferable.

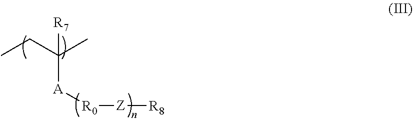

In General Formula (III),

A represents an ester bond (a group represented by —COO—) or an amide bond (a group represented by —CONH—).

n is the repetition number of the structure represented by —R₀—Z—, represents an integer of 0 to 5, and is preferably 0 or 1, and more preferably 0. In a case where n is 0, —R₀—Z— is not present, and is thus a single bond.

R₀ represents an alkylene group, a cycloalkylene group, or a combination thereof. In a case where a plurality of Re's are present, R₀'s each independently represent an alkylene group, a cycloalkylene group, or a combination thereof.

Z represents a single bond, an ether bond, an ester bond, an amide bond, a urethane bond, or a urea bond. In a case where a plurality of Z's are present, Z's each independently represent a single bond, an ether bond, an ester bond, an amide bond, or a urethane bond.

R₈ represents a monovalent organic group having a lactone structure or sultone structure.

R₇ represents a hydrogen atom, a halogen atom, or a monovalent organic group (preferably a methyl group).

The alkylene group or the cycloalkylene group of R₀ may have a substituent.

Z is preferably an ether bond or an ester bond, and more preferably an ester bond.

The resin (A) may have a repeating unit having a carbonate structure. The carbonate structure is preferably a cyclic carbonate ester structure.

The repeating unit having a cyclic carbonate ester structure is preferably a repeating unit represented by General Formula (A-1).

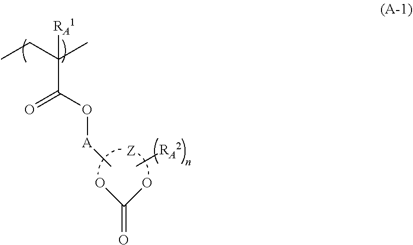

In General Formula (A-1), R_{A}¹ represents a hydrogen atom, a halogen atom, or a monovalent organic group (preferably a methyl group).

n represents an integer of 0 or more.

R_{A}² represents a substituent. In a case where n is 2 or more. R_{A}²'s each independently represent a substituent.

A represents a single bond or a divalent linking group.

Z represents an atomic group which forms a monocyclic or polycyclic structure together with a group represented by —O—C(═O)—O— in the formula.

It is also preferable that the resin (A) has the repeating unit described in paragraphs <0370> to <0414> of US2016/0070167A1 as the repeating unit having at least one selected from the group consisting of a lactone structure, a sultone structure, and a carbonate structure.

The resin (A) may have only one kind or two or more kinds of repeating units having at least one selected from the group consisting of a lactone structure, a sultone structure, and a carbonate structure.

Specific examples of a monomer corresponding to the repeating unit represented by General Formula (III) and a monomer corresponding to the repeating unit represented by General Formula (A-1) are shown below, but the present invention is not limited to these specific examples. The following specific examples correspond to a case where R₇ in General Formula (III) and R_{A}¹ in General Formula (A-1) are each a methyl group, but R₇ and R_{A}¹ may be optionally substituted with a hydrogen atom, a halogen atom, or a monovalent organic group.

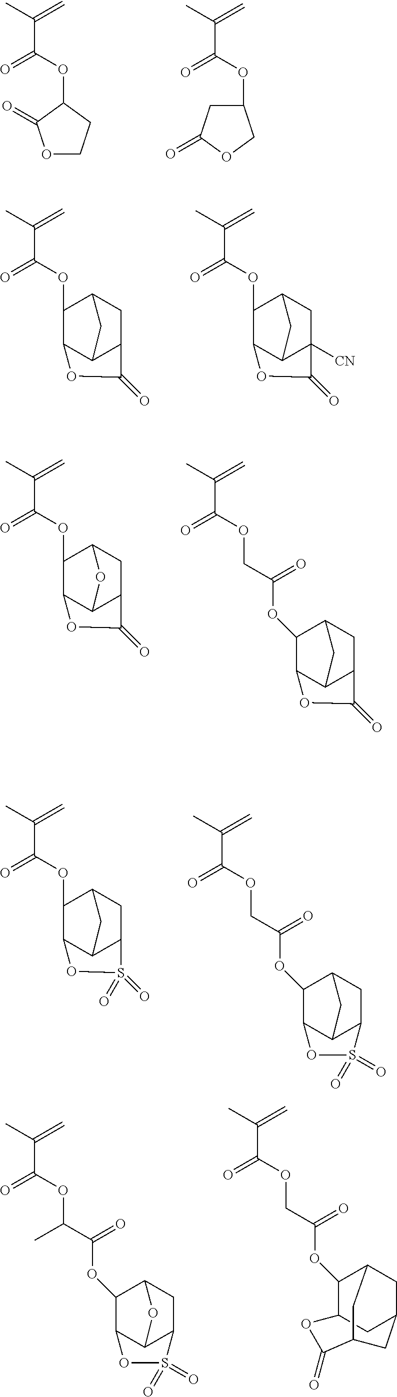

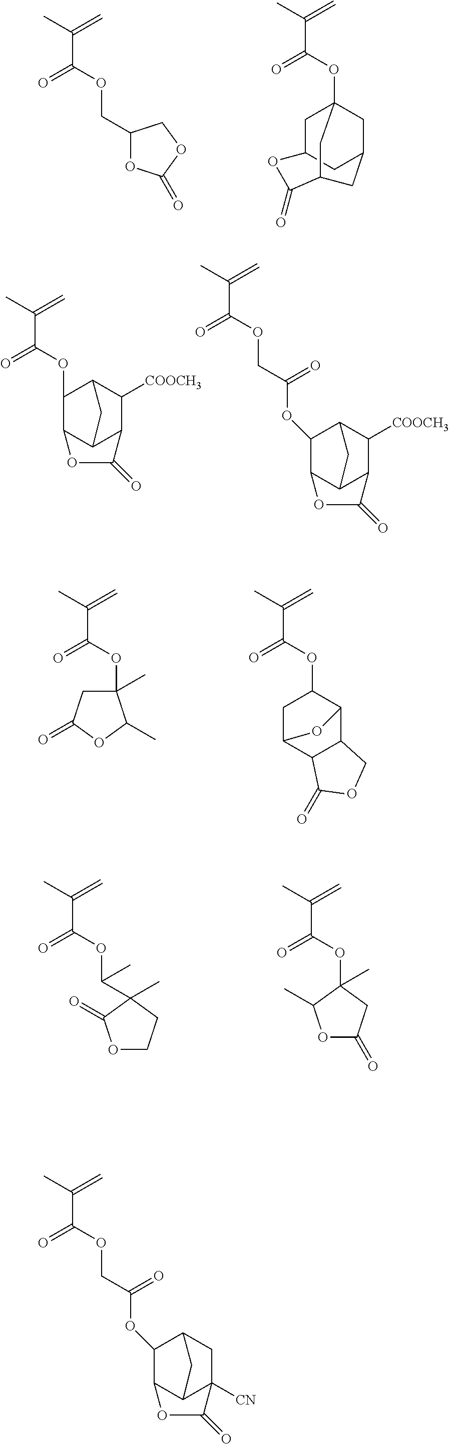

In addition to the monomers, monomers shown below are also suitably used as a raw material of the resin (A).

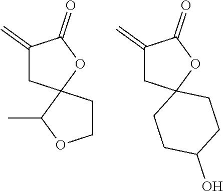

The content of the repeating unit having at least one selected from the group consisting of a lactone structure, a sultone structure, and a carbonate structure included in the resin (A) (a total of the contents in a case where a plurality of the repeating units having at least one selected from the group consisting of a lactone structure, a sultone structure, and a carbonate structure are present) is preferably 5% to 30% by mole, more preferably 10% to 30% by mole, and still more preferably 20% to 30% by mole, with respect to all the repeating units in the resin (A).

The resin (A) may further have a variety of repeating structural units, in addition to the repeating structural units, for the purpose of controlling dry etching resistance, suitability for a standard developer, adhesiveness to a substrate, and a resist profile, resolving power, heat resistance, sensitivity, and the like which are general characteristics required for a resist.

Examples of such a repeating structural unit include, but are not limited to, repeating structural units corresponding to a predetermined monomer.

Examples of such a predetermined monomer include a compound having one addition-polymerizable unsaturated bond, which is selected from acrylic acid esters, methacrylic acid esters, acrylamides, methacrylamides, allyl compounds, vinyl ethers, vinyl esters, and the like.

In addition to these, an addition-polymerizable unsaturated compound that is copolymerizable with the monomers corresponding to various repeating structural units as described above may be copolymerized.

In the resin (A), the molar ratio of each repeating structural unit contained is appropriately set in order to control various types of performance.

The resin (A) is preferably a resin in which all the repeating units are constituted with (meth)acrylate-based repeating units. In this case, any of a resin in which all of the repeating units are methacrylate-based repeating units, a resin in which all of the repeating units are acrylate-based repeating units, and a resin in which all of the repeating units are methacrylate-based repeating units and acrylate-based repeating units can be used, but it is preferable that the acrylate-based repeating units account for 50% by mole or less of all of the repeating units of the resin (A).

(Repeating Unit Having Aromatic Ring)

For the resin (A), at least one of the repeating units of the resin (A) is a repeating unit having an aromatic ring (Condition [4]).

For example, “the repeating unit having a structure (acid-decomposable group) in which a phenolic hydroxyl group is protected with a leaving group that leaves through decomposition by the action of an action” in the above-mentioned repeating unit B, and the above-mentioned repeating unit D (repeating unit having a phenolic hydroxyl group) correspond to the repeating unit having an aromatic ring.

That is, in the resin (A), an aromatic ring is included in at least one of the repeating unit A or the repeating unit B, or the resin (A) has a repeating unit having an aromatic ring (preferably, repeating unit D) other than the repeating unit A and the repeating unit B.

In the resin (A), the content of the repeating unit having an aromatic ring is, for example, 40% by mole or more, preferably 55% by mole or more, and more preferably 60% by mole or more with respect to all the repeating units in the resin (A) from the viewpoint that the etching resistance is more excellent. In addition, the upper limit thereof is not particularly limited, and is, for example, 97% by mole or less, preferably 85% by mole or less, and more preferably 80% by mole or less.

(Method for Polymerizing Resin (A))

The resin (A) can be synthesized in accordance with an ordinary method (for example, radical polymerization). Examples of the general synthesis method include (1) a bulk polymerization method in which polymerization is performed by dissolving monomer species and an initiator in a solvent and heating the solution, and (2) a dropwise addition polymerization method in which a solution of monomer species and an initiator is added dropwise to a heating solvent for 1 to 10 hours, with (2) the dropwise addition polymerization method being preferable.

Examples of the reaction solvent during polymerization include ethers such as tetrahydrofuran, 1,4-dioxane, and diisopropyl ether, ketones such as methyl ethyl ketone and methyl isobutyl ketone, ester solvents such as ethyl acetate, amides such as dimethyl formamide and dimethyl acetamide, and a solvent which dissolves the composition of the embodiment of the present invention, such as propylene glycol monomethyl ether acetate (PGMEA), propylene glycol monomethyl ether (PGME), and cyclohexanone, which will be described later. It is preferable to use the same solvent as the solvent used in the composition of the embodiment of the present invention. With this, generation of the particles during storage can be suppressed.

It is preferable that the polymerization reaction is performed in an inert gas atmosphere such as nitrogen and argon. As the polymerization initiator, a commercially available radical initiator (for example, an azo-based initiator and a peroxide) is used to initiate the polymerization. As the radical initiator, an azo-based initiator is preferable, and an azo-based initiator having an ester group, a cyano group, or a carboxy group is more preferable. Preferred examples of the initiator include azobisisobutyronitrile, azobisdimethylvaleronitrile, and dimethyl 2,2′-azobis(2-methyl propionate).

A polymerization initiator may be optionally added for the polymerization reaction, as described above. A method for adding the polymerization initiator into a system is not particularly limited, and it may be in either an aspect in which a polymerization initiator is added at once or an aspect in which a polymerization initiator is dividedly added in portionwise. During the polymerization reaction, the concentration of the solid content of the reaction solution is usually 5% to 60% by mass, and preferably 10% to 50% by mass. The reaction temperature is usually 10° C. to 150° C., preferably 30° C. to 120° C., and more preferably 60° C. to 100° C. After the reaction, a polymer is recovered by a method such as a method in which the reaction solution is put into a solvent, and a powder or a solid content is recovered.

The weight-average molecular weight of the resin (A) is preferably 1,000 to 200,000, more preferably 2,000 to 30,000, and still more preferably 3,000 to 25,000. The dispersity (Mw/Mn) is usually 1.0 to 3.0, preferably 1.0 to 2.6, more preferably 1.0 to 2.0, and still particularly preferably 1.1 to 2.0.

The resin (A) may be used singly or in combination of two or more kinds thereof.

The content of the resin (A) in the composition of the embodiment of the present invention is generally 20% by mass or more in many cases, and is preferably 40% by mass or more, more preferably 60% by mass or more, and still more preferably 80% by mass or more, with respect to the total solid content. The upper limit is not particularly limited, but is preferably 99.5% by mass or less, more preferably 99% by mass or less, and still more preferably 98% by mass or less.

<Resin (B)>

In a case where the composition of the embodiment of the present invention includes a crosslinking agent (G) which will be described later, it is preferable that the composition of the embodiment of the present invention includes an alkali-soluble resin (B) having a phenolic hydroxyl group (hereinafter also referred to as a “resin (B)”), which is different from the resin (A). The resin (B) preferably has a repeating unit having a phenolic hydroxyl group.

In this case, typically, the negative-tone pattern is suitably formed.

The crosslinking agent (G) max be in a form that is carried in the resin (B).

The resin (B) may have the above-mentioned acid-decomposable group.

As the repeating unit having a phenolic hydroxyl group contained in the resin (B), a repeating unit represented by General Formula (II) is preferable.

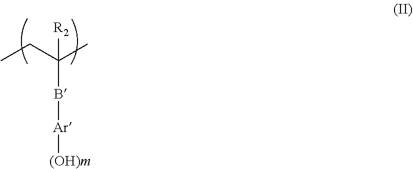

In General Formula (II),

R₂ represents a hydrogen atom, an alkyl group (preferably a methyl group), or a halogen atom (preferably a fluorine atom).

B′ represents a single bond or a divalent linking group.

Ar′ represents an aromatic ring group,

m represents an integer of 1 or more.

The resin (B) may be used singly or in combination of two or more kinds thereof.

The content of the resin (B) in the total solid content of the composition of the embodiment of the present invention is generally 30% by mass or more in many cases, and is preferably 40% by mass or more, and more preferably 50% by mass or more. The upper limit is not particularly limited, but is preferably 99% by mass or less, more preferably 90% by mass or less, and still more preferably 85% by mass or less.

Suitable examples of the resin (B) include the resins disclosed in paragraphs <0142> to <0347> of US2016/0282720A1.

The composition of the embodiment of the present invention may include both of the resin (A) and the resin (B).

<Photoacid Generator (C)>

It is preferable that the composition of the embodiment of the present invention typically a photoacid generator (hereinafter also referred to as “a photoacid generator (C)”).

The photoacid generator is a compound that generates an acid upon irradiation with actinic rays or radiation.

As the photoacid generator, a compound that generates an organic acid upon irradiation with actinic rays or radiation is preferable. Examples thereof include a sulfonium salt compound, an iodonium salt compound, a diazonium salt compound, a phosphonium salt compound, an imidesulfonate compound, an oximesulfonate compound, a diazodisulfone compound, a disulfone compound, and an o-nitrobenzyIsulfonate compound.

As the photoacid generator, known compounds that generate an acid upon irradiation with actinic rays or radiation can be appropriately selected and used singly or as a mixture thereof. For example, the known compounds disclosed in paragraphs <0125> to <0319> of US2016/0070167A1, paragraphs <0086> to <0094> of US2015/0004544A1, and paragraphs <0323> to <0402> of US2016/0237190A1 can be suitably used as the photoacid generator (C).

As the photoacid generator (C), for example, a compound represented by General Formula (ZI), General Formula (ZII), or General Formula (ZIII) is preferable.

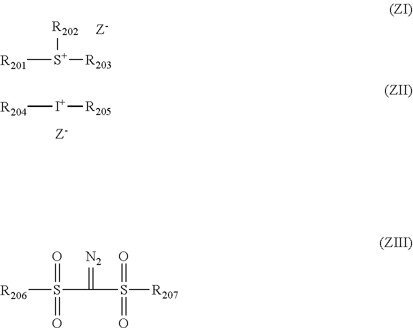

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group) and —CH₂—CH₂—O—CH₂—CH₂—.

Z₋ represents an anion (which is preferably a non-nucleophilic anion).

Suitable aspects of the cation in General Formula (ZI) include the corresponding groups in a compound (ZI-1), a compound (ZI-2), a compound (ZI-3), and a compound (ZI-4) which will be described later.

In addition, the photoacid generator (C) may also be a compound having a plurality of the structures represented by General Formula (ZI). For example, it may be a compound having a structure in which at least one of R₂₀₁, . . . , or R₂₀₃ in the compound represented by General Formula (ZI) is bonded to at least one of R₂₀₁, . . . , or R₂₀₁ of another compound represented by General Formula (ZI) through a single bond or a linking group.

First, the compound (ZI-1) will be described.

The compound (ZI-1) is an arylsulfonium compound in which at least one of R₂₀₁, . . . , or R₂₀₃ in General Formula (ZI) is an aryl group, a that is, a compound having arylsulfonium as a cation.

In the arylsulfonium compound, all of R₂₀₁ to R₂₀₃ may be aryl groups, or some of R₂₀₁ to R₂₀₃ may be aryl groups and the remainders may be alkyl groups or cycloalkyl groups.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium compound has two or more aryl groups, these two or more aryl groups may be the same as or different from each other.

The alkyl group or the cycloalkyl group which may be contained, as desired, in the arylsulfonium compound, is preferably a linear alkyl group having 1 to 15 carbon atoms, a branched alkyl group having 3 to 15 carbon atoms, or a cycloalkyl group having 3 to 15 carbon atoms, for example, a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of each of R₂₀₁ to R₂₀₃ may have an alkyl group (for example, an alkyl group having 1 to 15 carbon atoms), a cycloalkyl group (for example, a cycloalkyl group having 3 to 15 carbon atoms), an aryl group (for example, an aryl group having 6 to 14 carbon atoms), an alkoxy group (for example, an alkoxy group having 1 to 15 carbon atoms), a halogen atom, a hydroxyl group, or a phenylthio group as a substituent.

Next, the compound (ZI-2) will be described.

The compound (ZI-2) is a compound in which R₂₀₁ to R₂₀₃ in Formula (ZI) each independently represent an organic group not having an aromatic ring. Here, the aromatic ring also encompasses an aromatic ring containing a heteroatom. The organic group, as each of R₂₀₁ to R₂₀₃, containing no aromatic ring has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

Preferred examples of the alkyl group and the cycloalkyl group of each of R₂₀₁ to R₂₀₃ include a linear alkyl group having 1 to 10 carbon atoms or a branched alkyl group having 3 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group).

R₂₀₁ to R₂₀₃ may further be substituted with a halogen atom, an alkoxy group (for example, an alkoxy group having 1 to 5 carbon atoms), a hydroxyl group, a cyano group, or a nitro group.

Next, the compound (ZI-3) will be described.

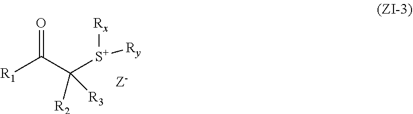

In General Formula (ZI-3), R₁ represents an alkyl group, a cycloalkyl group, an aryl group, or a benzyl group. In a case where R₁ has a ring structure, the ring structure may include an oxygen atom, a sulfur atom, an ester bond, an amide bond, or a carbon-carbon double bond.

R₂ and R₃ each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, an alkoxycarbonylalkyl group, an allyl group, or a vinyl group.

In addition, R> and R₃ may be bonded to each other to form a ring. Further, R₁ and R₂ may be bonded to each other to form a ring, and the ring thus formed may include a carbon-carbon double bond. In addition, Rₓ and R_{y} may be bonded to each other to form a ring, and the ring thus formed may include an oxygen atom, a sulfur atom, an ester bond, an amide bond, or a carbon-carbon double bond.

Z₋ represents an anion.

In General Formula (ZI-3), as each of the alkyl group and the cycloalkyl group represented by R₁, a linear alkyl group having 1 to 15 carbon atoms (preferably having 1 to 10 carbon atoms), a branched alkyl group having 3 to 15 carbon atoms (preferably having 3 to 10 carbon atoms), or a cycloalkyl group having 3 to 15 carbon atoms (preferably having 1 to 10 carbon atoms) is preferable, and specific examples of the alkyl group and the cycloalkyl group include a methyl group, an ethyl group, a propyl group, an n-butyl group, a sec-butyl group, a t-butyl group, a cyclopropyl group, a cyclobutyl group, a cyclohexyl group, and a norbornyl group.

As the aryl group represented by R₁, a phenyl group or a naphthyl group is preferable. and the phenyl group is more preferable. The aryl group may be an aryl group having a heterocyclic structure having an oxygen atom, a sulfur atom, or the like. Examples of the heterocyclic structure include a furan ring, a thiophene ring, a benzofuran ring, and a benzothiophene ring.

R₁ may further have a substituent (for example, a substituent group T).

In addition, in a case where R₁ has a ring structure, the ring structure may include an oxygen atom, a sulfur atom, an ester bond, an amide bond, or a carbon-carbon double bond.

Examples of the alkyl group, the cycloalkyl group, and the aryl group represented by each of R₂ and R₃ include the same ones as those of R₁ as mentioned above and preferred aspects thereof are also the same. In addition, R₂ and R₃ may be bonded to each other to form a ring.

Examples of the halogen atom represented by each of R₂ and R₃ include a fluorine atom, a chlorine atom, a bromine atom, and an iodine atom.

Examples of the alkyl group and the cycloalkyl group represented by each of Rₓ and R_{y} include the same ones as those of R₁ as mentioned above and preferred aspects thereof are also the same.

Examples of the 2-oxoalkyl group represented by each of Rₓ and R_{y} include a 2-oxoalkyl group example having 1 to 15 carbon atoms (preferably having 1 to 10 carbon atoms), and specific examples of the 2-oxoalkyl group include a 2-oxopropyl group and a 2-oxobutyl group.

Examples of the alkoxycarbonylalkyl group represented by each of Rₓ and R_{y} include an alkoxycarbonylalkyl group having 1 to 15 carbon atoms (preferably having 1 to 10 carbon atoms). Rₓ and R_{y} may be bonded to each other to form a ring.

In addition, Rₓ and R_{y} may be bonded to each other to form a ring structure, and the ring structure formed by the mutual linking of Rₓ and R_{y} may include an oxygen atom, a sulfur atom, an ester bond, an amide bond, or a carbon-carbon double bond.

In General Formula (ZI-3A), R₁ and R₂ may be bonded to each other to form a ring structure, and the ring structure thus formed may include a carbon-carbon double bond.

Among those, the compound (ZI-3) is preferably a compound (ZI-3A).

The compound (ZI-3A) is a compound represented by General Formula (ZI-3A), which has a phenacylsulfonium salt structure.

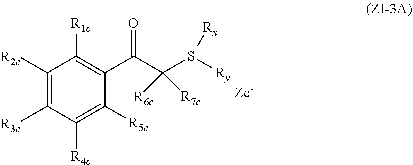

In General Formula (ZI-3A),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each have the same definitions as R₂ and R₃ in General Formula (ZI-3) described above and preferred aspects thereof are also the same.

Rₓ and R_{y} each have the same definitions as Rₓ and R_{y} in General Formula (ZI-3) described above and preferred aspects thereof are also the same.

Among any two or more of R_{1c} to R_{5c}, and Rₓ and R_{y} each may be bonded to each other to form a ring structure, and the ring structure may each independently include an oxygen atom, a sulfur atom, an ester bond, an amide bond, or carbon-carbon double bond. Further, R_{5c} and R_{6c}, and R_{5c} and Rₓ may be bonded to each other to form ring structures, and the ring structures each independently include a carbon-carbon double bond. In addition, R_{6c} and R_{7c} may be bonded to each other to form a ring structure.

Examples of the ring structure include an aromatic or non-aromatic hydrocarbon ring, an aromatic or non-aromatic heterocycle, or a polycyclic fused ring composed of two or more of these rings. Examples of the ring structure include 3- to 10-membered rings, and the ring structures are preferably 4- to 8-membered ring, and more preferably 5- or 6-membered rings.

Examples of groups formed by the bonding of any two or more of R_{1c} to R_{5c}, R_{6c} and R_{7c}, and Rₓ and R_{y} include a butylene group and a pentylene group.

As groups formed by the bonding of R_{5c} and R_{6c}, and R_{5c} and Rₓ, a single bond or an alkylene group is preferable. Examples thereof include a methylene group and an ethylene group.

Z_{c-} represents an anion.

Next, the compound (ZI-4) w ill be described.

The compound (ZI-4) is represented by General Formula (ZI-4).

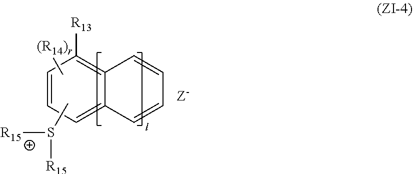

In General Formula (ZI-4),

1 represents an integer of 0 to 2. 1 is particularly preferably 0.

r represents an integer of 0 to 8.

R₁₃ represents a hydrogen atom, a fluorine atom, a hydroxyl group, an alkyl group, a cycloalkyl group, an alkoxy group, an alkoxycarbonyl group, or a group having a monocyclic or polycyclic cycloalkyl skeleton. These groups may have a substituent.

R₁₄ represents an alkyl group, a cycloalkyl group, an alkoxy group, an alkylsulfonyl group, a cycloalkylsulfonyl group, an alkylcarbonyl group, an alkoxycarbonyl group, or an alkoxy group having a monocyclic or polycyclic cycloalkyl skeleton. In a case where a plurality of R₁₄'s are present, R₁₄'s may be the same as or different from each other. These groups may have a substituent.

R₁₅'s each independently represent an alkyl group, a cycloalkyl group, or a naphthyl group. These groups may have a substituent. Two R₁₅'s may be bonded to each other to form a ring. In a case where two R₁₅'s are bonded to form a ring, the ring skeleton may include a heteroatom such as an oxygen atom and a nitrogen atom. In one aspect, it is preferable that two R₁₅'s are alkylene groups, and are bonded to each other to form a ring structure.

Z⁻ represents an anion.

In General Formula (ZI-4), as the alkyl group of each of R₁₃, R₁₄, and R₁₅, an alkyl which is linear or branched. The number of carbon atoms of the alkyl group is preferably 1 to 10. As the alkyl group, a methyl group, an ethyl group, an n-butyl group, a t-butyl group, or the like is more preferable. The number of ring members is particularly preferably 5 or 6.

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

As the aryl group of each of R₂₀₄ to R₂₀₇, a phenyl group or a naphthyl group is preferable, and the phenyl group is more preferable. The aryl group of each of R₂₀₄ to R₂₀₇ may be an aryl group having a heterocyclic structure having an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferred examples of the alkyl group and the cycloalkyl group in each of R₂₀₄ to R₂₀₇ include a linear alkyl group having 1 to 10 carbon atoms or a branched alkyl group having 3 to 10 carbon atoms (for example, a methyl group, an ethyl group, a propyl group, a butyl group, and a pentyl group), and a cycloalkyl group having 3 to 10 carbon atoms (a cyclopentyl group, a cyclohexyl group, and a norbornyl group).

The alkyl group, the alkyl group, and the cycloalkyl group of each of R₂₀₄ to R₂₀₁ may each independently have a substituent. Examples of the substituent which the aryl group, the alkyl group, or the cycloalkyl group of each of R₂₀₄ to R₂₀₁ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z₋ represents an anion.

As Z₋ in General Formula (ZI), Z₋ in General Formula (ZII), Z₋ in General Formula (ZI-3), and Z₋ in General Formula (ZI-4), an anion represented by General Formula (3) is preferable.

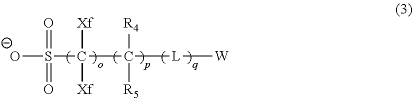

In General Formula (3),

o represents an integer of 1 to 3. p represents an integer of 0 to 10. q represents an integer of 0 to 10.

Xf's each independently represent a fluorine atom or an alkyl group substituted with at least one fluorine atom. The number of carbon atoms of the alkyl group is preferably 1 to 10, and more preferably 1 to 4. Further, as the alkyl group substituted with at least one fluorine atom, a perfluoroalkyl group is preferable.

Xf is preferably a fluorine atom or a perfluoroalkyl group having 1 to 4 carbon atoms, and more preferably a fluorine atom or CF₃. In particular, it is still more preferable that both Xf's are fluorine atoms.

R₄ and R₅ each independently represent a hydrogen atom, a fluorine atom, an alkyl group, or an alkyl group substituted with at least one fluorine atom. In a case where a plurality of each of R₄'s and R₅'s are present, R₄'s and R₅'s may be the same as or different from each other.

The alkyl group represented by each of R₄ and R₅ may have a substituent, and preferably has 1 to 4 carbon atoms. R₄ and R₅ are each preferably a hydrogen atom.

Specific examples and suitable embodiments of the alkyl group substituted with at least one fluorine atom are the same as the specific examples and suitable embodiments of Xf in General Formula (3).

L represents a divalent linking group. In a case where a plurality of L's are present, L's may be the same as or different from each other.

Examples of the divalent linking group include —COO—(—C(═O)—O—), —OCO—, —CONH—, —NHCO—, —CO—, —O—, —S—, —SO—. —SO₂—, an alkylene group (preferably having 1 to 6 carbon atoms), a cycloalkylene group (preferably having 3 to 15 carbon atoms), an alkenylene group (preferably having 2 to 6 carbon atoms), or a divalent linking group formed by combination of these plurality of groups. Among these, —COO—, —OCO—, —CONH—, —NHCO—, —CO—, —O—, —SO₂—, —COO-alkylene group-, —OCO-alkylene group-, —CONH-alkylene group-, or —NHCO— alkylene group- is preferable, and —COO—, —OCO—, —CONH—, —SO₂—, —COO-alkylene group-, or —OCO-alkylene group- is more preferable.

W represents an organic group including a cyclic structure. Among these, a cyclic organic group is preferable.

Examples of the cyclic organic group include an alicyclic group, an aryl group, and a heterocyclic group.

The alicyclic group may be monocyclic or polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among these, an alicyclic group having a bulky structure having 7 or more carbon atoms, such as a norbornyl group, a tricyclodecanyl group, a tetracyclodecanyl group, a tetracyclododecanyl group, and an adamantyl group is preferable.

The aryl group may be monocyclic or polycyclic. Examples of the aryl group include a phenyl group, a naphthyl group, a phenanthryl group, and an anthryl group.

The heterocyclic group may be monocyclic or polycyclic. In a case where it is polycyclic, it is possible to suppress acid diffusion. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having an aromaticity include a tetrahydropyran ring, a lactone ring, a sultone ring, and a decahydroisoquinoline ring. Examples of the lactone ring and the sultone ring include the above-mentioned lactone structures and sultone structures exemplified in the resin. As the heterocycle in the heterocyclic group, a furan ring, a thiophene ring, a pyridine ring, or a decahydroisoquinoline ring is particularly preferable.

The cyclic organic group may have a substituent. Examples of the substituent include, an alkyl group (which may be linear or branched, and preferably has 1 to 12 carbon atoms), a cycloalkyl group (which may be any one of a monocycle, a polycycle, and a spiro ring, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (carbon contributing to ring formation) may be carbonyl carbon.

As the anion represented by General Formula (3), SO₃⁻—CF₂—CH₂—OCO-(L)q′-W, SO₃⁻—CF₂—CHF—CH₂—OCO-(L)q′-W, SO₃—CF₂—COO-(L)q′-W, SO₃⁻—CF₂—CF₂—CH₂—CH₂-(L)q-W, or SO₃⁻—CF₂—CH(CF₃)—OCO-(L)q′-W is preferable. Here, L, q, and W are each the same as in General Formula (3). q′ represents an integer of 0 to 10.

In one aspect, as Z⁻ in General Formula (ZI), Z⁻ in General Formula (ZII), Z₋ in General Formula (ZI-3), and Z⁻ in General Formula (ZI-4), an anion represented by General Formula (4) is also preferable.

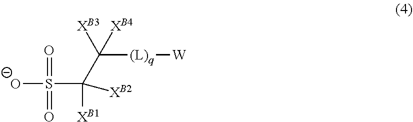

In General Formula (4),

X^{B1} and X^{B2} each independently represent a hydrogen atom or a monovalent organic group having no fluorine atom. X^{B1} and X^{B2} are each preferably a hydrogen atom.

X^{B3} and X^{B4} each independently represent a hydrogen atom or a monovalent organic group. It is preferable that at least one of X^{B3} or X^{B4} is a fluorine atom or a monovalent organic group having a fluorine atom, and it is more preferable that both of X^{B3} and X^{B4} are a fluorine atom or a monovalent organic group having a fluorine atom. It is still more preferable that X^{B3} and X^{B4} are both an alkyl group substituted with a fluorine atom.

L, q, and W are the same as in General Formula (3).

Z⁻ in General Formula (ZI), Z⁻ in General Formula (ZII), Z_{c}⁻ in General Formula (ZI-3), and Z⁻ in General Formula (ZI-4) may be a benzenesulfonic acid anion, and is preferably a benzenesulfonic acid anion substituted with a branched alkyl group or a cycloalkyl group.

As Z⁻ in General Formula (ZI), Z⁻ in General Formula (ZII), Z⁻ in General Formula (ZI-3), and Z in General Formula (ZI-4), an aromatic sulfonic acid anion represented by General Formula (SA1) is also preferable.

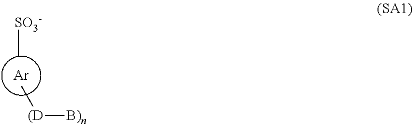

In Formula (SA1),

Ar represents an aryl group and may further have a substituent other than a sulfonic acid anion and a -(D-B) group. Examples of the substituent that may further be contained include a fluorine atom and a hydroxyl group.

n represents an integer of 0 or more. n is preferably 1 to 4, more preferably 2 or 3, and still more preferably 3.

D represents a single bond or a divalent linking group. Examples of the divalent linking group include an ether group, a thioether group, a carbonyl group, a sulfoxide group, a sulfone group, a sulfonic acid ester group, an ester group, and a group formed by combination of two or more kinds of these groups.

B represents a hydrocarbon group.

It is preferable that D is a single bond and B is an aliphatic hydrocarbon structure. It is more preferable that B is an isopropyl group or a cyclohexyl group.

Preferred examples of the sulfonium cation in General Formula (ZI) and the iodonium cation in General Formula (ZII) are shown below.

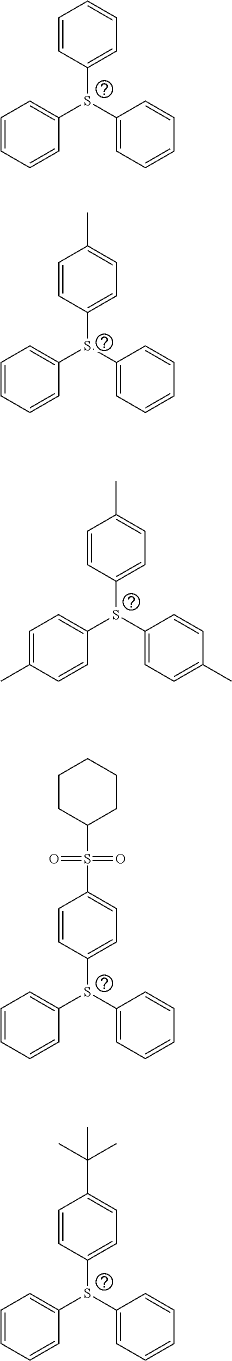

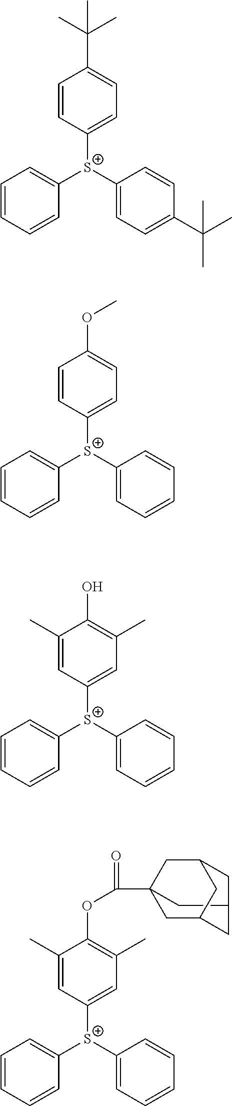

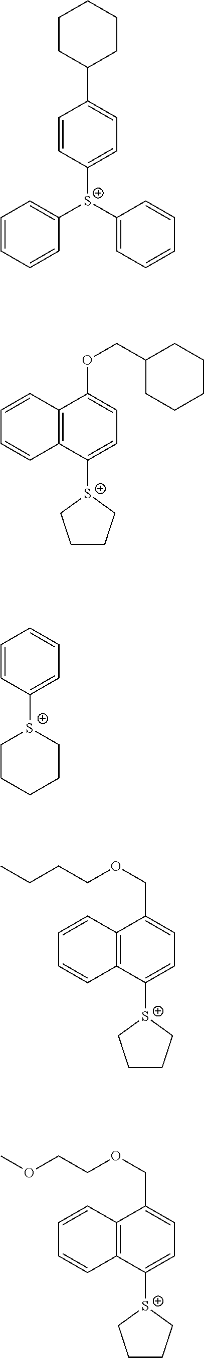

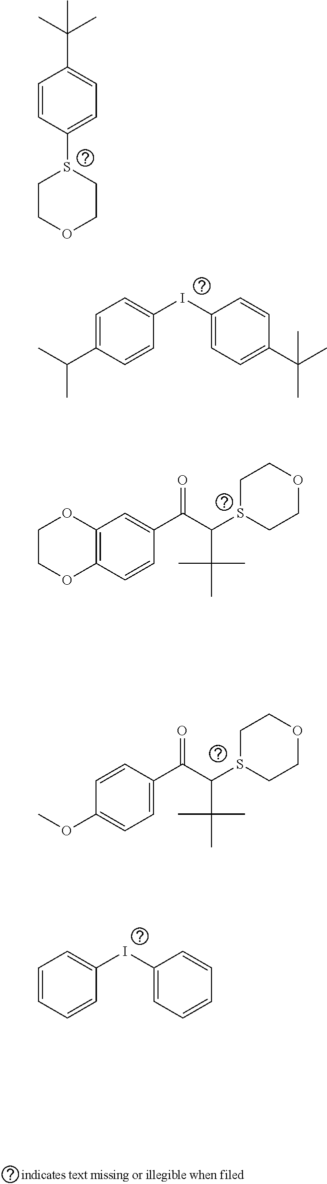

Preferred examples of the anion Z⁻ in General Formula (ZI) and General Formula (ZII), Z⁻ in General Formula (ZI-3), and Z⁻ in General Formula (ZI-4) are shown below.

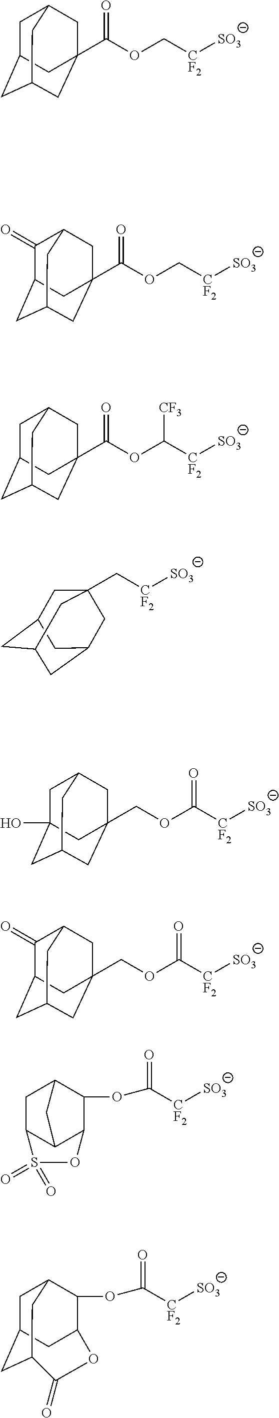

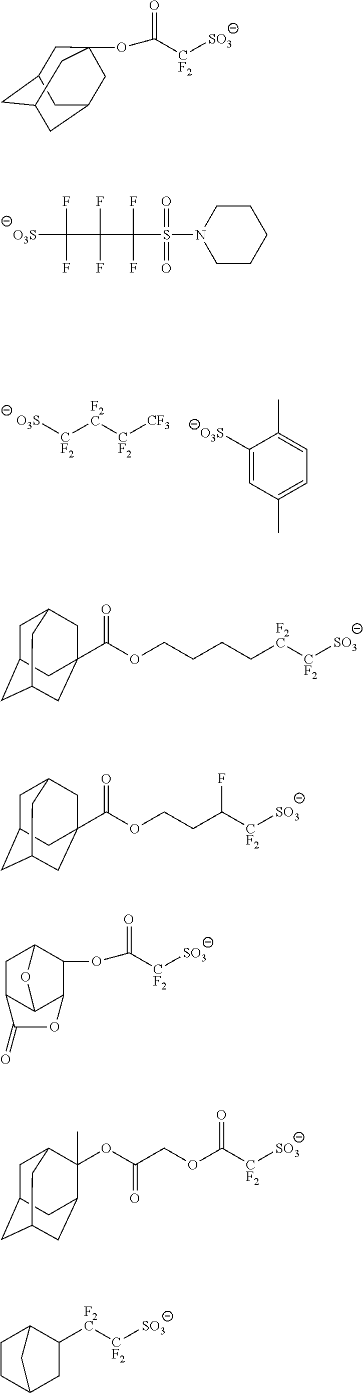

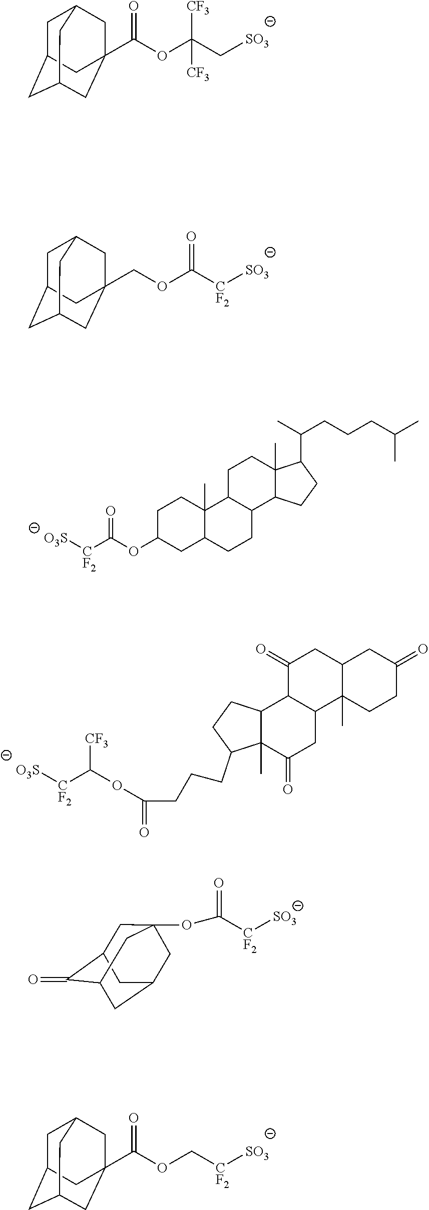

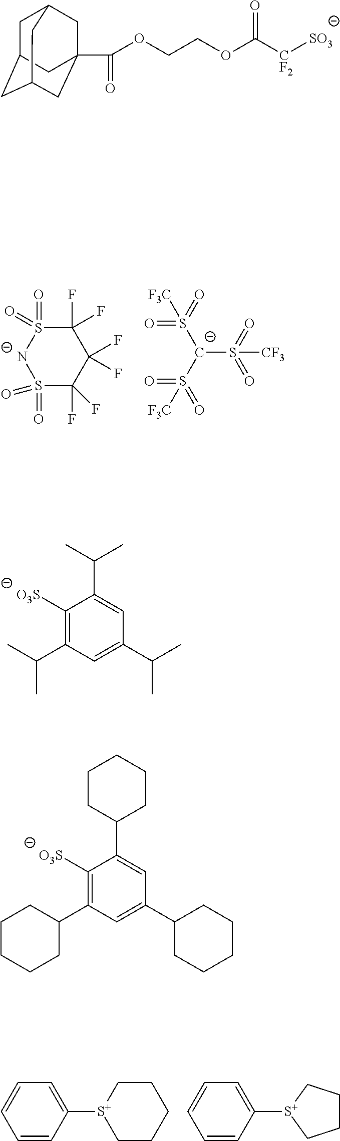

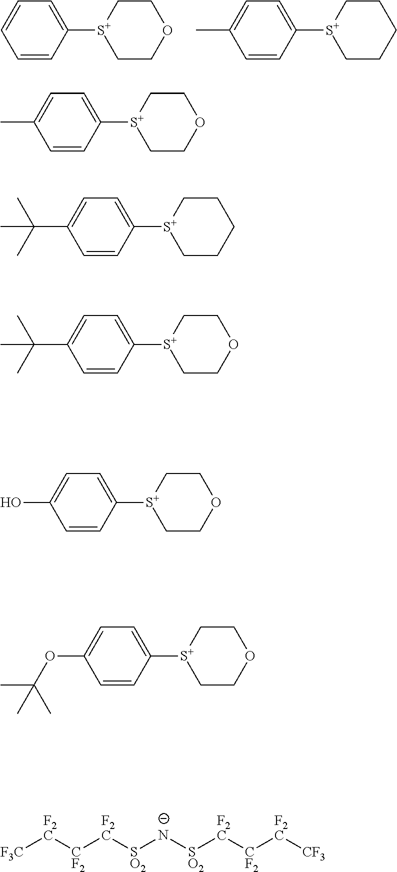

The cation and the anion can be optionally combined and used as a photoacid generator.

The photoacid generator may be in a form of a low-molecular-weight compound or in a form incorporated into a part of a polymer. Further, the form of a low-molecular-weight compound and the form incorporated into a part of a polymer may also be used in combination.

In the present invention, the photoacid generator is preferably in the form of the low-molecular-weight compound.

In a case where the photoacid generator is in the form of the low-molecular-weight compound, the molecular weight is preferably 3,000 or less, more preferably 2,000 or less, and still more preferably 1,000 or less.

In a case where the photoacid generator is in the form incorporated into a part of a polymer, it may be incorporated into the above-mentioned resin (A) or into a resin other than the resin (A).

The photoacid generators may be used singly or in combination of two or more kinds thereof.

The content of the photoacid generator (a total content in a case where a plurality of the photoacid generators are present) in the composition of the embodiment of the present invention is preferably 0.1%6 to 35%6 by mass, more preferably 0.5% to 25% by mass, still more preferably 1% to 20% by mass, and particularly preferably 1% to 15% by mass with respect to the total solid contents of the composition.

In a case where the compound represented by General Formula (ZI-3) or (ZI-4) is contained as the photoacid generator, the content of the photoacid generator (a total content in a case where a plurality of the photoacid generators are present) included in the composition is preferably 1%6 to 35% by mass, and more preferably 1% to 30% by mass with respect to the total solid contents of the composition.

<Acid Diffusion Control Agent (D)>

The composition of the embodiment of the present invention preferably contains an acid diffusion control agent (D). The acid diffusion control agent (D) acts as a quencher that inhibits a reaction of the acid-decomposable resin in the unexposed area by excessive generated acids by trapping the acids generated from a photoacid generator or the like upon exposure. For example, a basic compound (DA), a basic compound (DB) whose basicity is reduced or lost upon irradiation with actinic rays or radiation, an onium salt (DC) which becomes a relatively weak acid with respect to a photoacid generator, a low-molecular-weight compound (DD) which has a nitrogen atom and a group that leaves by the action of an acid, an onium compound (DE) having a nitrogen atom in a cationic moiety, or the like can be used as the acid diffusion control agent. In the composition of the embodiment of the present invention, a known acid diffusion control agent can be appropriately used. For example, the known compounds disclosed in paragraphs <0627> to <0664> of US2016/0070167A1, paragraphs <0095> to <0187> of US2015/0004544A1, paragraphs <0403> to <0423> of US2016/0237190AI, and paragraphs <0259> to <0328> of US2016/0274458A1 can be suitably used as the acid diffusion control agent (D).

As the basic compound (DA), compounds having structures represented by Formulae (A) to (E) are preferable.

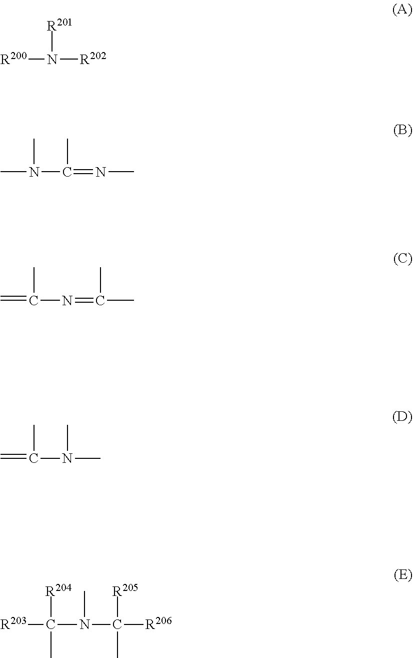

In General Formulae (A) and (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms). R²⁰¹ and R²⁰² may be bonded to each other to form a ring.

R²⁰³, R²⁰⁴, R²⁰⁵, and R²⁰⁶ may be the same as or different from each other, and each represent an alkyl group having 1 to 20 carbon atoms.

The alkyl group in each of General Formulae (A) and (E) may have a substituent or may be unsubstituted.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in each of General Formulae (A) and (E) are more preferably unsubstituted.

As the basic compound (DA), guanidine, aminopyrrolidine, pyrazole, pyrazoline, piperazine, aminomorpholine, aminoalkylmorpholine, piperidine, or the like is preferable: and a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond, or the like is more preferable.

The basic compound (DB) whose basicity is reduced or lost upon irradiation with actinic rays or radiation (hereinafter also referred to as a “compound (DB)”) is a compound which has a proton-accepting functional group, and decomposes under irradiation with actinic rays or radiation to exhibit deterioration in proton-accepting properties, no proton-accepting properties, or a change from the proton-accepting properties to acidic properties.

The proton-accepting functional group refers to a functional group having a group or an electron which is capable of electrostatically interacting with a proton, and for example, means a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by the following formula.

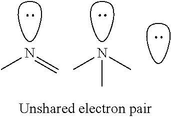

Preferred examples of the partial structure of the proton-accepting functional group include a crown ether structure, an azacrown ether structure, primary to tertiary amine structures, a pyridine structure, an imidazole structure, and a pyrazine structure.

The compound (DB) decomposes upon irradiation with actinic rays or radiation to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is generated from the compound (DB) having the proton-accepting functional group and the proton.

The proton-accepting properties can be confirmed by performing pH measurement.

In the present invention, the acid dissociation constant pKa of the compound generated by the decomposition of the compound (DB) upon irradiation with actinic rays or radiation preferably satisfies pKa<−1, more preferably −13<pKa<−1, and still more preferably −13<pKa<−3.

The acid dissociation constant pKa as mentioned herein refers to an acid dissociation constant pKa in an aqueous solution, and is defined, for example, in Chemical Handbook (II) (Revised 4^{th} Edition, 1993, compiled by the Chemical Society of Japan, Maruzen Company, Ltd.). A lower value thereof indicates higher acid strength. Specifically, the acid dissociation constant pKa in an aqueous solution may be measured by using an infinite-dilution aqueous solution and measuring the acid dissociation constant at 25° C. Alternatively, the acid dissociation constant pKa can also be determined using the following software package 1, by computation from a value based on a Hammett substituent constant and the database of publicly known literature values. Any of the values of pKa described in the present specification represent values determined by calculation using the software package.

Software package 1: Advanced Chemistry Development (ACD/Labs) Software V8.14 for Solaris (I 994-2007 ACD/Labs).

In the composition of the embodiment of the present invention, an onium salt (DC) which becomes a relatively weak acid with respect to the photoacid generator can be used as an acid diffusion control agent.

In a case of mixing the photoacid generator and the onium salt capable of generating an acid which is a relatively weak acid with respect to an acid generated from the photoacid generator, and then using the mixture, in a case where the acid generated from the photoacid generator upon irradiation with actinic rays or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is deactivated in appearance, and thus, it is possible to carry out the control of acid diffusion.

As the onium salt which becomes a relatively weak acid with respect to the photoacid generator, compounds represented by General Formulae (dl-1) to (dl-3) are preferable.

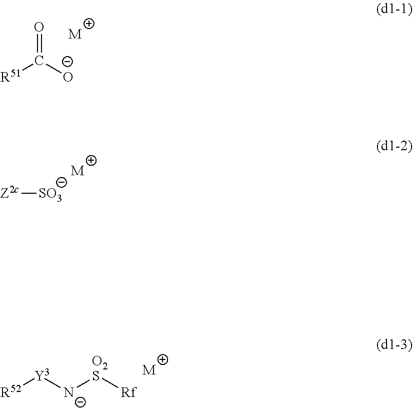

In the formulae, R⁵¹ is a hydrocarbon group which may have a substituent, Z^{2c} is a hydrocarbon group (provided that carbon adjacent to S is not substituted with a fluorine atom) having 1 to 30 carbon atoms, which may have a substituent. R⁵² is an organic group, Y³ is a linear, branched, or cyclic alkylene group or arylene group, Rf is a hydrocarbon group including a fluorine atom, and M+'s are each independently an ammonium cation, a sulfonium cation, or an iodonium cation.

Preferred examples of the sulfonium cation or the iodonium cation represented by M⁺ include the sulfonium cations exemplified for General Formula (ZI) and the iodonium cations exemplified for General Formula (ZII) of the photoacid generator.

The onium salt (DC) which becomes a relatively weak acid with respect to the photoacid generator may be a compound (hereinafter also referred to as a “compound (DCA)”) having a cationic moiety and an anionic moiety in the same molecule, in which the cationic moiety and the anionic moiety are linked to each other through a covalent bond.

As the compound (DCA), a compound represented by any one of General Formulae (C-1), . . . , or (C-3) is preferable.

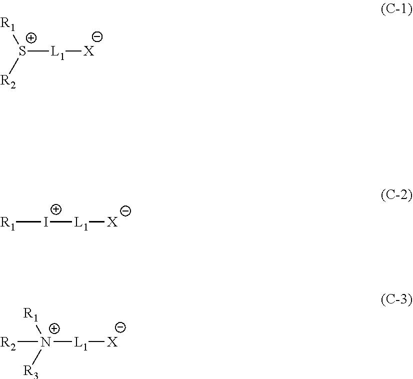

In General Formulae (C-1) to (C-3),

R₁, R₂, and R₃ represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, —SO₂⁻, and —N⁻—R₄. R₄ represents a monovalent substituent having a carbonyl group: —C(═O)—, a sulfonyl group: —S(═O)₂—, or a sulfinyl group: —S(═O)— at a site for linking to an adjacent N atom. R₁, R₂, R₃, R₄, and L₁ may be bonded to one another to form a ring structure. Further, in General Formula (C-3), two of R₁ to R₃ may be combined to represent a divalent substituent or R₁ to R₃ may be bonded to an N atom through a double bond.

Examples of the substituent having 1 or more carbon atoms in each of R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group. The substituent is preferably an alkyl group, a cycloalkyl group, or an aryl group.

Examples of L₁ as a divalent linking group include a linear or branched alkylene group, a cycloalkylene group, an arylene group, a carbonyl group, an ether bond, ester bond, amide bond, a urethane bond, a urea bond, and a group formed by a combination of two or more kinds of these groups. L₁ is preferably an alkylene group, an arylene group, an ether bond, ester bond, and a group formed by a combination of two or more kinds of these groups.

The low-molecular-weight compound (DD) (hereinafter referred to as a “compound (DD)”) which has a nitrogen atom and a group that leaves by the action of an acid is preferably an amine derivative having a group that leaves by the action of an acid on a nitrogen atom.

As the group that leaves by the action of an acid, an acetal group, a carbonate group, a carbamate group, a tertiary ester group, a tertiary hydroxyl group, or a hemiaminal ether group are preferable, and a carbamate group or a hemiaminal ether group is particularly preferable.

The molecular weight of the compound (DD) is preferably 100 to 1,000, more preferably 100 to 700, and still more preferably 100 to 500.

The compound (DD) may have a carbamate group having a protecting group on a nitrogen atom. The protecting group constituting the carbamate group is represented by General Formula (d-1).

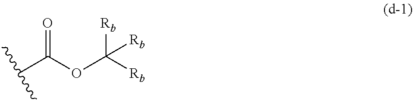

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be bonded to each other to form a ring.

The alkyl group, the cycloalkyl group, the aryl group, or the aralkyl group represented by R_{b} may be substituted with a functional group such as a hydroxyl group, a cyano group, an amino group, a pyrrolidino group, a piperidino group, a morpholino group, and an oxo group, an alkoxy group, or a halogen atom. This shall apply to the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by the mutual linking of two Rb's include an alicyclic hydrocarbon group, an aromatic hydrocarbon group, a heterocyclic hydrocarbon group, and derivatives thereof.

Examples of the specific structure of the group represented by General Formula (d-1) include, but are not limited to, the structures disclosed in paragraph <0466> in US2012/0135348A1.

It is preferable that the compound (DD) has a structure represented by General Formula (6).

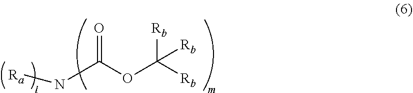

In General Formula (6).

1 represents an integer of 0 to 2, and m represents an integer of 1 to 3, satisfying l+m=3.

Rₐ represents a hydrogen atom, an alkyl group, a cycloalkyl group, an aryl group, or an aralkyl group. In a case where 1 is 2, two Rₐ's may be the same as or different from each other, and two Rₐ's may be linked to each other to form a heterocycle, together with the nitrogen atom in the formula. The heterocycle may include a heteroatom other than the nitrogen atom in the formula.

R_{b} has the same meaning as R_{b} in General Formula (d-1), and preferred examples are also the same.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (these groups may be substituted with the groups as described above) of Rₐ include the same groups as the specific examples as described above with respect to R_{b}.

Specific examples of the particularly preferred compound (DD) in the present invention include, but are not limited to, the compounds disclosed in paragraph <0475> in US2012/0135348A1.

The onium salt compound (DE) (hereinafter also referred to as a “compound (DE)”) having a nitrogen atom in a cation portion is preferably a compound having a basic moiety including a nitrogen atom in a cation portion. The basic moiety is preferably an amino group, and more preferably an aliphatic amino group. It is more preferable that all of the atoms adjacent to the nitrogen atom in the basic moiety are hydrogen atoms or carbon atoms. Further, from the viewpoint of improvement of basicity, it is preferable that an electron-withdrawing functional group (a carbonyl group, a sulfonyl group, a cyano group, a halogen atom, and the like) is not directly linked to the nitrogen atom.

Specific preferred examples of the compound (DE) include, but are not limited to, the compounds disclosed in paragraph <0203> of US2015/0309408A1.

Preferred examples of the acid diffusion control agent (D) are shown below.

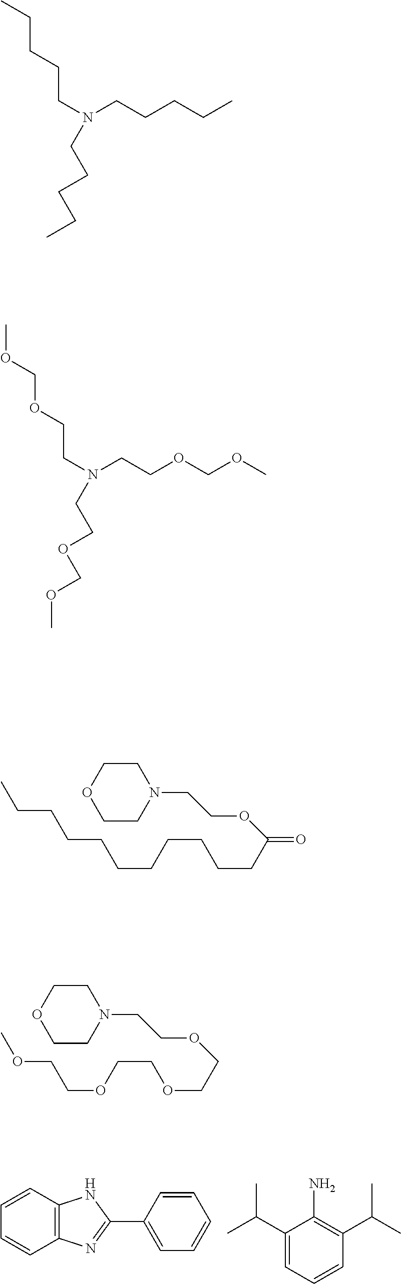

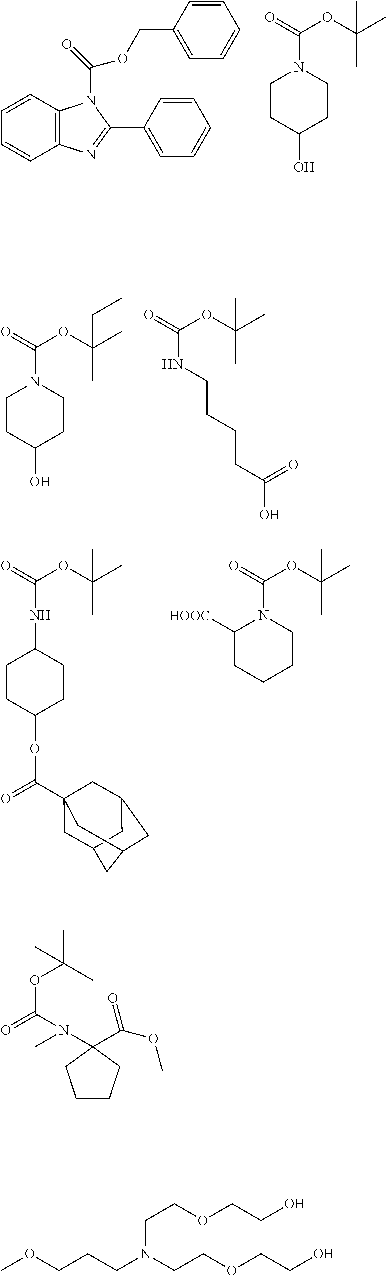

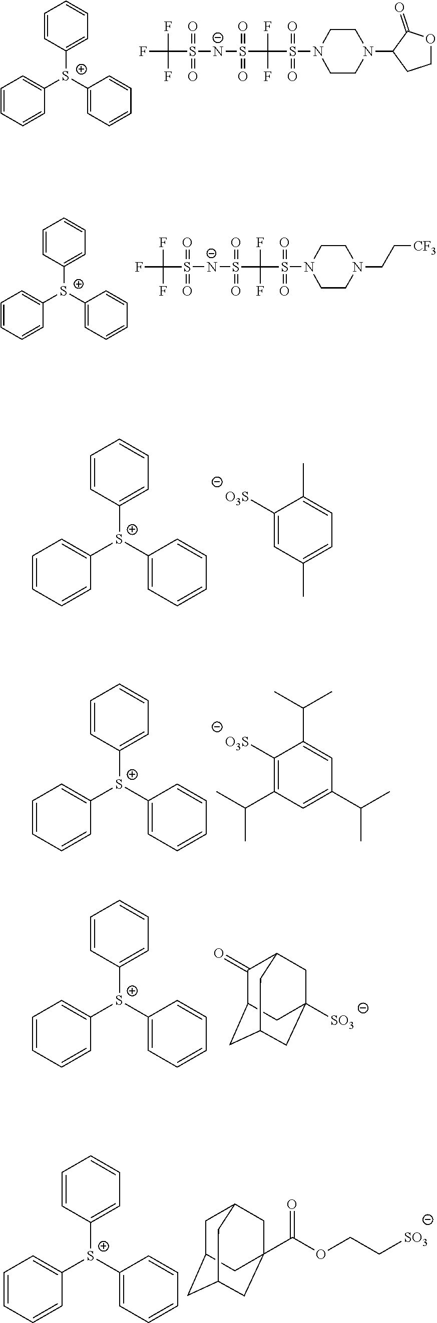

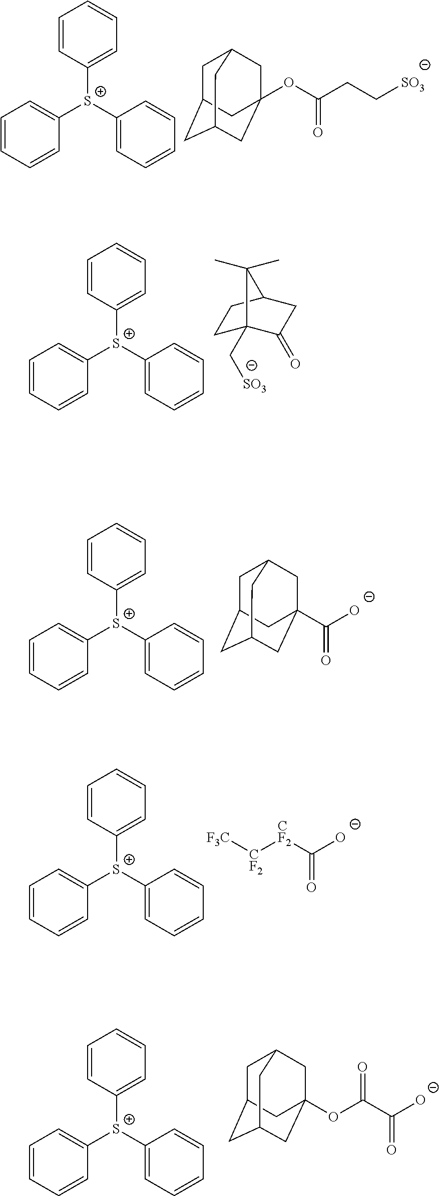

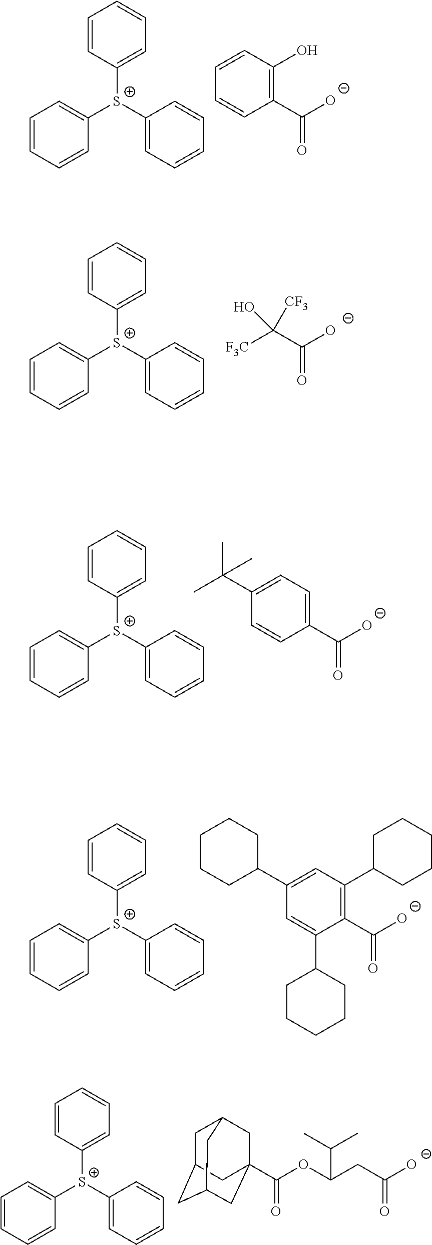

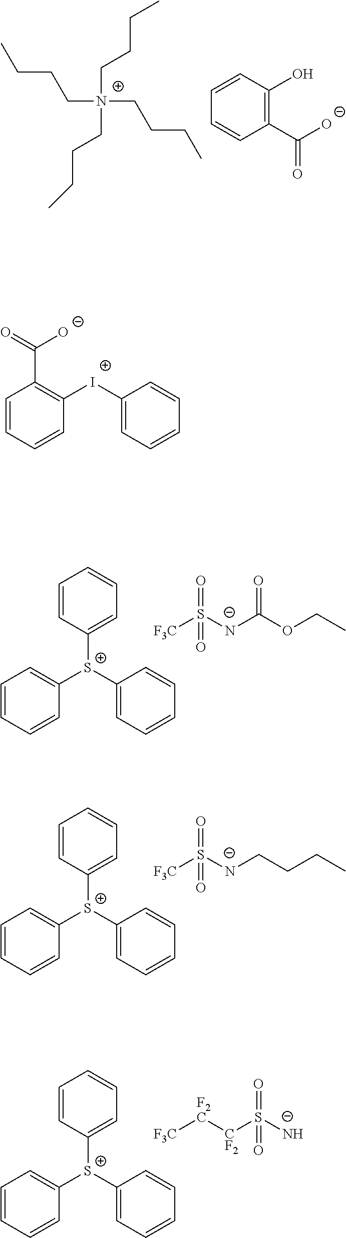

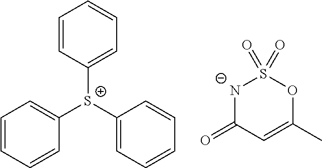

In the composition of the embodiment of the present invention, the acid diffusion control agent (D) may be used singly or in combination of two or more kinds thereof.

The content of the acid diffusion control agent (D) (a total content in a case where a plurality of the acid diffusion control agents (D) are present) in the composition is preferably 0.05% to 10% by mass, and more preferably 0.05% to 5% by mass with respect to the total solid content of the composition.

<Hydrophobic Resin (E)>

The composition of the embodiment of the present invention preferably contains a hydrophobic resin (E). Further, the hydrophobic resin (E) is preferably a resin which is different from the resin (A) and the resin (B).

By incorporating the hydrophobic resin (E) into the composition of the embodiment of the present invention, it is possible to improve the static/dynamic contact angle at a surface of an actinic ray-sensitive or radiation-sensitive film. Thus, it becomes possible to improve development characteristics, suppress generation of out gas, improve immersion liquid tracking properties upon immersion liquid exposure, and reduce liquid immersion defects, for example.

It is preferable that the hydrophobic resin (E) is designed to be unevenly distributed on a surface of a resist film, but unlike the surfactant, the hydrophobic resin (E) does not necessarily have a hydrophilic group in a molecule thereof and does not necessarily contribute to uniform mixing of polar/non-polar materials.

The hydrophobic resin (E) is preferably a resin having a repeating unit having at least one selected from a “fluorine atom”, a “silicon atom”, or a “CH₃ partial structure which is contained in a side chain portion of a resin” from the viewpoint of uneven distribution on a film surface layer, and more preferably has two or more types.

In a case where the hydrophobic resin (E) includes a fluorine atom and/or a silicon atom, the fluorine atom and/or the silicon atom described above in the hydrophobic resin (E) may be included in the main chain of a resin or may be included in a side chain.

In a case where the hydrophobic resin (E) includes a fluorine atom, it is preferably a resin which has an alkyl group having a fluorine atom, a cycloalkyl group having a fluorine atom, or an aryl group having a fluorine atom as a partial structure having a fluorine atom.

It is preferable that the hydrophobic resin (E) has at least one group selected from the following (x) to (z) groups:

(x) an acid group,

(y) a group whose solubility in an alkali developer through decomposition by the action of the alkali developer (hereinafter also referred to as a polarity converting group), and

(z) a group capable of decomposing by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonylXalkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

As the acid group, a fluorinated alcohol group (preferably hexafluoroisopropanol group), a sulfonimido group, or a bis(alkylcarbonyl)methylene group is preferable.

Examples of the group (y) whose solubility in an alkali developer through decomposition by the action of the alkali developer include a lactone group, a carboxylic acid ester group (—COO—), an acid anhydride group (—C(O)OC(O)—), an acid imido group (—NHCONH—), a carboxylic acid thioester group (—COS—), a carbonate ester group (—OC(O)O—), a sulfuric acid ester group (—OSO₂O—), and a sulfonic acid ester group (—SO₂O—), and the lactone group or the carboxylic acid ester group (—COO—) is preferable.

Examples of the repeating unit including the group include a repeating unit in which the group is directly bonded to the main chain of a resin, such as a repeating unit with an acrylic acid or a methacrylic acid. In this repeating unit, the group may be bonded to the main chain of the resin through a linking group. Alternatively, the group may also be incorporated into a terminal of the resin by using a polymerization initiator or chain transfer agent having the group during polymerization.

Examples of the repeating unit having a lactone group include the same ones as the repeating unit having a lactone structure as described earlier in the section of the resin (A).

The content of the group (y) whose solubility in an alkali developer through decomposition by the action of the alkali developer is preferably 1% to 100% by mole, more preferably 3% to 98% by mole, and still more preferably 5% to 95% by mole, with respect to all the repeating units in the hydrophobic resin (E).

With respect to the hydrophobic resin (E), examples of the repeating unit having a group (z) capable of decomposing by the action of an acid include the same ones as the repeating units having an acid-decomposable group, as exemplified in the resin (A). The repeating unit having a group (z) capable of decomposing by the action of an acid may have at least one of a fluorine atom or a silicon atom. The content of the repeating units having a group (z) capable of decomposing by the action of an acid is preferably 1% to 80% by mole, more preferably 10% to 80% by mole, and still more preferably 20% to 60% by mole, with respect to all the repeating units in the hydrophobic resin (E).

The hydrophobic resin (E) may have a repeating unit which is different from the above-mentioned repeating units.

The content of the repeating units including a fluorine atom is preferably 10% to 100% by mole, and more preferably 30% to 100% by mole, with respect to all the repeating units in the hydrophobic resin (E). Further, the content of the repeating units including a silicon atom is preferably 10% to 100% by mole, and more preferably 20% to 100% by mole, with respect to all the repeating units in the hydrophobic resin (E).

On the other hand, in a case where the hydrophobic resin (E) includes a CH₃ partial structure in the side chain moiety thereof, it is also preferable that the hydrophobic resin (E) has a form not having substantially any one of a fluorine atom and a silicon atom. Further, it is preferable that the hydrophobic resin (E) is substantially constituted with only repeating units, which are composed of only atoms selected from a carbon atom, an oxygen atom, a hydrogen atom, a nitrogen atom, and a sulfur atom.

The weight-average molecular weight of the hydrophobic resin (E) in terms of standard polystyrene is preferably 1,000 to 100,000, and more preferably 1,000 to 50,000.

The total content of residual monomers and/or oligomer components included in the hydrophobic resin (E) is preferably 0.01% to 5% by mass, and more preferably 0.01% to 3% by mass. Further, the dispersity (Mw/Mn) is preferably in the range of 1 to 5, and more preferably in the range of 1 to 3.

As the hydrophobic resin (E), known resins can be appropriately selected and used singly or as a mixture. For example, the known resins disclosed in paragraphs <0451> to <0704> of US2015/0168830A1 and paragraphs <0340> to <0356> of US2016/0274458A1 can be suitably used as the hydrophobic resin (E). Further, the repeating units disclosed in paragraphs <0177> to <0258> of US2016/0237190A1 are also preferable as a repeating unit constituting the hydrophobic resin (E).

Preferred examples of a monomer corresponding to the repeating unit constituting the hydrophobic resin (E) are shown below.

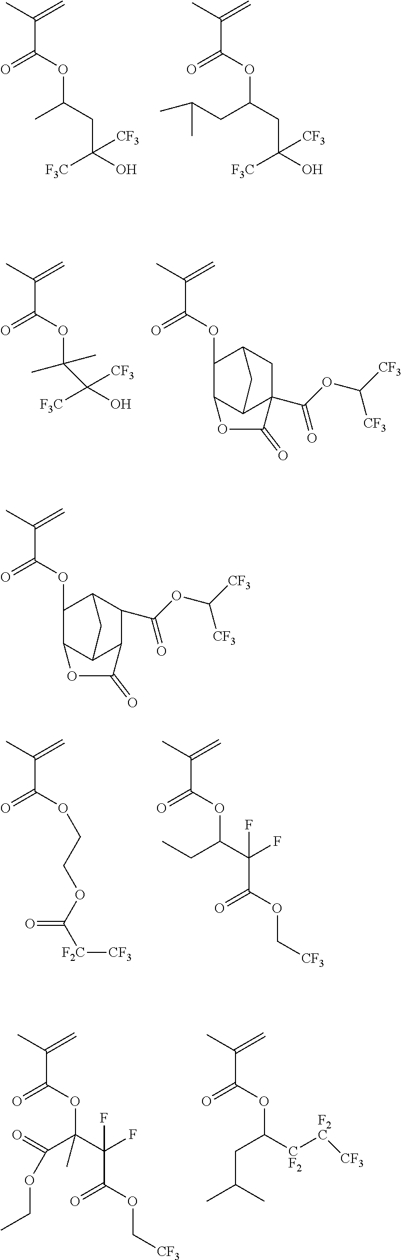

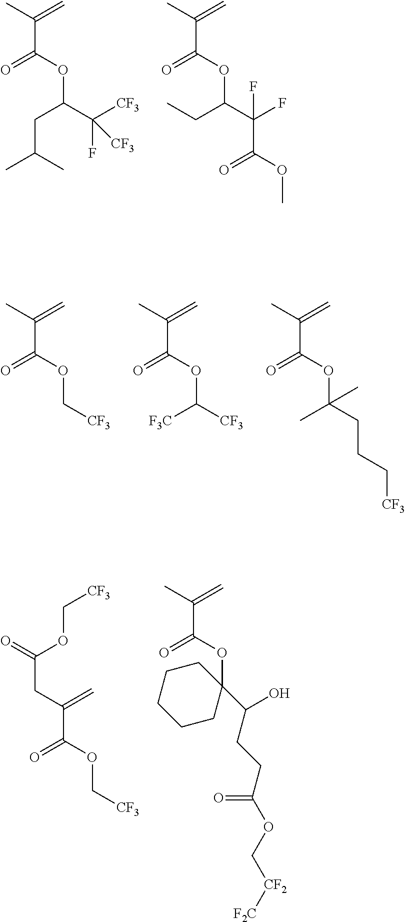

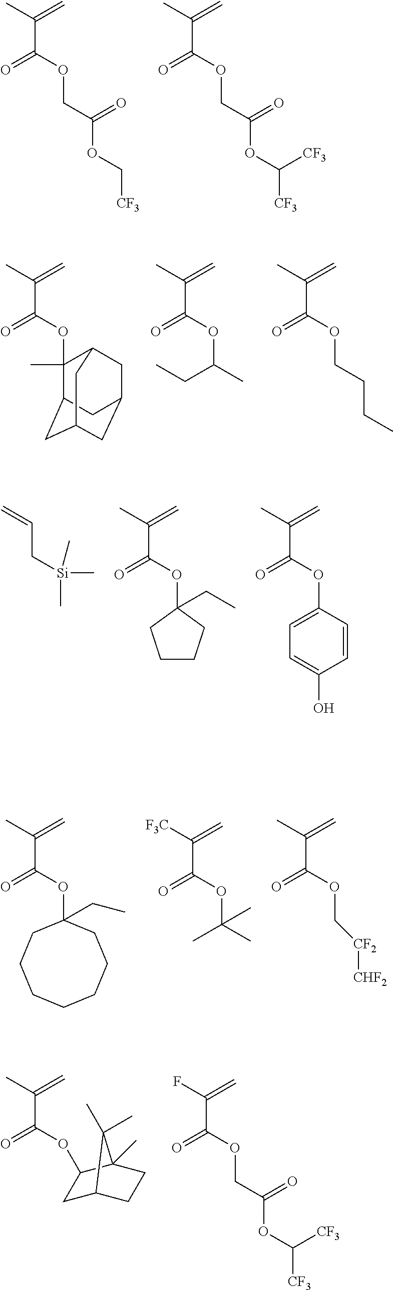

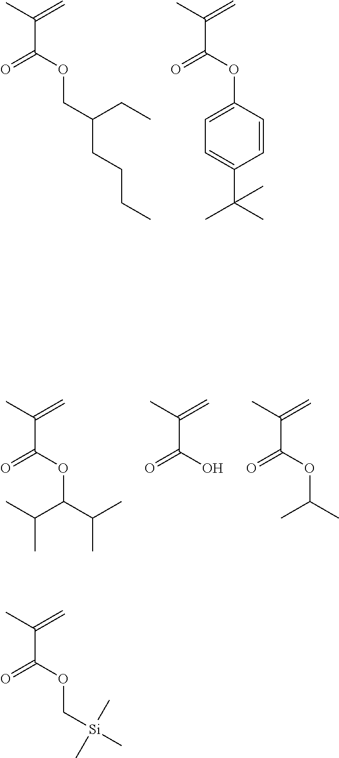

The hydrophobic resin (E) may be used singly or in combination of two or more kinds thereof.

It is preferable to use a mixture of two or more kinds of hydrophobic resins (E) having different levels of surface energy from the viewpoint of satisfying both the immersion liquid tracking properties and the development characteristics upon liquid immersion exposure.

The content of the hydrophobic resin (E) in the composition is preferably 0.01% to 10% by mass, and more preferably 0.05% to 8% by mass with respect to the total solid content in the composition of the embodiment of the present composition.

<Solvent (F)>

The composition of the embodiment of the present invention preferably contains a solvent.

In the composition of the embodiment of the present invention, a known resist solvent can be appropriately used. For example, the known solvents disclosed in paragraphs <0665> to <0670> of US2016/0070167A1, paragraphs <0210> to <0235> of US2015/0004544A1, paragraphs <0424> to <0426> of US2016/0237190A1, and paragraphs <0357> to <0366> of US2016/0274458A1 can be suitably used.

Examples of the solvent which can be used in the preparation of the composition include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

A mixed solvent obtained by mixing a solvent having a hydroxyl group in the structure and a solvent having no hydroxyl group in the structure may be used as the organic solvent.

As the solvent having a hydroxyl group and the solvent having no hydroxyl group, the above-mentioned exemplary compounds can be appropriately selected, but as the solvent including a hydroxyl group, an alkylene glycol monoalkyl ether, alkyl lactate, or the like is preferable, and propylene glycol monomethyl ether (PGME), propylene glycol monoethyl ether (PGEE), methyl 2-hydroxyisobutyrate, or ethyl lactate is more preferable. Further, as the solvent having no hydroxyl group, alkylene glycol monoalkyl ether acetate, alkyl alkoxy propionate, a monoketone compound which may have a ring, cyclic lactone, alkyl acetate, or the like is preferable: among these, propylene glycol monomethyl ether acetate (PGMEA), ethyl ethoxypropionate, 2-heptanone, α-butyrolactone, cyclohexanone, cyclopentanone, or butyl acetate is more preferable; and propylene glycol monomethyl ether acetate, α-butyrolactone, ethyl ethoxypropionate, cyclohexanone, cyclopentanone, or 2-heptanone is still more preferable. As the solvent having no hydroxyl group propylene carbonate is also preferable.

The mixing ratio (mass ratio) of the solvent having a hydroxyl group to the solvent having no hydroxyl group is 1/99 to 99/1, preferably 10/90 to 90/10, and more preferably 20/80 to 60/40. A mixed solvent containing 50% by mass or more of the solvent having no hydroxyl group is preferable from the viewpoint of coating evenness.

The solvent preferably contains propylene glycol monomethyl ether acetate, and may be a single solvent formed of propylene glycol monomethyl ether acetate or a mixed solvent of two or more kinds of solvents containing propylene glycol monomethyl ether acetate.

<Crosslinking Agent (G)>

The composition of the embodiment of the present invention may contain a compound capable of crosslinking a resin by the action of an acid (hereinafter also referred to as a crosslinking agent (G)). As the crosslinking agent (G), a known compound can be appropriately used. For example, the known compounds disclosed in paragraphs <0379> to <0431> of US2016/0147154A1 and paragraphs <0064> to <0141> of US2016/0282720A1 can be suitably used as the crosslinking agent (G).

The crosslinking agent (G) is a compound having a crosslinkable group which can crosslink a resin, and examples of the crosslinkable group include a hydroxymethyl group, an alkoxymethyl group, an acyloxymethyl group, an alkoxymethyl ether group, an oxirane ring, and an oxetane ring.

The crosslinkable group is preferably a hydroxymethyl group, an alkoxymethyl group, an oxirane ring, or an oxetane ring.

The crosslinking agent (G) is preferably a compound (which also includes a resin) having two or more crosslinkable groups.

The crosslinking agent (G) is preferably a phenol derivative, a urea-based compound (compound having a urea structure), or a melamine-based compound (compound having a melamine structure), which has a hydroxymethyl group or an alkoxymethyl group.

The crosslinking agent may be used singly or in combination of two or more kinds thereof.

The content of the crosslinking agent (G) is preferably 1% to 50% by mass, more preferably 3% to 40% by mass, and still more preferably 5% to 30% by mass.

<Surfactant (H)>

The composition of the embodiment of the present invention preferably contains a surfactant. In a case where the composition contains the surfactant, a fluorine-based and/or silicon-based surfactant (specifically a fluorine-based surfactant, a silicon-based surfactant, or a surfactant having both of a fluorine atom and a silicon atom) is preferable.

By incorporating the surfactant into the composition of the embodiment of the present invention, it becomes possible to form a pattern which has excellent adhesiveness and decreased development defects with good sensitivity and resolution in a case of using an exposure light source of 250 nm or less, and particularly 220 nm or less.

Examples of the fluorine-based and/or silicon-based surfactant include the surfactants described in paragraph <0276> of US2008/0248425A.

In addition, another surfactant other than the fluorine-based and/or silicon-based surfactant, described in paragraph <0280> of US2008/0248425A can also be used.

These surfactants may be used singly or in combination of two or more kinds thereof.

In a case where the composition of the embodiment of the present invention contains a surfactant, the content of the surfactant is preferably 0.0001% to 2% by mass, and more preferably 0.0005% to 1% by mass with respect to the total solid content of the composition.

On the other hand, by setting the amount of the surfactant to 10 ppm or more with respect to the total solid content of the composition, the hydrophobic resin (E) is further unevenly distributed on the surface. Thus, a surface of the actinic ray-sensitive or radiation-sensitive film can be made more hydrophobic, which can enhance water tracking properties upon liquid immersion exposure.

(Other Additives)

The composition of the embodiment of the present invention may further contain an acid proliferation agent, a dye, a plasticizer, a light sensitizer, a light absorber, an alkali-soluble resin, a dissolution inhibitor, a dissolution promoter, or the like.

Examples of the plasticizer include polyalkylene glycol (the number of carbon atoms in the oxyalkylene unit is preferably 2 to 6, more preferably 2 to 4, and still more preferably 2 to 3, and the average addition number is preferably 2 to 10, and more preferably 2 to 6). Specific examples of the plasticizer include the following ones.

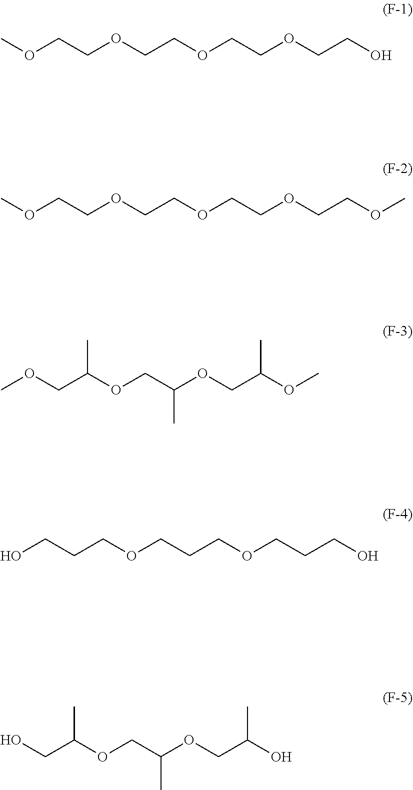

These plasticizers may be used singly or in combination of two or more kinds thereof.

In a case where the composition of the embodiment of the present invention contains a plasticizer, the content of the plasticizer is preferably 0.01% to 20% by mass, and more preferably 1% to 15% by mass with respect to the total solid content of the composition.

<Preparation Method>

The concentration of the solid content of the composition of the embodiment of the present invention is 10% by mass or more, and the upper limit is usually approximately 50% by mass. Among those, the concentration of the solid content of the composition of the embodiment of the present invention is preferably 10% to 50% by mass, more preferably 25% to 50% by mass, and still more preferably 30% to 50% by mass. The concentration of the solid content of the composition of the embodiment of the present invention is a mass percentage of the mass of other resist components excluding the solvent with respect to the total mass of the composition.

In addition, the film thickness of the actinic ray-sensitive or radiation-sensitive film formed of the composition of the embodiment of the present invention is 1 μm or more, and from the viewpoint of increasing the number of processing stages, the film thickness is preferably 3 μm or more, more preferably 5 μm or more, and still more preferably 10 μm or more. The upper limit is not particularly limited, and is, for example, 100 μm or less.

In addition, it is possible to form a pattern from the composition of the embodiment of the present invention as described later.

The film thickness of a pattern thus formed is 1 μm or more, and from the viewpoint of increasing the number of processing stages, the film thickness is preferably 3 μm or more, more preferably 5 μm or more, and still more preferably 10 μm or more. The upper limit is not particularly limited, and is, for example, 100 μm or less.

The composition of the embodiment of the present invention is used after being applied onto a predetermined support (substrate) to be used after dissolving the above-mentioned components in a predetermined organic solvent, preferably the mixed solvent, and filtering using a filter. A pore size of the filter to be used for filtration using the filter is preferably 0.1 μm or less, more preferably 0.05 μm or less, and still more preferably 0.03 μm or less. In addition, in a case where the concentration of the solid content of the composition is high (for example, 25% by mass or more), a pore size of the filter to be used for filtration using the filter is preferably 3 μm or less, more preferably 0.5 μm or less, and still more preferably 0.3 μm or less. This filter is preferably a polytetrafluoroethylene-, polyethylene- or nylon-made filter. In the filtration using a filter, circulating filtration may be performed or the filtration may be performed by connecting plural kinds of filters in series or in parallel, as disclosed in JP2002-062667A, for example. In addition, the composition may be filtered in plural times. Furthermore, the composition may be subjected to a deaeration treatment or the like before or after filtration using the filter.

The viscosity of the composition of the embodiment of the present invention is preferably 100 to 500 mPa·s. The viscosity of the composition of the embodiment of the present invention is more preferably 100 to 300 mPa·s from the viewpoint that the coatability is more excellent.

In addition, the viscosity can be measured by an E type viscometer.

<Applications>

The composition of the embodiment of the present invention relates to an actinic ray-sensitive or radiation-sensitive resin composition whose properties change by undergoing a reaction upon irradiation with actinic rays or radiation. More specifically, the composition of the embodiment of the present invention relates to an actinic ray-sensitive or radiation-sensitive resin composition which can be used in a step of manufacturing a semiconductor such as an integrated circuit (IC), for manufacture of a circuit board for a liquid crystal, a thermal head, or the like, the manufacture of a mold structure for imprinting, other photofabrication processes, a planographic printing plate, or an acid-curable composition. A pattern formed in the present invention can be used in an etching step, an ion implantation step, a bump electrode forming step, a rewiring forming step, a microelectromechanical system (MEMS), or the like.

[Pattern Forming Method]

The present invention also relates to a pattern forming method using the actinic ray-sensitive or radiation-sensitive resin composition. Hereinafter, the pattern forming method of the embodiment of the present invention will be described. Further, the actinic ray-sensitive or radiation-sensitive film of the present invention will also be described, together with the pattern forming method.

The pattern forming method of the embodiment of the present invention includes:

(i) a step of forming a resist film (actinic ray-sensitive or radiation-sensitive film) on a support using the above-mentioned actinic ray-sensitive or radiation-sensitive resin composition (resist film forming step),

(ii) a step of exposing the resist film (irradiating actinic rays or radiation) (exposing step), and

(iii) a step of developing the exposed resist film using a developer (developing step).

The pattern forming method of the embodiment of the present invention is not particularly limited as long as it includes the (i) to (iii) steps, and may further include the following steps.

In the pattern forming method of the embodiment of the present invention, the exposing method in the (ii) exposing step may be liquid immersion exposure.

The pattern forming method of the embodiment of the present invention preferably includes a (iv) prebaking (PB) step before the (ii) exposing step.

The pattern forming method of the embodiment of the present invention preferably includes a (v) post-exposure baking (PEB) step after the (ii) exposing step and before the (iii) developing step.

The pattern forming method of the embodiment of the present invention may include the (ii) exposing step a plurality of times.

The pattern forming method of the embodiment of the present invention may include the (iv) prebaking heating step a plurality of times.

The pattern forming method of the embodiment of the present invention may include the (v) post-exposure baking step a plurality of times.

In the pattern forming method of the embodiment of the present invention, the above-mentioned (i) resist film forming step, (ii) exposing step, and (iii) developing step can be performed by a generally known method.

In addition, a resist underlayer film (for example, spin on glass (SOG), spin on carbon (SOC), and an antireflection film) may be formed between the resist film and the support, as desired. As a material constituting the resist underlayer film, known organic or inorganic materials can be appropriately used.

A protective film (topcoat) may be formed on the upper layer of the resist film. As the protective film, a known material can be appropriately used. The compositions for forming a protective film disclosed in, for example, US2007/0178407A, US2008/0085466A, US2007/0275326A, US2016/0299432A. US2013/0244438A, or WO2016/157988A can be suitably used. The composition for forming a protective film preferably contains the above-mentioned acid diffusion control agent.

A protective film may be formed on the upper layer of the resist film containing the above-mentioned hydrophobic resin.

The support is not particularly limited, and a substrate which is generally used in a process for manufacturing a semiconductor such as an IC, and a process for manufacturing a circuit board for a liquid crystal, a thermal head, or the like, and other lithographic processes of photofabrication can be used. Specific examples of the support include an inorganic substrate such as silicone, SiO₂, and SiN.

For any of the (iv) prebaking step and the (v) post-exposure baking step, the heating temperature is preferably 70° C. to 150° C., more preferably 70° C. to 130° C., still more preferably 80° C. to 130° C., and most preferably 80° C. to 120° C.

For any of the (iv) prebaking step and the (v) post-exposure baking step, the heating time is preferably 30 to 300 seconds, more preferably 30 to 180 seconds, and still more preferably 30 to 90 seconds.

Heating may be performed using a means comprised in an exposure device and a development device, or may also be performed using a hot plate or the like.

The light source wavelength used in the exposing step is not particularly limited, and examples thereof include infrared rays, visible light, ultraviolet rays, far ultraviolet rays, extreme ultraviolet rays (EUV), X-rays, and electron beams. Among those, far ultraviolet rays are preferable, whose wavelength is preferably 250 nm or less, more preferably 220 nm or less, and still more preferably 1 to 200 nm. Specific examples thereof include a KrF excimer laser (248 nm), an ArF excimer laser (193 nm), an F₂ excimer laser (157 nm), X-rays, EUV (13 nm), and electron beams, the KrF excimer laser, the ArF excimer laser, EUV, or the electron beams are preferable, and the KrF excimer laser is more preferable.

In the (iii) developing step, the developer may be either an alkali developer or a developer containing an organic solvent (hereinafter also referred to as an organic developer).

As the alkali developer, a quaternary ammonium salt typified by tetramethylammonium hydroxide is usually used, but in addition to the developer, an aqueous alkali-solution such as an inorganic alkali, primary to tertiary amines, alcohol amine, and cyclic amine can also be used.

In addition, the alkali developer may contain an appropriate amount of alcohols and/or a surfactant. The alkali concentration of the alkali developer is usually 0.1% to 20% by mass. The pH of the alkali developer is usually 10 to 15.

The time for performing development using the alkali developer is usually 10 to 300 seconds.

The alkali concentration, the pH, and the development time using the alkali developer can be appropriately adjusted depending on a pattern formed.

As the organic developer, a developer containing at least one organic solvent selected from the group consisting of a ketone-based solvent, an ester-based solvent, an alcohol-based solvent, an amide-based solvent, an ether-based solvent, and hydrocarbon-based solvents is preferable.

Examples of the ketone-based solvent include 1-octanone, 2-octanone, 1-nonanone. 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate.

As the alcohol-based solvent, the amide-based solvent, the ether-based solvent, and the hydrocarbon-based solvent, the solvents disclosed in paragraphs <0715> to <0718> of US2016/0070167A1 can be used.

A plurality of the solvents may be mixed or the solvent may be used in admixture with a solvent other than those described above or water. The moisture content in the entire developer is preferably less than 50% by mass, more preferably less than 20% by mass, and still more preferably less than 10% by mass, and particularly preferably, moisture is not substantially included.

The content of the organic solvent with respect to the organic developer is preferably 50% to 100% by mass, more preferably 80% to 100% by mass, still more preferably 90% to 100% by mass, and particularly preferably 95% to 100% by mass with respect to the total amount of the developer.

The organic developer may contain an appropriate amount of a known surfactant, as desired.

The content of the surfactant is usually 0.001% to 5% by mass, preferably 0.005% to 2% by mass, and still more preferably 0.01% to 0.5% by mass with respect to the total amount of the developer.

The organic developer may contain the above-mentioned acid diffusion control agent.

Examples of the developing method include a method in which a substrate is immersed in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), and a method in which a developer is continuously discharged onto a substrate spun at a constant rate while scanning a developer discharging nozzle at a constant rate (a dynamic dispense method).

A combination of a step of performing development using an aqueous alkali-solution (an alkali developing step) and a step of performing development using a developer containing an organic solvent (an organic solvent developing step) may be used. Thus, a finer pattern can be formed since a pattern can be formed by keeping only a region with an intermediate exposure intensity from not being dissolved.

It is preferable that after the (iii) developing step, a step of performing washing using a rinsing liquid (a rinsing step) is included.

As the rinsing liquid used in the rinsing step after the developing step using an alkali developer, for example, pure water can be used. Pure water may contain an appropriate amount of a surfactant. In this case, after the developing step or the rinsing step, a treatment for removing the developer or the rinsing liquid adhering on a pattern by a supercritical fluid may be added. In addition, after the rinsing treatment or the treatment using a supercritical fluid, a heating treatment for removing moisture remaining in the pattern may be performed.

The rinsing liquid used in the rinsing step after the step of performing development using a developer containing an organic solvent is not particularly limited as long as the rinsing liquid does not dissolve the resist pattern, and a solution containing a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same solvents as those described for the developer containing an organic solvent.

As the rinsing liquid used in the rinsing step in this case, a rinsing liquid containing a monohydric alcohol is more preferable.

Here, examples of the monohydric alcohol used in the rinsing step include linear, branched, or cyclic monohydric alcohols. Specific examples thereof include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, and methyl isobutyl carbinol. Examples of the monohydric alcohol having 5 or more carbon atoms include 1-hexanol, 2-hexanol, 4-methyl-2-pentanol, 1-pentanol, 3-methyl-1-butanol, and methyl isobutyl carbinol.

The respective components in plural number may be mixed or the components may be used in admixture with an organic solvent other than the above solvents.

The moisture content in the rinsing liquid is preferably 10% by mass or less, more preferably 5% by mass or less, and still more preferably 3% by mass or less. By setting the moisture content to 10% by mass or less, good development characteristics can be obtained.

The rinsing liquid may contain an appropriate amount of a surfactant.

In the rinsing step, the substrate that has been subjected to development using an organic developer is subjected to a washing treatment using a rinsing liquid containing an organic solvent. A method for the washing treatment method is not particularly limited, but examples thereof include a method in which a rinsing liquid is continuously discharged on a substrate rotated at a constant rate (a rotation application method), a method in which a substrate is immersed in a tank filled with a rinsing liquid for a certain period of time (a dip method), and a method in which a rinsing liquid is sprayed on a substrate surface (a spray method). Among those, it is preferable that a washing treatment is performed using the rotation application method, and a substrate is rotated at a rotation speed of 2,000 to 4,000 revolutions per minute (rpm) after washing, thereby removing the rinsing liquid from the substrate. Furthermore, it is also preferable that the method includes a baking step after the rinsing step (post-baking). The developer and the rinsing liquid remaining between and inside the patterns are removed by the baking step. In the heating step after the rinsing step, the heating temperature is usually 40° C. to 160° C., preferably 70° C. to 120° C., and more preferably 70° C. to 95° C., and typically for 10 seconds to 3 minutes, and preferably for 30 seconds to 90 seconds.

It is preferable that various materials (for example, a resist solvent, a developer, a rinsing liquid, a composition for forming an antireflection film, and a composition for forming a topcoat) used in the actinic ray-sensitive or radiation-sensitive resin composition of the embodiment of the present invention, and the pattern forming method of the embodiment of the present invention do not include impurities such as metals. The content of the impurities included in these materials is preferably 1 ppm by mass or less, more preferably 100 ppt by mass or less, and still more preferably 10 ppt by mass or less, and particularly preferably, the impurities are not substantially included (no higher than a detection limit of a measurement device).

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. As the filter, a filter which had been washed with an organic solvent in advance may be used. In the step of filtration using a filter, plural kinds of filters connected in series or in parallel may be used. In a case of using the plural kinds of filters, a combination of filters having different pore diameters and/or materials may be used. In addition, various materials may be filtered plural times, and the step of filtering plural times may be a circulatory filtration step. As the filter, a filter having a reduced amount of elutes as disclosed in JP2016-201426A is preferable.

In addition to the filtration using a filter, removal of impurities by an adsorbing material may be performed, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used. Examples of the metal adsorbing agent include those disclosed in JP2016-206500A.

In addition, as a method for reducing the impurities such as metals included in various materials, metal content selects the less material as a raw material constituting the various materials, performing filtering using a filter of the raw material constituting the various materials, equipment the inner and a method such as performing distillation under conditions suppressing as much as possible equal to contamination is lined with TEFLON (registered trademark). Preferred conditions in the filtering using a filter to be performed on the raw material constituting the various materials are similar to the above-mentioned conditions.

In order to prevent impurities from being incorporated, it is preferable that various materials are stored in the container described in US2015/0227049A, JP2015-123351A, or the like.

A method for improving the surface roughness of a pattern may be applied to a pattern formed by the pattern forming method of the embodiment of the present invention. Examples of the method for improving the surface roughness of a pattern include the method of treating a resist pattern by plasma of a hydrogen-containing gas disclosed in US2015/0104957A. In addition, known methods as described in JP2004-235468A, US2010/0020297A, and Proc. of SPIE Vol. 832883280N-1 “EUV Resist Curing Technique for LWR Reduction and Etch Selectivity Enhancement” may be applied.

In addition, a pattern formed by the method can be used as a core material (core) of the spacer process disclosed in JP1991-270227A (JP-H03-270227A) and US2013/0209941A, for example.

[Method for Manufacturing Electronic Device]

In addition, the present invention further relates to a method for manufacturing an electronic device, including the above-described pattern forming method, and an electronic device manufactured by the method for manufacturing an electronic device. The electronic device of an embodiment of the present invention is suitably mounted on electric or electronic equipment (for example, home electronics, office automation (OA)-related equipment, media-related equipment, optical equipment, and telecommunication equipment).

### EXAMPLES

Hereinbelow, the present invention will be described in more detail with reference to Examples. The materials, the amounts of materials used, the proportions, the treatment details, the treatment procedure, or the like shown in the Examples below may be modified if appropriate as long as the modifications do not depart from the spirit of the present invention. Therefore, the scope of the present invention should not be construed as being limited to the Examples shown below.

[Preparation of Actinic Ray-Sensitive or Radiation-Sensitive Resin Composition]

Various components included in the actinic ray-sensitive or radiation-sensitive resin compositions shown in Table 2 are shown below.

<Resin>

The molar ratios, the weight-average molecular weight (Mw), and the dispersity (Mw/Mn) of the repeating units in the resins (A-1 to A-12, AX-1 to AX-3) shown in Table 2 are shown in Table 1.

In addition, the weight-average molecular weight (Mw) and the dispersity (Mw/Mn) of the resins A-1 to A-12, and AX-1 to AX-3 were measured by means of GPC (carrier: tetrahydrofuran (THF)) (an amount in terms of polystyrene). In addition, the compositional ratios (ratio in % by mole) of the resins were measured by means of ₁₃C-nuclear magnetic resonance (NMR).

In addition, the glass transition temperature of the repeating unit A (in addition, the “glass transition temperature (Tg (° C.))” as mentioned herein means a Tg (° C.) in a case where a monomer from which the repeating unit A is derived is used to form a homopolymer) is also shown in Table 1. A method for measuring the glass transition temperature of the repeating unit A will be described later.

In addition, “Presence or absence of repeating unit having aromatic ring” and “Molar ratio (% by mole) of repeating unit having aromatic ring” in the resins A-1 to A-12, and AX-1 to AX-3 are also shown in Table 1. Further, for example, in a case of the resin A-1, the repeating unit MD-1 corresponds to “Repeating unit having aromatic ring”, and in a case of the resin A-5, the repeating unit MD-1 and the repeating unit MB-3 correspond to “Repeating unit having aromatic ring”.

TABLE 1

| | | | | | | | | Repeating | | | | | | | |
|---|---|---|---|---|---|---|---|---|---|---|---|---|---|---|---|
| | | | | | | Repeating | | unit D | | | | | | | Molar |
| | | | | Repeating | | unit C | | (Repeating | | | | | | Presence | ratio |
| | | | | unit B | | (Repeating | | unit | | Repeating | | | | or | (% by |
| | | | | (Repeating unit | | unit | | having | | unit E | | | | absence of | mole) of |
| | Repeating unit A | | | having acid- | | having | | phenolic | | (Other | | | | repeating | repeating |
| | | Glass | | decomposable | | carboxy | | hydroxyl | | repeating | | | | unit | unit |
| | | transition | | group) | | group) | | group) | | units) | | | | having | having |
| | | temperature | % by | | % by | | % by | | % by | | % by | | | aromatic | aromatic |
| | Type | (° C.) | mole | Type | mole | Type | mole | Type | mole | Type | mole | Mw | Mw/Mn | ring | ring |
| Resin A-1 | MA-1 | −10° C. | 16 | MB-1 | 9 | — | — | MD-1 | 75 | — | — | 16,000 | 1.6 | Present | 75 |
| Resin A-2 | MA-2 | −15° C. | 20 | MB-1 | 13 | MC-1 | 5 | MD-1 | 62 | — | — | 13,000 | 1.3 | Present | 62 |
| Resin A-3 | MA-3 | −70° C. | 13 | MB-1 | 12 | — | — | MD-1 | 75 | — | — | 20,000 | 1.7 | Present | 75 |
| Resin A-4 | MA-4 | −55° C. | 11 | MB-2 | 9 | — | — | MD-1 | 80 | — | — | 10,000 | 1.4 | Present | 80 |
| Resin A-5 | MA-5 | 9° C. | 5 | MB-3 | 20 | — | — | MD-1 | 75 | — | — | 10,000 | 1.4 | Present | 95 |
| Resin A-6 | MA-6 | 35° C. | 42 | MB-4 | 18 | — | — | MD-1 | 40 | — | — | 28,000 | 1.9 | Present | 40 |
| Resin A-7 | MA-7 | −20° C. | 35 | MB-5 | 12 | — | — | MD-2 | 53 | — | — | 15,000 | 1.6 | Present | 53 |
| Resin A-8 | MA-8 | −5° C. | 10 | MB-6 | 20 | — | — | MD-3 | 70 | — | — | 22,000 | 1.7 | Present | 90 |
| Resin A-9 | MA-9 | 36° C. | 4 | MB-1 | 18 | — | — | MD-1 | 78 | — | — | 18,000 | 1.7 | Present | 78 |
| Resin A-10 | MA-1 | −10° C. | 18 | MB-1 | 12 | — | — | MD-1 | 70 | — | — | 17,000 | 1.6 | Present | 70 |
| Resin A-11 | MA-10 | −65° C. | 18 | MB-1 | 18 | — | — | MD-1 | 64 | — | — | 21,000 | 1.5 | Present | 64 |
| Resin A-12 | MA-1 | −10° C. | 22 | MB-1 | 19 | — | — | MD-1 | 59 | — | — | 19,000 | 1.5 | Present | 59 |
| Resin AX-1 | MA-4 | −55° C. | 40 | MB-2 | 50 | MC-1 | 10 | — | — | — | — | 20,000 | 2.0 | Absent | 0 |
| Resin AX-2 | — | — | — | MB-2 | 50 | MC-1 | 10 | — | — | ME-1 | 40 | 20,000 | 2.0 | Present | 40 |
| Resin AX-3 | — | — | — | MB-2 | 25 | MC-1 | 10 | — | — | ME-1 | 65 | 20,000 | 2.0 | Present | 65 |

The monomer structures used for the synthesis of the resins A-1 to A-12, and AX-1 to AX-3 are shown below.

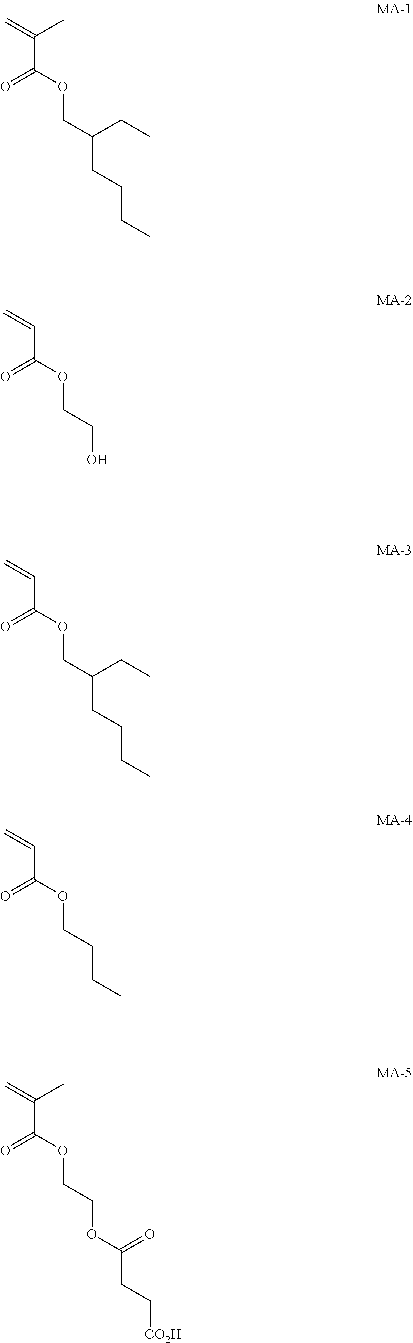

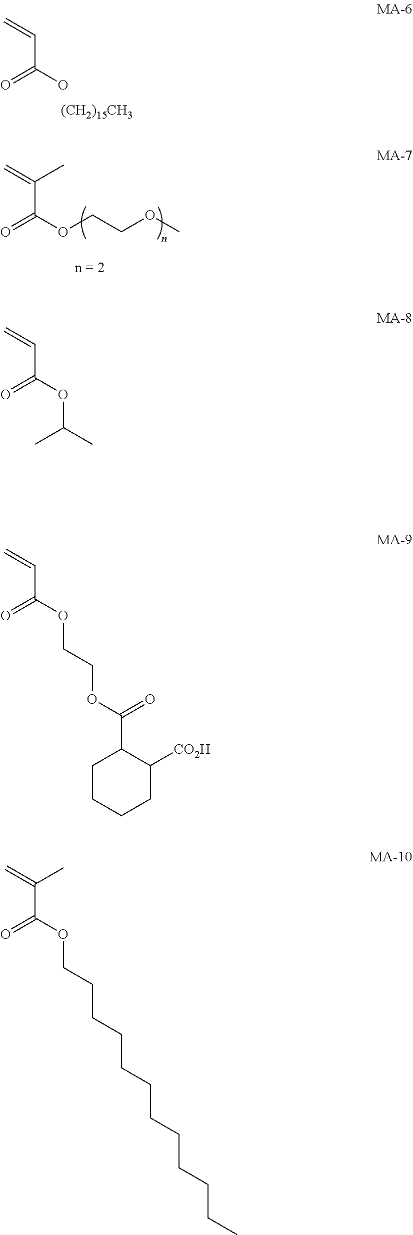

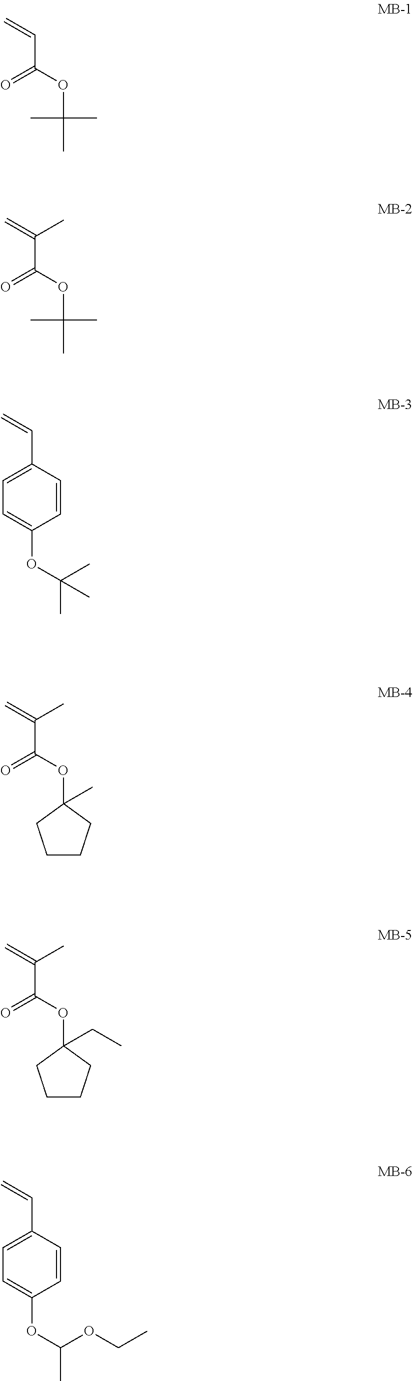

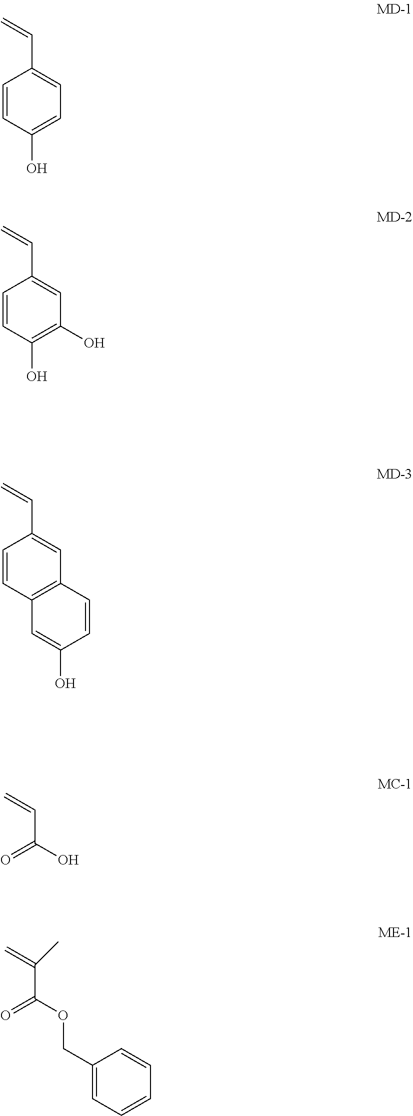

In addition, specific structures of the resins A-1 to A-12, and AX-1 to AX-3 are shown below.

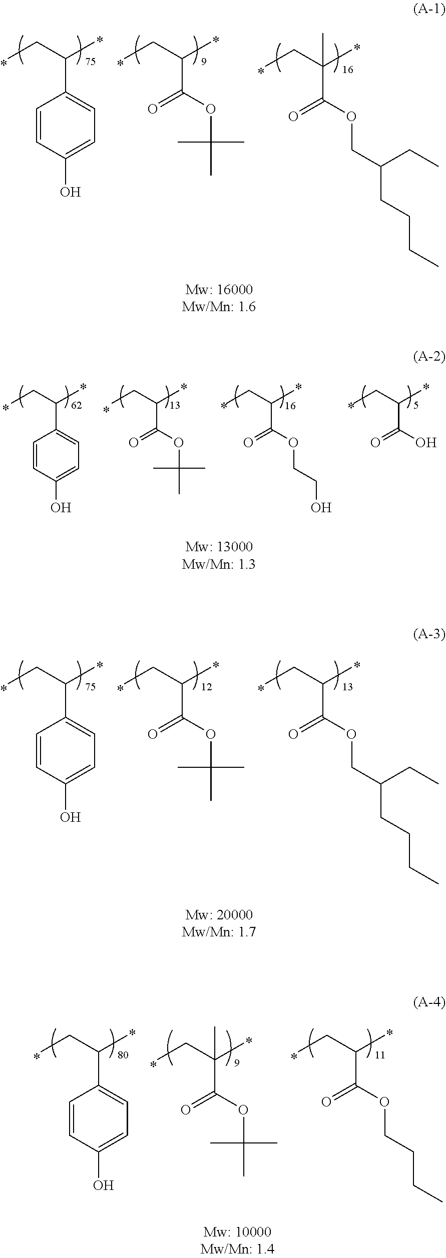

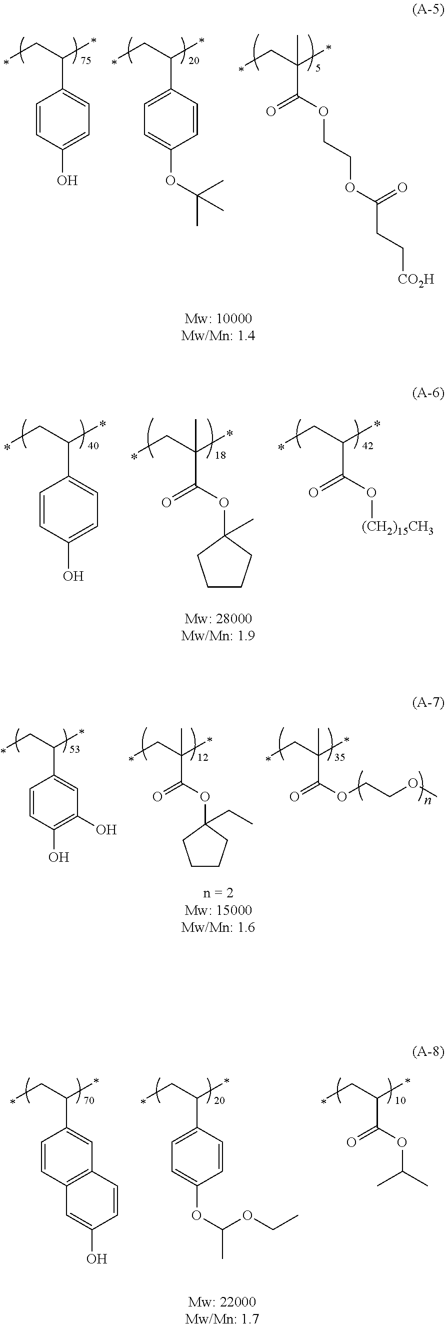

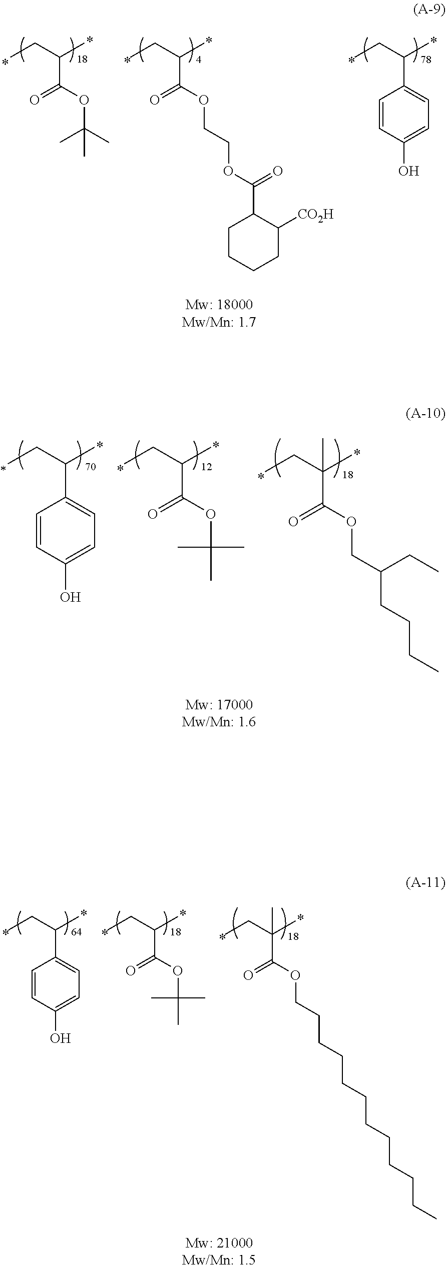

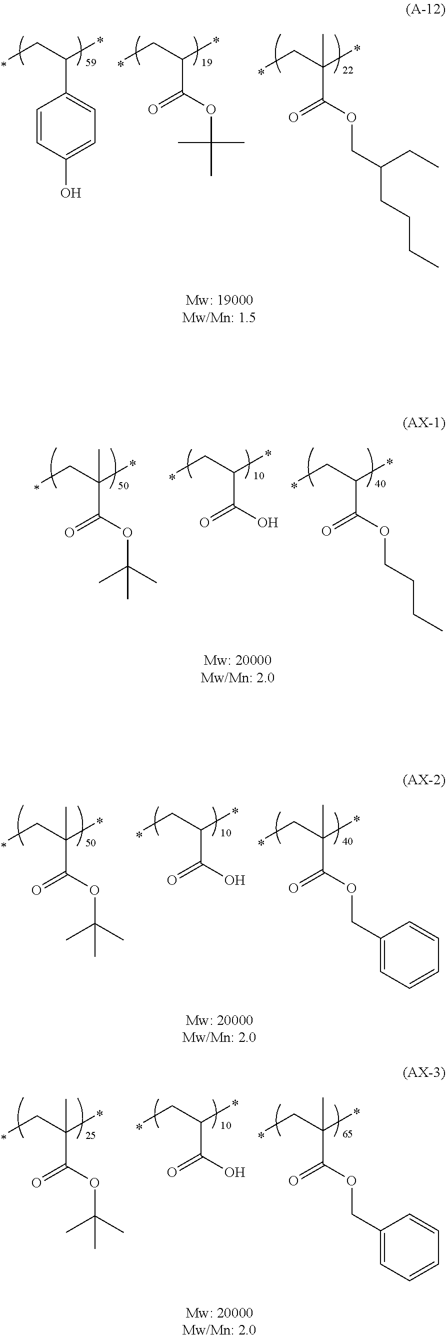

(Measurement of Glass Transition Temperature of Repeating Unit A)

The glass transition temperature of the repeating unit A is intended to mean a glass transition temperature (Tg (° C.)) in a case where monomers forming a repeating unit are used to form a homopolymer.

As a glass transition temperature (Tg (° C.)) of the homopolymer, in a case where there is a catalog value or a literature value, the value is employed, and in a case where there is not such a value, the glass transition temperature (Tg (° C.)) can be measured by differential scanning calorimetry (DSC).

Hereinafter, in a case where the glass transition temperature (Tg (° C.)) of the homopolymer is measured by the DSC method, a method for synthesizing the homopolymer and a method for measuring the glass transition temperature will be described.

Method for Synthesizing Homopolymer

Upon measurement of the glass transition temperature of the repeating unit A, a homopolymer was synthesized according to the following procedure. In addition, the synthesis of the homopolymer is performed by a general dropwise addition polymerization method.

54 parts by mass of PGMEA was heated to 80° C. under a nitrogen gas stream. While stirring the liquid, 125 parts by mass of a PGMEA solution including 21% by mass of a monofunctional monomer and 0.35% by mass of 2,2′-dimethyl azobisisobutyrate was added dropwise thereto for 6 hours. After dropwise addition, the mixture was further stirred at 80° C. for 2 hours. The reaction solution was left to be cooled, then reprecipitated with a large amount of methanol/water (mass ratio of 9:1), and filtered. The obtained solid was dried to obtain a homopolymer (Mw: 18,000).

Method for Measuring Glass Transition Temperature

The glass transition temperature of the obtained homopolymer was measured by the DSC method. As the DSC device, a “thermal analysis DSC differential scanning calorimeter Q1000 Type” manufactured by TA Instruments Japan Ltd., and a temperature raising rate was set to 10° C./min to perform the measurement.

<Acid Generator>

The structures of the acid generators (compounds C-1 to C-8) shown in Table 2 are shown below.

In addition, “nBu” in the formulae represents an n-butyl group.

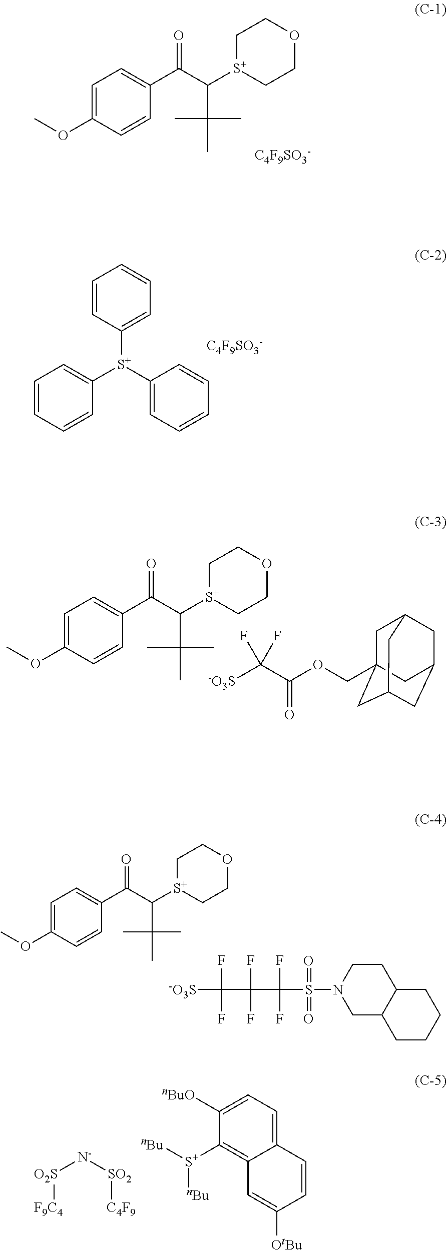

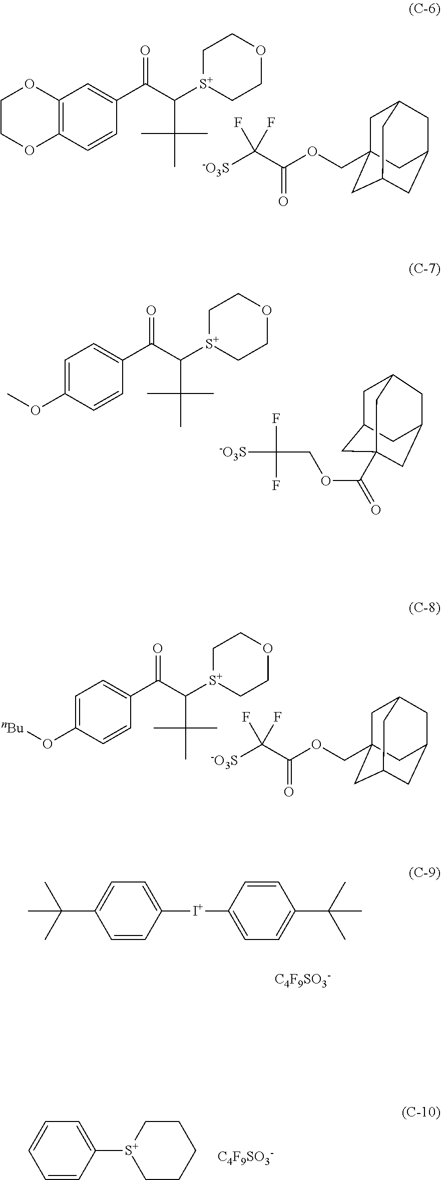

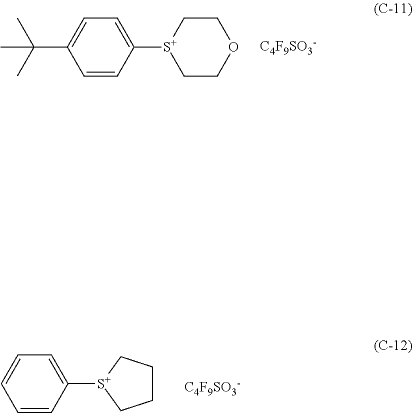

<Acid Diffusion Control Agent>

The structures of the acid diffusion control agents shown in Table 2 are shown below.

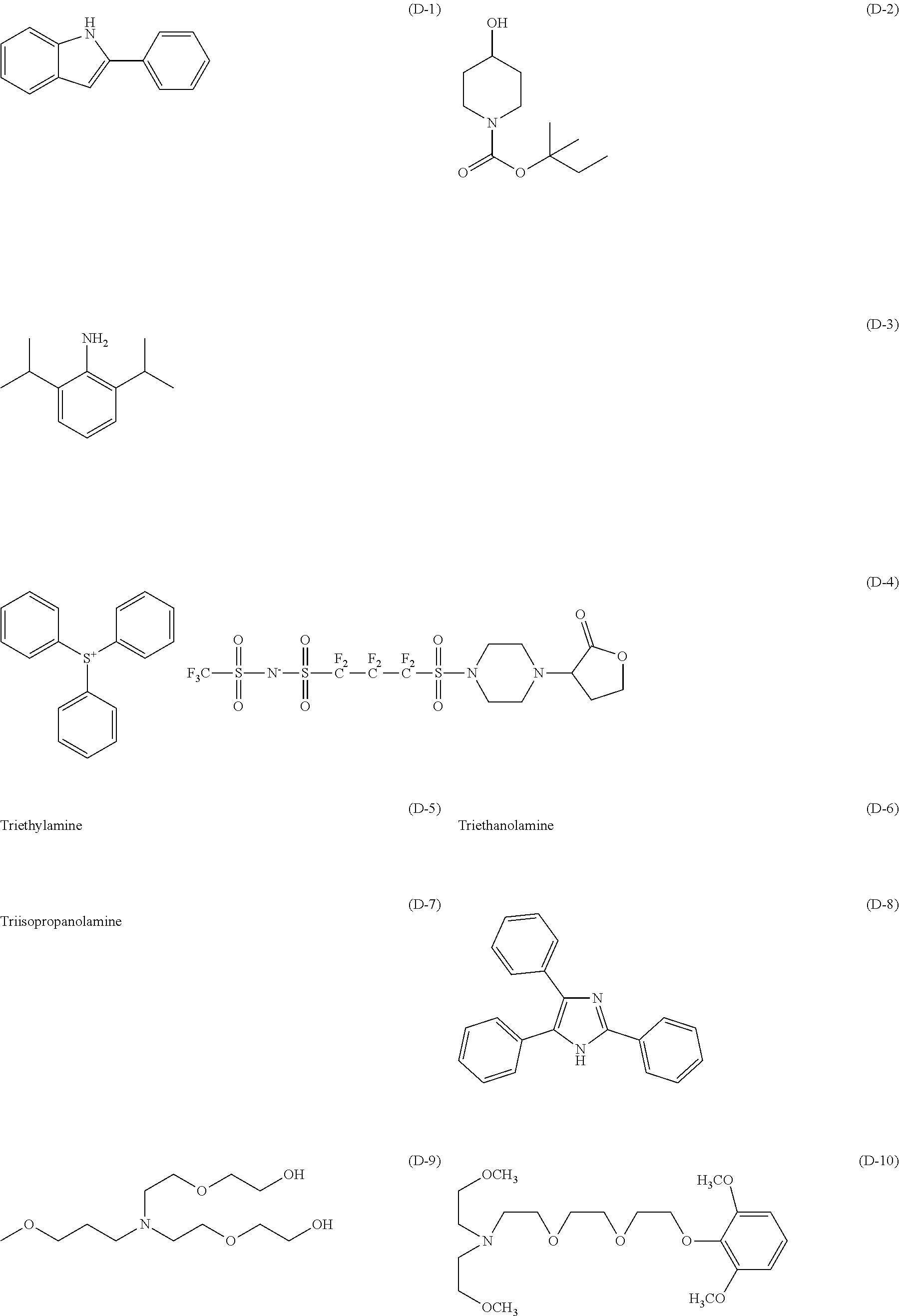

<Surfactant>

The surfactant shown in Table 2 is shown below.

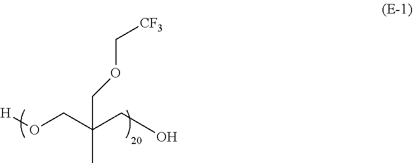

(E-2): MEGAFACE “R-41” (manufactured by DIC Corporation)

<Additive>

Additives F-1 to F-5 shown in Table 2 are shown below.

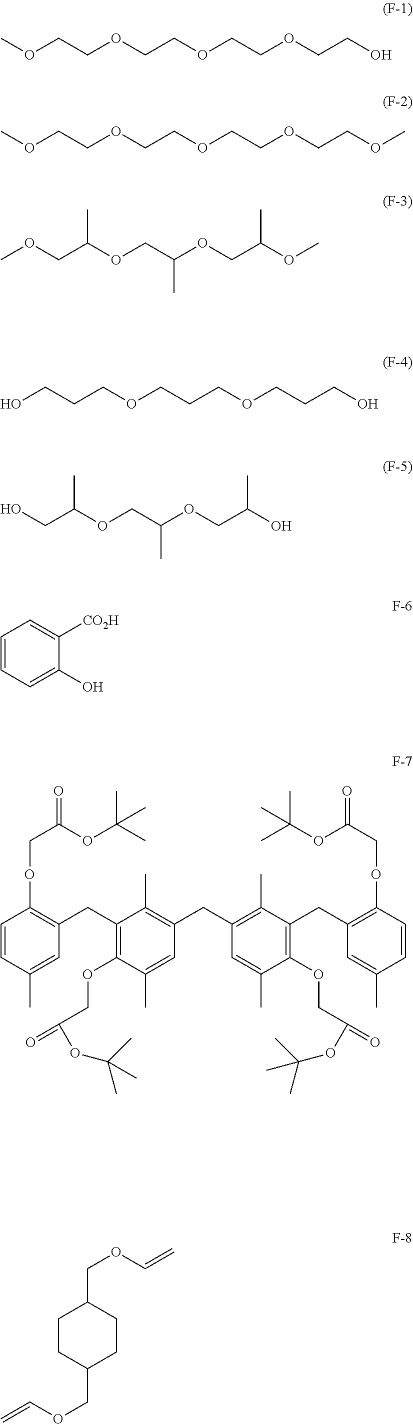

<Solvent>

The solvents shown in Table 2 are shown below.

S-1: Propylene glycol monomethyl ether acetate (PGMEA)

S-2: Propylene glycol monomethyl ether (PGME)

S-3: Ethyl lactate (EL)

S-4: Ethyl 3-ethoxypropionate (EEP)

S-5: 2-Heptanone (MAK)

S-6: Methyl 3-methoxypropionate (MMP)

S-7: 3-Methoxybutyl acetate

<Preparation of Actinic Ray-Sensitive or Radiation-Sensitive Resin Composition>

The respective components shown in Table 2 were mixed until they reached the concentrations of the solid content described in Table 2. Then, the obtained mixed liquid was filtered through a polyethylene-based filter having a pore size of 3 μm to prepare an actinic ray-sensitive or radiation-sensitive resin composition (hereinafter also referred to as a resin composition). In addition, the solid content in the resin composition means all components except for the solvent. The obtained resin composition was used in Examples and Comparative Examples.

Furthermore, the amounts of twenty five metal impurity components (Na, K. Ca. Fe, Cu. Mg, Mn, Al, Li, Cr, Ni. Sn, Zn, Ag. As, Au, Ba, Cd, Co, Pb, Ti, V. W. Mo, Zr) included in each of the compositions were measured with inductively coupled plasma mass spectrometry (ICP-MS device) “Agilent 7500cs” manufactured by Agilent Technologies, and thus, the contents of the respective metal species were each less than 10 ppb.

Moreover, in Table 2, the content (% by mass) of each of the components means a content with respect to the total solid content.

TABLE 2

| | Actinic ray-sensitive or radiation-sensitive resin composition | | | | | | | | | | | | | |
|---|---|---|---|---|---|---|---|---|---|---|---|---|---|---|
| | | | | | Acid | | | | | | | | | |
| | | | | | diffusion | | | | | | | | | |
| | | | Acid | | control | | | | | | | | | |
| | Resin | | generator | | agent | | Surfactant | | Additive | | Solvent | | | |
| | | Content | | Content | | Content | | Content | | Content | | | Mass ratio | |
| | | (% by | | (% by | | (% by | | (% by | | (% by | | | (solvent 1/ | Solid content |
| | Type | mass) | Type | mass) | Type | mass) | Type | mass) | Type | mass) | Solvent 1 | Solvent 2 | solvent 2) | (% by mass) |
| Example 1 | A-1 | 86.85 | C-1 | 2.9 | D-2 | 0.2 | E-1 | 0.05 | F-1 | 10 | S-1 | S-2 | 60/40 | 39 |
| Example 2 | A-2 | 90.35 | C-4 | 2.5 | D-4 | 0.1 | E-1 | 0.05 | F-2 | 7 | S-1 | | 100 | 33 |
| Example 3 | A-3 | 91.75 | C-3 | 3.1 | D-2 | 0.1 | E-1 | 0.05 | F-3 | 5 | S-1 | S-2 | 80/20 | 31 |
| Example 4 | A-4 | 97.40 | C-4 | 2.5 | D-2 | 0.1 | | | | | S-1 | S-5 | 50/50 | 28 |
| Example 5 | A-5 | 97.15 | C-1 | 2.7 | D-3 | 0.1 | E-1 | 0.05 | | | S-1 | S-2 | 70/30 | 33 |
| Example 6 | A-6 | 87.65 | C-3 | 3.1 | D-1 | 0.2 | E-1 | 0.05 | F-1 | 9 | S-1 | S-3 | 80/20 | 31 |
| Example 7 | A-7 | 97.00 | C-1 | 2.9 | D-4 | 0.1 | | | | | S-5 | S-6 | 60/40 | 28 |
| Example 8 | A-8 | 93.55 | C-5 | 2.3 | D-4 | 0.1 | E-1 | 0.05 | F-2 | 4 | S-4 | S-7 | 50/50 | 39 |
| Example 9 | A-9 | 97.25 | C-1 | 2.6 | D-3 | 0.1 | E-1 | 0.05 | | | S-1 | S-2 | 60/40 | 38 |
| Example 10 | A-1 | 96.85 | C-2 | 2.9 | D-2 | 0.2 | E-1 | 0.05 | | | S-1 | S-2 | 60/40 | 39 |
| Example 11 | A-2 | 90.35 | C-6 | 2.4 | D-4 | 0.2 | E-1 | 0.05 | F-2 | 7 | S-1 | | 100 | 33 |
| Example 12 | A-3 | 96.75 | C-7 | 2.9 | D-2 | 0.3 | E-1 | 0.05 | | | S-1 | S-2 | 80/20 | 31 |
| Example 13 | A-1 | 86.85 | C-1 | 2.9 | D-2 | 0.2 | E-1 | 0.05 | F-1 | 10 | S-1 | S-2 | 60/40 | 39 |
| Example 14 | A-10 | 88.60 | C-4 | 1.3 | D-2 | 0.01 | E-1 | 0.09 | F-2 | 10 | S-1 | S-2 | 50/50 | 38 |
| Example 15 | A-10 | 83.80 | C-4 | 1.1 | D-2 | 0.05 | E-1 | 0.05 | F-4 | 35 | S-1 | S-2 | 50/50 | 41 |
| Example 16 | A-10 | 88.48 | C-3 | 1.4 | D-2 | 0.02 | E-1 | 0.1 | F-2 | 10 | S-1 | S-2 | 50/50 | 37 |
| Example 17 | A-10 | 83.70 | C-3 | 1.2 | D-2 | 0.01 | E-1 | 0.09 | F-4 | 15 | S-1 | S-2 | 50/50 | 41 |
| Example 18 | A-10 | 88.60 | C-1 | 1.3 | D-2 | 0.04 | E-1 | 0.06 | F-2 | 10 | S-1 | S-2 | 50/50 | 39 |
| Example 19 | A-10 | 83.54 | C-1 | 1.3 | D-2 | 0.08 | E-1 | 0.08 | F-4 | 35 | S-1 | S-2 | 50/50 | 43 |
| Example 20 | A-10 | 88.40 | C-4 | 1.5 | D-2 | 0.02 | E-2 | 0.08 | F-2 | 10 | S-1 | S-2 | 50/50 | 38 |

TABLE 3

| | Actinic ray-sensitive or radiation-sensitive resin composition | | | | | | | | | | | | | |
|---|---|---|---|---|---|---|---|---|---|---|---|---|---|---|
| | | | | | Acid | | | | | | | | | |
| | | | | | diffusion | | | | | | | | | |
| | | | Acid | | control | | | | | | | | | |
| | Resin | | generator | | agent | | Surfactant | | Additive | | Solvent | | | |
| | | Content | | Content | | Content | | Content | | Content | | | Mass ratio | |
| | | (% by | | (% by | | (% by | | (% by | | (% by | | | (solvent 1/ | Solid content |
| | Type | mass) | Type | mass) | Type | mass) | Type | mass) | Type | mass) | Solvent 1 | Solvent 2 | solvent 2) | (% by mass) |
| Example 21 | A-10 | 83.84 | C-4 | 1.1 | D-2 | 0.01 | E-2 | 0.05 | F-4 | 15 | S-1 | S-2 | 50/50 | 42 |
| Example 22 | A-10 | 88.25 | C-3 | 1.6 | D-2 | 0.08 | E-2 | 0.07 | F-2 | 10 | S-1 | S-2 | 50/50 | 36 |
| Example 23 | A-10 | 83.75 | C-3 | 1.1 | D-2 | 0.09 | E-2 | 0.06 | F-4 | 15 | S-1 | S-2 | 50/50 | 42 |
| Example 24 | A-10 | 88.60 | C-1 | 1.3 | D-2 | 0.02 | E-2 | 0.08 | F-2 | 10 | S-1 | S-2 | 50/50 | 38 |
| Example 25 | A-10 | 83.77 | C-1 | 1.2 | D-2 | 0.01 | E-2 | 0.02 | F-4 | 15 | S-1 | S-2 | 50/50 | 41 |
| Example 26 | A-10 | 88.67 | C-8 | 1.2 | D-2 | 0.04 | E-2 | 0.09 | F-2 | 10 | S-1 | S-2 | 50/50 | 39 |
| Example 27 | A-11 | 88.59 | C-4 | 1.3 | D-2 | 0.05 | E-1 | 0.06 | F-2 | 10 | S-1 | S-2 | 50/50 | 40 |
| Example 28 | A-11 | 83.71 | C-4 | 1.2 | D-2 | 0.02 | E-1 | 0.07 | F-4 | 15 | S-1 | S-2 | 50/50 | 41 |
| Example 29 | A-11 | 88.44 | C-3 | 1.5 | D-2 | 0.01 | E-1 | 0.05 | F-2 | 10 | S-1 | S-2 | 50/50 | 40 |
| Example 30 | A-11 | 83.80 | C-3 | 1.1 | D-2 | 0.01 | E-1 | 0.09 | F-4 | 15 | S-1 | S-2 | 50/50 | 42 |
| Example 31 | A-12 | 88.57 | C-4 | 1.3 | D-2 | 0.05 | E-1 | 0.08 | F-2 | 10 | S-1 | S-2 | 50/50 | 42 |
| Example 32 | A-12 | 83.73 | C-4 | 1.1 | D-2 | 0.09 | E-1 | 0.08 | F-4 | 15 | S-1 | S-2 | 50/50 | 44 |
| Example 33 | A-12 | 88.54 | C-3 | 1.4 | D-2 | 0.02 | E-1 | 0.04 | F-2 | 10 | S-1 | S-2 | 50/50 | 44 |
| Example 34 | A-12 | 83.83 | C-3 | 1.1 | D-2 | 0.01 | E-1 | 0.06 | F-4 | 15 | S-1 | S-2 | 50/50 | 43 |
| Example 35 | A-1 | 86.85 | C-1 | 2.9 | D-2 | 0.2 | E-1 | 0.05 | F-5 | 10 | S-1 | S-2 | 60/40 | 39 |
| Comparative | AX-1 | 97.15 | C-1 | 2.7 | D-3 | 0.1 | E-1 | 0.05 | | | S-1 | S-2 | 80/20 | 36 |
| Example 1 | | | | | | | | | | | | | | |
| Comparative | AX-2 | 96.85 | C-1 | 2.9 | D-2 | 0.2 | E-1 | 0.05 | | | S-1 | S-2 | 60/40 | 39 |
| Example 2 | | | | | | | | | | | | | | |
| Comparative | AX-3 | 96.85 | C-1 | 2.9 | D-2 | 0.2 | E-1 | 0.05 | | | S-1 | S-2 | 60/40 | 42 |
| Example 3 | | | | | | | | | | | | | | |

TABLE 4

| | Actinic ray-sensitive or radiation-sensitive resin composition | | | | | | | | | | | | | |
|---|---|---|---|---|---|---|---|---|---|---|---|---|---|---|
| | | | | | Acid | | | | | | | | | |
| | | | | | diffusion | | | | | | | | | |
| | | | Acid | | control | | | | | | | | | |
| | Resin | | generator | | agent | | Surfactant | | Additive | | Solvent | | | |
| | | Content | | Content | | Content | | Content | | Content | | | Mass ratio | |
| | | (% by | | (% by | | (% by | | (% by | | (% by | | Solvent | (solvent 1/ | Solid content |
| | Type | mass) | Type | mass) | Type | mass) | Type | mass) | Type | mass) | Solvent 1 | 2 | solvent 2) | (% by mass) |
| Example 36 | A-10 | 97.84 | C-9 | 2.0 | D-5 | 0.07 | | | F-6 | 0.088 | S-1 | S-2 | 20/80 | 40 |
| Example 37 | A-10 | 97.84 | C-2 | 2.0 | D-5 | 0.07 | | | F-6 | 0.088 | S-1 | S-2 | 20/80 | 40 |
| Example 38 | A-10 | 97.84 | C-10 | 2.0 | D-5 | 0.07 | | | F-6 | 0.088 | S-1 | S-2 | 20/80 | 40 |
| Example 39 | A-10 | 97.84 | C-9 | 2.0 | D-6 | 0.07 | | | F-6 | 0.088 | S-1 | S-2 | 20/80 | 40 |
| Example 40 | A-10 | 97.84 | C-9 | 2.0 | D-7 | 0.07 | | | F-6 | 0.088 | S-1 | S-2 | 20/80 | 40 |
| Example 41 | A-10 | 93.16 | C-9 | 2.0 | D-5 | 0.06 | | | F-6/F-7 | 0.08/4.7 | S-1 | S-2 | 20/80 | 40 |
| Example 42 | A-10 | 93.16 | C-9 | 2.0 | D-5 | 0.06 | | | F-6/F-8 | 0.08/4.7 | S-1 | S-2 | 20/80 | 40 |
| Example 43 | A-10 | 98.92 | C-9 | 1.0 | D-5 | 0.03 | | | F-6 | 0.045 | S-1 | S-2 | 20/80 | 40 |
| Example 44 | A-12 | 97.84 | C-9 | 2.0 | D-5 | 0.07 | | | F-6 | 0.088 | S-1 | S-2 | 20/80 | 40 |
| Example 45 | A-12 | 97.84 | C-2 | 2.0 | D-5 | 0.07 | | | F-6 | 0.088 | S-1 | S-2 | 20/80 | 40 |
| Example 46 | A-12 | 97.84 | C-10 | 2.0 | D-5 | 0.07 | | | F-6 | 0.088 | S-1 | S-2 | 20/80 | 40 |
| Example 47 | A-12 | 97.84 | C-9 | 2.0 | D-6 | 0.07 | | | F-6 | 0.088 | S-1 | S-2 | 20/80 | 40 |
| Example 48 | A-12 | 97.84 | C-9 | 2.0 | D-7 | 0.07 | | | F-6 | 0.088 | S-1 | S-2 | 20/80 | 40 |
| Example 49 | A-12 | 93.16 | C-9 | 2.0 | D-5 | 0.06 | | | F-6/F-7 | 0.08/4.7 | S-1 | S-2 | 20/80 | 40 |
| Example 50 | A-12 | 93.16 | C-9 | 2.0 | D-5 | 0.06 | | | F-6/F-8 | 0.08/4.7 | S-1 | S-2 | 20/80 | 40 |
| Example 51 | A-12 | 98.92 | C-9 | 1.0 | D-5 | 0.03 | | | F-6 | 0.045 | S-1 | S-2 | 20/80 | 40 |
| Example 52 | A-10 | 88.40 | C-11 | 1.5 | D-2 | 0.02 | E-2 | 0.08 | F-2 | 10 | S-1 | S-2 | 50/50 | 38 |
| Example 53 | A-10 | 88.40 | C-12 | 1.5 | D-2 | 0.02 | E-2 | 0.08 | F-2 | 10 | S-1 | S-2 | 50/50 | 38 |
| Example 54 | A-10 | 88.40 | C-9 | 1.5 | D-2 | 0.02 | E-2 | 0.08 | F-2 | 10 | S-1 | S-2 | 50/50 | 38 |
| Example 55 | A-10 | 88.40 | C-2 | 1.5 | D-2 | 0.02 | E-2 | 0.08 | F-2 | 10 | S-1 | S-2 | 50/50 | 38 |
| Example 56 | A-10 | 88.40 | C-10 | 1.5 | D-2 | 0.02 | E-2 | 0.08 | F-2 | 10 | S-1 | S-2 | 50/50 | 38 |
| Example 57 | A-10 | 88.40 | C-4 | 1.5 | D-5 | 0.02 | E-2 | 0.08 | F-2 | 10 | S-1 | S-2 | 50/50 | 38 |
| Example 58 | A-10 | 88.40 | C-4 | 1.5 | D-6 | 0.02 | E-2 | 0.08 | F-2 | 10 | S-1 | S-2 | 50/50 | 38 |
| Example 59 | A-10 | 88.40 | C-4 | 1.5 | D-7 | 0.02 | E-2 | 0.08 | F-2 | 10 | S-1 | S-2 | 50/50 | 38 |
| Example 60 | A-10 | 93.40 | C-4 | 1.5 | D-2 | 0.02 | E-2 | 0.08 | F-6 | 5 | S-1 | S-2 | 50/50 | 38 |
| Example 61 | A-10 | 93.40 | C-4 | 1.5 | D-2 | 0.02 | E-2 | 0.08 | F-7 | 5 | S-1 | S-2 | 50/50 | 38 |
| Example 62 | A-10 | 93.40 | C-4 | 1.5 | D-2 | 0.02 | E-2 | 0.08 | F-8 | 5 | S-1 | S-2 | 50/50 | 38 |

TABLE 5

| | Actinic ray-sensitive or radiation-sensitive resin composition | | | | | | | | | | | | | |
|---|---|---|---|---|---|---|---|---|---|---|---|---|---|---|
| | | | | | Acid | | | | | | | | | |
| | | | | | diffusion | | | | | | | | | |
| | | | Acid | | control | | | | | | | | | |
| | Resin | | generator | | agent | | Surfactant | | Additive | | Solvent | | | |
| | | Content | | Content | | Content | | Content | | Content | | | Mass ratio | |
| | | (% by | | (% by | | (% by | | (% by | | (% by | | | (solvent 1/ | Solid content |
| | Type | mass) | Type | mass) | Type | mass) | Type | mass) | Type | mass) | Solvent 1 | Solvent 2 | solvent 2) | (% by mass) |
| Example 63 | A-10 | 91.80 | C-4 | 1.1 | D-2 | 0.05 | E-1 | 0.05 | F-4 | 7 | S-1 | S-2 | 50/50 | 41 |
| Example 64 | A-10 | 86.70 | C-3 | 1.2 | D-2 | 0.01 | E-1 | 0.09 | F-4 | 12 | S-1 | S-2 | 50/50 | 41 |
| Example 65 | A-10 | 95.54 | C-1 | 1.3 | D-2 | 0.08 | E-1 | 0.08 | F-4 | 3 | S-1 | S-2 | 50/50 | 43 |
| Example 66 | A-10 | 93.84 | C-4 | 1.1 | D-2 | 0.01 | E-2 | 0.05 | F-4 | 5 | S-1 | S-2 | 50/50 | 42 |
| Example 67 | A-10 | 88.75 | C-3 | 1.1 | D-2 | 0.09 | E-2 | 0.06 | F-4 | 10 | S-1 | S-2 | 50/50 | 42 |
| Example 68 | A-10 | 93.77 | C-1 | 1.2 | D-2 | 0.01 | E-2 | 0.02 | F-4 | 5 | S-1 | S-2 | 50/50 | 41 |
| Example 69 | A-11 | 90.71 | C-4 | 1.2 | D-2 | 0.02 | E-1 | 0.07 | F-4 | 8 | S-1 | S-2 | 50/50 | 41 |
| Example 70 | A-11 | 97.80 | C-3 | 1.1 | D-2 | 0.01 | E-1 | 0.09 | F-4 | 1 | S-1 | S-2 | 50/50 | 42 |
| Example 71 | A-12 | 88.73 | C-4 | 1.1 | D-2 | 0.09 | E-1 | 0.08 | F-4 | 10 | S-1 | S-2 | 50/50 | 44 |
| Example 72 | A-12 | 93.83 | C-3 | 1.1 | D-2 | 0.01 | E-1 | 0.06 | F-4 | 5 | S-1 | S-2 | 50/50 | 43 |
| Example 73 | A-10 | 90.60 | C-4 | 1.3 | D-2 | 0.01 | E-1 | 0.09 | F-5 | 8 | S-1 | S-2 | 50/50 | 38 |
| Example 74 | A-10 | 95.48 | C-3 | 1.4 | D-2 | 0.02 | E-1 | 0.1 | F-5 | 3 | S-1 | S-2 | 50/50 | 37 |
| Example 75 | A-10 | 92.60 | C-1 | 1.3 | D-2 | 0.04 | E-1 | 0.06 | F-5 | 6 | S-1 | S-2 | 50/50 | 39 |
| Example 76 | A-10 | 88.40 | C-4 | 1.5 | D-2 | 0.02 | E-2 | 0.08 | F-5 | 10 | S-1 | S-2 | 50/50 | 38 |
| Example 77 | A-10 | 83.25 | C-3 | 1.6 | D-2 | 0.08 | E-2 | 0.07 | F-5 | 15 | S-1 | S-2 | 50/50 | 36 |
| Example 78 | A-10 | 92.60 | C-1 | 1.3 | D-2 | 0.02 | E-2 | 0.08 | F-5 | 6 | S-1 | S-2 | 50/50 | 38 |
| Example 79 | A-10 | 88.67 | C-8 | 1.2 | D-2 | 0.04 | E-2 | 0.09 | F-5 | 10 | S-1 | S-2 | 50/50 | 39 |
| Example 80 | A-12 | 88.57 | C-4 | 1.3 | D-2 | 0.05 | E-2 | 0.08 | F-5 | 10 | S-1 | S-2 | 50/50 | 42 |
| Example 81 | A-12 | 83.54 | C-8 | 1.4 | D-2 | 0.02 | E-2 | 0.04 | F-5 | 15 | S-1 | S-2 | 50/50 | 44 |
| Example 82 | A-10 | 88.40 | C-4 | 1.5 | D-8 | 0.03 | E-2 | 0.08 | F-2 | 10 | S-1 | S-2 | 50/50 | 38 |
| Example 83 | A-10 | 88.40 | C-2 | 1.5 | D-9 | 0.02 | E-2 | 0.08 | F-2 | 10 | S-1 | S-2 | 50/50 | 38 |
| Example 84 | A-12 | 88.58 | C-8 | 1.3 | D-10 | 0.04 | E-2 | 0.08 | F-5 | 10 | S-1 | S-2 | 50/50 | 42 |

### Pattern Formation and Various Evaluations

### Pattern Formation (Examples 1 to 12, Examples 14 to 84, and Comparative Examples 1 to 3)

The resin composition prepared above was added dropwise to an 8-inch Si wafer (manufactured by Advanced Materials Technology) in the state where the substrate was stopped, which had been subjected to a hexamethyldisilazane treatment, using a spin coater “ACT-8” manufactured by Tokyo Electron Limited, while not being provided with an antireflection layer. After the dropwise addition of the resin composition, the substrate was rotated while maintaining the rotation speed at 500) rpm for 3 seconds, at 100 rpm for 2 seconds, at 500 rpm for 3 seconds, and at 100 rpm for 2 seconds again, and thereafter, the rotation speed was raised to a film thickness-setting rotation speed (1,200 rpm), which was maintained for 60 seconds. Thereafter, drying under heating was performed on a hot plate at 130° C. for 60 seconds to form a positive-tone resist film having a film thickness of 11 μm. This resist film was subjected to pattern exposure through a mask having a line-and-space pattern under exposure conditions of NA=0.60 and σ=0.75, using a KrF excimer laser scanner (manufactured by ASML, PAS5500/850C, wavelength of 248 nm) such that the space width and the pitch width of a pattern formed after the reduction projection exposure and the development became 5 μm and 25 μm, respectively. After the irradiation, the resist film was baked at 120° C. for 60 seconds, dipped in an aqueous 2.38%-by-mass tetramethylammonium hydroxide (TMAH) solution for 60 seconds, then rinsed with pure water for 30 seconds, dried, and then baked at 110° C. for 60 seconds to form a lone space pattern with a space width of 5 μm and a pitch width of 25 nm.

In addition, the pattern exposure was an exposure through a mask having a line-and-space pattern such that the space width and the pitch width after the reduction projection exposure and the development become 5 μm and 25 μm, respectively, and the exposure dose was an optimal exposure dose (sensitivity) (mJ/cm₂) for forming a lone space pattern having a space width of 5 m and a pitch width of 25 μm. In the determination of the sensitivity, the space width of the pattern was measured using a scanning electron microscope (SEM) (938011 manufactured by Hitachi, Ltd.).

According to the procedure, a pattern wafer for evaluation, having a substrate and a pattern formed on a surface of the substrate, was obtained.

### Pattern Formation (Example 13)

Pattern formation was carried out by the same method except that rinsing with pure water and baking at 110° C. for 60 seconds after the drying were not performed in pattern formation (Examples 1 to 12, Examples 14 to 84, and Comparative Examples 1 to 3).

According to the procedure, a pattern wafer for evaluation, having a substrate and a pattern formed on a surface of the substrate, was obtained.

<Performance Evaluation>

Performance evaluation of the pattern was carried out using the obtained pattern wafer for evaluation.

(Performance Evaluation 1: Evaluation of Crack Resistance against Vacuum Treatment of Pattern)

The pattern wafer for evaluation was subjected to a vacuum treatment (evacuation) for 60 seconds in a chamber within a critical dimension-scanning electron microscope (CD-SEM). In addition, the pressure in the chamber was set to 0.002 Pa.

After the vacuum treatment, the pattern wafer for evaluation was observed with an optical microscope, evaluation of the crack resistance was performed. Specifically, the number of cracks (/8-inch wafer) of cracks of the pattern formed on a surface of the substrate was counted and evaluated based on the following standard.

“A”: The number of cracks is 0.

“B”: The number of cracks is 1 or more and less than 5.

“C”: The number of cracks is 5 or more and less than 50.

“D”: The number of cracks is 50 or more.

The results are shown in Table 3.

(Performance Evaluation 2: Evaluation of Crack Resistance against Plasma Treatment of Pattern)

Using the pattern wafer for evaluation, evaluation of crack resistance against a plasma treatment of the pattern formed on the substrate was evaluated. During a dry etching treatment of an object to be etched, even a pattern used as a mask is also exposed to a plasma environment. With this, it is necessary that the crack resistance against the plasma treatment of the pattern should be good.

With regard to the evaluation of crack resistance against the plasma treatment of the pattern, specifically, the pattern wafer for evaluation was put into a dry etching device (manufactured by Hitachi High-Technologies Corporation. U-621) and subjected to an etching treatment for 60 seconds under the conditions of a gas pressure of 4 Pa, a plasma powder of 1,200 W, and a substrate bias of 600 W, using a CF4/Ar/N₂ mixed gas (gas ratio (volume ratio), 1:10:10).

After the etching treatment, the pattern wafer for evaluation was observed with an optical microscope, evaluation of crack resistance was performed. Specifically, the number of cracks (/8-inch wafer) of cracks of the pattern formed on a surface of the substrate was counted, and evaluated based on the following standard.

“A”: The number of cracks is 0.

“B”: The number of cracks is 1 or more and less than 5.

“C”: The number of cracks is 5 or more and less than 50.

“D”: The number of cracks is 50 or more.

The results are shown in Table 3.

(Performance Evaluation 3: Evaluation of Etching Resistance) The pattern wafer for evaluation was put into a dry etching device (manufactured by Hitachi High-Technologies Corporation, U-621) and subjected to an etching treatment for 60 seconds under the conditions of a gas pressure of 4 Pa, a plasma powder of 1,200 W, and a substrate bias of 600 W, using a CF₄/Ar/N₂ mixed gas (gas ratio (volume ratio), 1:10:10).

After the etching treatment, the film thickness of a pattern formed on a surface of the substrate surface was measured with an optical interference type film thickness measuring device (manufactured by SCREEN Ltd., VM-1020). An etching rate (unit: nm/min) determined from “Film thickness before etching treatment-Film thickness after etching treatment” was calculated, and the etching resistance was evaluated based on the following standard.

“A”: The etching rate is less than 50 nm/min.

“B”: The etching rate is 50 nm/min or more and less than 100 nm/min.

“C”: The etching rate is 100 nm/min or more.

The results are shown in Table 3.

TABLE 6

| | Performance | Performance | |
|---|---|---|---|
| | evaluation 1 | evaluation 2 | Performance |
| | (Crack resistance | (Crack resistance | evaluation 3 |
| | against vacuum | against plasma treat- | (Etching |
| Table 3-1 | treatment of pattern) | ment of pattern) | resistance) |
| Example 1 | A | A | A |
| Example 2 | A | A | A |
| Example 3 | A | A | A |
| Example 4 | A | A | A |
| Example 5 | A | B | A |
| Example 6 | B | B | B |
| Example 7 | A | A | B |
| Example 8 | A | B | A |
| Example 9 | B | B | A |
| Example 10 | B | B | A |
| Example 11 | A | A | A |
| Example 12 | A | A | A |
| Example 13 | A | A | A |
| Example 14 | A | A | A |
| Example 15 | A | A | A |
| Example 16 | A | A | A |
| Example 17 | A | A | A |
| Example 18 | A | A | A |
| Example 19 | A | A | A |
| Example 20 | A | A | A |

TABLE 7

| | Performance | Performance | |
|---|---|---|---|
| | evaluation 1 | evaluation 2 | Performance |
| | (Crack resistance | (Crack resistance | evaluation 3 |
| | against vacuum | against plasma treat- | (Etching |
| Table 3-2 | treatment of pattern) | ment of pattern) | resistance) |
| Example 21 | A | A | A |
| Example 22 | A | A | A |
| Example 23 | A | A | A |
| Example 24 | A | A | A |
| Example 25 | A | A | A |
| Example 26 | A | A | A |
| Example 27 | A | B | A |
| Example 28 | A | B | A |
| Example 29 | A | B | A |
| Example 30 | A | B | A |
| Example 31 | A | B | A |
| Example 32 | A | B | A |
| Example 33 | A | B | A |
| Example 34 | A | B | |
| Example 35 | A | A | A |
| Comparative | A | D | C |
| Example 1 | | | |
| Comparative | D | D | B |
| Example 2 | | | |
| Comparative | D | C | A |
| Example 3 | | | |

TABLE 8

| | Performance | Performance | |
|---|---|---|---|
| | evaluation 1 | evaluation 2 | Performance |
| | (Crack resistance | (Crack resistance | evaluation 3 |
| | against vacuum | against plasma treat- | (Etching |
| Table 3-3 | treatment of pattern) | ment of pattern) | resistance) |
| Example 36 | A | A | A |
| Example 37 | A | A | A |
| Example 38 | A | A | A |
| Example 39 | A | A | A |
| Example 40 | A | A | A |
| Example 41 | A | A | A |
| Example 42 | A | A | A |
| Example 43 | A | A | A |
| Example 44 | A | A | A |
| Example 45 | A | A | A |
| Example 46 | A | A | A |
| Example 47 | A | A | A |
| Example 48 | A | A | A |
| Example 49 | A | A | A |
| Example 50 | A | A | A |
| Example 51 | A | A | A |
| Example 52 | A | A | A |
| Example 53 | A | A | A |
| Example 54 | A | A | A |
| Example 55 | A | A | A |
| Example 56 | A | A | A |
| Example 57 | A | A | A |
| Example 58 | A | A | A |
| Example 59 | A | A | A |
| Example 60 | A | A | A |
| Example 61 | A | A | A |
| Example 62 | A | A | A |

TABLE 9

| | Performance | Performance | |
|---|---|---|---|
| | evaluation 1 | evaluation 2 | Performance |
| | (Crack resistance | (Crack resistance | evaluation 3 |
| | against vacuum | against plasma treat- | (Etching |
| Table 3-4 | treatment of pattern) | ment of pattern) | resistance) |
| Example 63 | A | A | A |
| Example 64 | A | A | A |
| Example 65 | A | A | A |
| Example 66 | A | A | A |
| Example 67 | A | A | A |
| Example 68 | A | A | A |
| Example 69 | A | A | A |
| Example 70 | A | A | A |
| Example 71 | A | A | A |
| Example 72 | A | A | A |
| Example 73 | A | A | A |
| Example 74 | A | A | A |
| Example 75 | A | A | A |
| Example 76 | A | A | A |
| Example 77 | A | A | A |
| Example 78 | A | A | A |
| Example 79 | A | A | A |
| Example 80 | A | A | A |
| Example 81 | A | A | A |
| Example 82 | A | A | A |
| Example 83 | A | A | A |
| Example 84 | A | A | A |

As seen from the results in Table 3, it was possible to form a pattern having excellent crack resistance and etching resistance in a case where the pattern was used as a mask for an etching of an object to be etched, with the actinic ray-sensitive or radiation-sensitive resin compositions of Examples.

On the other hand, it was confirmed that a desired effect is not expressed with the actinic ray-sensitive or radiation-sensitive resin compositions of Comparative Examples.

From the comparison of Examples 1 to 9, Example 11, Example 12, and Examples 14 to 84, it was confirmed that in a case where the Tg as a monomer forming the repeating unit A being used to form a homopolymer is 30° C. or lower, the crack resistance against the vacuum treatment of the pattern is further improved.

In addition, from the comparison of Examples 1 to 9, Example 11, Example 12, and Examples 14 to 84, it was confirmed that in a case where the content of the repeating unit B is 15% by mole or less with respect to all the repeating units in the resin, the crack resistance against the plasma treatment of the pattern is further improved.

Moreover, from the comparison of Examples 1 to 9, Example 11, Example 12, and Examples 14 to 84, it was confirmed that in a case where any at least one of the repeating units contained in the resin is a repeating unit having an aromatic ring, the content of the repeating unit having an aromatic ring is 55% by mole or more with respect to all the repeating units in the resin, the etching resistance of the pattern is further improved.

Furthermore, from the comparison of Example 1, Example 35, and Example 10, it was confirmed that in a case where a compound represented by General Formula (ZI-3) is contained as a photoacid generator, the crack resistance against the vacuum treatment of the pattern and the crack resistance against the plasma treatment of the pattern are further improved.

In addition, from the results of Example 13, even in a case where the actinic ray-sensitive or radiation-sensitive resin composition of the embodiment of the present invention is not subjected to a heating step (Post Bake) after the rinsing step, the crack resistance against the vacuum treatment of the pattern and the crack resistance against the plasma treatment of the pattern are further improved.

What is claimed is:

1. An actinic ray-sensitive or radiation-sensitive resin composition, comprising:
a resin,
wherein the actinic ray-sensitive or radiation-sensitive resin composition has a concentration of a solid content of 10% by mass or more, and
wherein the resin includes:
a repeating unit A which is a repeating unit derived from a monomer allowing a homopolymer formed therefrom to have a glass transition temperature of 50° C. or lower, and
a repeating unit B which is a repeating unit having an acid-decomposable group,
a content of the repeating unit B is 20% by mole or less with respect to all the repeating units in the resin, and
at least one of the repeating unit contained in the resin is a repeating unit having an aromatic ring.

2. The actinic ray-sensitive or radiation-sensitive resin composition according to claim 1,
wherein a content of the repeating unit A is 5% by mole or more with respect to all the repeating units in the resin.

3. The actinic ray-sensitive or radiation-sensitive resin composition according to claim 1,
wherein a content of the repeating unit A is 10% by mole or more with respect to all the repeating units in the resin.

4. The actinic ray-sensitive or radiation-sensitive resin composition according to claim 1,
wherein the repeating unit A is a repeating unit derived from a monomer allowing a homopolymer formed therefrom to have a glass transition temperature of 30° C. or lower.

5. The actinic ray-sensitive or radiation-sensitive resin composition according to claim 1,
wherein the repeating unit A has a non-acid-decomposable chain alkyl group having 2 or more carbon atoms, which may have a heteroatom.

6. The actinic ray-sensitive or radiation-sensitive resin composition according to claim 5,
wherein the repeating unit A is a repeating unit represented by General Formula (1), 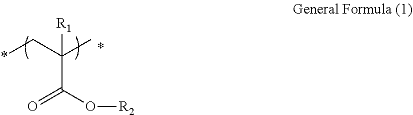
in General Formula (1), R₁ represents a hydrogen atom, a halogen atom, or an alkyl group, and R₂ represents a non-acid-decomposable chain alkyl group having 2 or more carbon atoms, which may include a heteroatom.

7. The actinic ray-sensitive or radiation-sensitive resin composition according to claim 1,
wherein the repeating unit A is a repeating unit represented by General Formula (2), 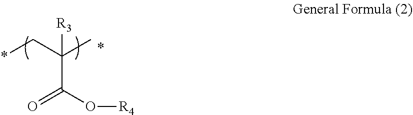
in General Formula (2), R₃ represents a hydrogen atom, a halogen atom, or an alkyl group, and R₄ represents a non-acid-decomposable alkyl group having a carboxy group or a hydroxyl group, which may include a heteroatom.

8. The actinic ray-sensitive or radiation-sensitive resin composition according to claim 1,
wherein the resin further includes a repeating unit C having a carboxy group.

9. The actinic ray-sensitive or radiation-sensitive resin composition according to claim 1,
wherein the resin further includes a repeating unit D having a phenolic hydroxyl group.

10. The actinic ray-sensitive or radiation-sensitive resin composition according to claim 1, further comprising a compound represented by General Formula (ZI-3) or a compound represented by General Formula (ZI-4), 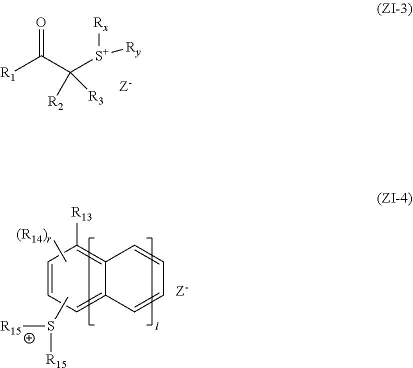
in General Formula (ZI-3), R₁ represents an alkyl group, a cycloalkyl group, an aryl group, or a benzyl group, and in a case where R₁ has a ring structure, the ring structure may include an oxygen atom, a sulfur atom, an ester bond, an amide bond, or a carbon-carbon double bond,
R₂ and R₃ each independently represent a hydrogen atom, an alkyl group, a cycloalkyl group, a halogen atom, a cyano group, or an aryl group,
Rₓ and R_{y} each independently represent an alkyl group, a cycloalkyl group, a 2-oxoalkyl group, an alkoxycarbonylalkyl group, an allyl group, or a vinyl group,
R₂ and R₃ may be bonded to each other to form a ring, R₁ and R₂ may be bonded to each other to form a ring, the ring thus formed may include a carbon-carbon double bond, Rₓ and R_{y} may be bonded to each other to form a ring, and the ring thus formed may include an oxygen atom, a sulfur atom, an ester bond, an amide bond, or a carbon-carbon double bond, and
Z⁻ represents an anion; and
in General Formula (ZI-4), R₁₃ represents a hydrogen atom, a fluorine atom, a hydroxyl group, an alkyl group, a cycloalkyl group, an alkoxy group, an alkoxycarbonyl group, or a group having a monocyclic or polycyclic cycloalkyl skeleton,
R₁₄ represents an alkyl group, a cycloalkyl group, an alkoxy group, an alkylsulfonyl group, a cycloalkylsulfonyl group, an alkylcarbonyl group, an alkoxycarbonyl group, or an alkoxy group having a monocyclic or polycyclic cycloalkyl skeleton, and in a case where a plurality of R₁₄'s are present, R₁₄'s may be the same as or different from each other,
R₁₅'s each independently represent an alkyl group, a cycloalkyl group, or a naphthyl group, and R₁₅'s may be bonded to each other to form a ring,
I represents an integer of 0 to 2,
r represents an integer of 0 to 8, and
Z⁻ represents an anion.

11. The actinic ray-sensitive or radiation-sensitive resin composition according to claim 1,
wherein the acid-decomposable group is a group in which a hydrogen atom of a polar group is substituted with a group represented by —C(R₃₆)(R₃₇)(R₃₈),
R₃₆ to R₃₈ each independently represent an alkyl group, a cycloalkyl group, an aryl group, an aralkyl group, or an alkenyl group, and
R₃₆ and R₃₇ may be bonded to each other to form a ring.

12. The actinic ray-sensitive or radiation-sensitive resin composition according to claim 1,
wherein a content of the repeating unit having an aromatic ring is 53% by mole or more with respect to all the repeating units in the resin.

13. A resist film formed of the actinic ray-sensitive or radiation-sensitive resin composition according to claim 1.

14. A pattern forming method comprising:
forming a resist film using the actinic ray-sensitive or radiation-sensitive resin composition according to claim 1;
exposing the resist film; and
developing the exposed resist film using a developer.

15. A method for manufacturing an electronic device, comprising the pattern forming method according to claim 14.
